(19) United States
(12) Patent Application Publication
(10) Pub. No.: US 2026/0239816 A1
(43) Pub. Date: Aug. 13, 2026

(54) MATERIALS FOR ORGANIC ELECTROLUMINESCENT DEVICES

(71) Applicant: Merck Patent GmbH, Darmstadt (DE)

(72) Inventors: Falk May, Mainz (DE); Martin Kraska, Fischbachtal (DE); Jonas Valentin Kroeber, Ober-Ramstadt (DE); Armin Auch, Herrenberg (DE)

(21) Appl. No.: 19/155,474

(22) PCT Filed: Feb. 14, 2024
(86) PCT No.: PCT/EP2024/053700

§ 371 Date: Aug. 11, 2025

(30) Foreign Application Priority Data
Feb. 17, 2023 (EP) 23157301.5

(51) Int. Cl. H10K 50/13; H10K 50/19; H10K 85/30; H10K 85/60; H10K 101/00; H10K 101/30

(52) U.S. Cl. CPC H10K 50/13; H10K 50/19; H10K 85/342; H10K 85/346; H10K 85/622; H10K 85/626; H10K 85/633; H10K 85/636; H10K 85/654; H10K 85/656; H10K 85/6572; H10K 85/6574; H10K 85/6576; H10K 2101/30; H10K 2101/90

(57) ABSTRACT

The present invention relates to an organic electroluminescent device (OLED) comprising two adjacent light emitting layers, which are vertically stacked on top of each other. The present invention also relate to a tandem organic electroluminescent device.

The present invention relates to an organic electroluminescent device (OLED) comprising two adjacent light emitting layers, which are vertically stacked on top of each other. The present invention also relate to a tandem organic electroluminescent device, and more specifically a tandem white organic electroluminescent device.

Nowadays, lots of displays are based on organic electroluminescent devices (OLEDs). There are different OLEDs architectures. For example, in typical flat-panel display, each pixel consists of laterally separated red, green and blue sub-pixels on a side-by-side geometry. Another OLED architecture has gained a lot of interest these last years, where light of different colours is emitted in different organic layers stacked on top of each other as described for example in Fröber et al., Three-terminal RGB full color OLED pixels for ultrahigh density displays. Sci Rep 8, 9684 (2018) and in Bobbert et al., A look inside white OLEDS, Europhysics News, Vol. 44, No. 5, 2013, pp. 21-25. These kind of architecture, the OLED comprises a plurality of light emitting stacks that are vertically arranged on top of each other is also known as tandem OLEDs. Tandem stacks can be used to fabricate white-OLEDs.

In tandem OLEDs, the light emitting stacks are generally electrically connected in series via connecting stacks, which function as charge generation layer (CGL). Thus, every light emitting stack can form an individual unit separated from the other light-emitting unit by a charge generation layer (CGL) as described in Zhang et al., Stacking multiple connecting functional materials in tandem organic light-emitting diodes, Sci Rep 7, 43130 (2017).

Each light emitting stack in a tandem OLED can have a multiple layer structure comprising for example a hole transport layer, a light emitting layer and an electron transport layer. In order to simplify the structure of the tandem device, it might be advantageous to limit the number of light-emitting stacks by, for example, using a light emitting stack comprising two light-emitting layers of different colors as described in US 2021/0175456 A1 and in Miao et al., Tandem white organic light-emitting diodes stacked with two symmetrical emitting units simultaneously achieving superior efficiency/CRI/color stability, Nanophotonics, 8(10), 2019, pp. 1783-1794.

However, the further development of OLEDs for commercialisation in displays and lighting applications requires constant improvement of the performance data of the tandem OLEDs, and more particularly in tandem white OLEDs, in terms of color stability. More particularly, there might be an unwanted shift of the recombination zone between two adjacent emissive layers as function of external voltage. The shift of the recombination zone might lead to a color shift of the OLED. Therefore, there is a need to avoid any color shift within an OLED as it is important to have an OLED showing good properties in terms of efficiency, color point and color stability. Furthermore, improvements in the lifetime are preferably achieved.

In corresponding investigations, it has now been found, surprisingly, that improved color stability are obtained with OLEDs comprising two emitting layers deposited on top of each others, in which certain conditions apply to the Interface Charge Density (ICD).

The invention thus relate to an an organic electroluminescent device comprising:
An anode;
A cathode, arranged opposite to the anode;
At least one light emitting stack arranged between the anode and the cathode;
   wherein the one light emitting stack comprises a first emitting layer, EMLₓ, a second emitting layer, EMLₓ₊₁;
   wherein EMLₓ₊₁ is arranged between the emitting layer EMLₓ and the cathode, and EMLₓ₊₁ is adjacent to the first emitting layer EMLₓ,
   characterized in that the interface charge density at the interface of the emitting layers EMLₓ and EMLₓ₊₁, namely ICD_{EMLx},E_{MLx+1}, fulfills the following equation:

$$y < {ICD}_{EMLx , EMLx + 1} \leq 0.1 mC \cdot {m}^{- 2}$$

where y is equal to −1 mC·m⁻²; and where ICD_{EMLx,EMLx+1} is the difference between the surface charge density of the emitting layers EMLₓ₊₁ and EMLₓ:

$${ICD}_{EMLx , EMLx + 1} = {SCD}_{EMLx + 1} - {SCD}_{EMLx}$$

where the surface charge density SCD of an emitting layer comprising n materials, SCD (EML), corresponds to the sum of the surface charge densities SCDᵢ of each material i present in the corresponding emitting layer multiplied by their proportion αᵢ in the layer:

$$SCD ( EML ) = {\sum }_{i = 1}^{n} {α}_{i} * {SCD}_{i}$$

where
αᵢ is the proportion of the material i in the corresponding emitting layer by weight, based on the total weight of the corresponding layer; and where SCDᵢ is the surface charge density of the material i as determined by dielectric spectroscopy measurements.

It is understood that the term “comprising” means that the named elements are essential, but other elements may be added and still form a construct of the present invention. More particularly, the organic electroluminescent device described above may comprise one or more further functional layers additionally to the anode, cathode and layers EMLₓ and EMLₓ+1.

The surface charge density, SCD of a given material i is obtained from dielectric spectroscopy measurements, more particularly from dielectric spectroscopy measurements in concentration series and extrapolated to pure layers. The applied experimental method is based on the method described in Nowy et al., Impedance spectroscopy as a probe for the degradation of organic light-emitting diodes. J. Appl. Phys. 107, 1-9 (2010). The determination of the surface charge density of a layer is explained in more details in the examples section below.

Preferably, y is equal to −0.8 mC·m⁻², more preferably equal to −0.6 mC·m⁻², even more preferably equal to −0.4 mC·m⁻².

It is also preferred that ICD_{EMLx,EMLx+1} fulfills the following equation:

$$y < {ICD}_{EMLx , EMLx + 1} \leq 0 mC {m}^{- 2}$$

Preferably, one of the emitting layers selected from EMLₓ and EMLₓ₊₁ has an emission maximum wavelength λ_{R} of from 590 to 660 nm. Therefore, one of the emitting layers selected from EMLₓ and EMLₓ₊₁ is a red emitting layer.

Also preferably, one of the emitting layers selected from EMLₓ and EMLₓ₊₁ has an emission maximum wavelength λ_{BGY} from 450 to 585 nm. Therefore, one of the emitting layers selected from EMLₓ and EMLₓ₊₁ is a blue, green or yellow emitting layer.

In accordance with a preferred embodiment, the first emitting layer EMLₓ has an emission maximum wavelength λ_{R} and the emitting layer EMLₓ₊₁ has an emission maximum wavelength λ_{BGY}. Therefore, the emitting layer EMLₓ is a red emitting layer and the emitting layer EMLₓ₊₁ is a blue, green or yellow emitting layer.

In accordance with another preferred embodiment, the first emitting layer EMLₓ has an emission maximum wavelength wavelength λ_{BGY} and the emitting layer EMLₓ₊₁ has an emission maximum wavelength λ_{R}, Therefore, the emitting layer EMLₓ is a blue, green or yellow emitting layer and the emitting layer EMLₓ₊₁ is a red emitting layer.

Preferably, the layer EMLₓ or EMLₓ₊₁ having an emission maximum wavelength λ_{R} of from 590 to 660 nm comprises at least one emitter selected from red phosphorescent emitters. More preferably, the layer EMLₓ or EMLₓ₊₁ having an emission maximum wavelength λ_{R} of from 590 to 660 nm comprises at least one emitter selected from red phosphorescent emitters and a host system, where the host system preferably comprises at least two host materials, wherein one host material is a hole-transporting host material and the other host material is an electron-transporting host material.

Preferably, the host system, in the layer EMLₓ or EMLₓ₊₁ having an emission maximum wavelength λ_{R} of from 590 to 660 nm, is present in the layer in a proportion of 70-99.5%, preferably 80-99.5%, more preferably 90-99%, particularly preferably 95-99% and the at least one emitter is present in the layer in a proportion of 0.5-50%, preferably 1-30%, more preferably 1-10%, particularly preferably 1-5%.

In this application, proportions are given as percent by volume when the mixtures are applied from the gas phase. If the mixtures are applied from solution, this corresponds to percent by mass.

When the layer EMLₓ or EMLₓ₊₁ having an emission maximum wavelength λ_{R} comprises at least one emitter selected from red phosphorescent emitters and a host system comprising a hole-transporting host material and an electron-transporting host material, then it is preferred that:
the at least one emitter has a LUMO of from −2.00 eV to −2.50 eV, preferably of from −2.10 eV to −2.40 eV, more preferably of from −2.20 eV to −2.30 eV, even more preferably of from −2.25 eV to −2.30 eV and a HOMO of from −4.90 eV to −5.20 eV, preferably of from −4.95 eV to −5.10 eV, more preferably of from −5.00 eV to −5.05 eV;
the hole-transporting host material has a LUMO of from −1.40 eV to −1.70 eV, preferably of from −1.45 eV to −1.65 eV, more preferably of from −1.50 eV to −1.60 eV, even more preferably of from −1.55 eV to −1.60 eV and a HOMO of from −5.0 eV to −5.35 eV, preferably of from −5.05 eV to −5.25 eV, more preferably of from −5.10 eV to −5.20 eV, even more preferably of from −5.15 eV to −5.20 eV; and the electron-transporting host material has a LUMO of from −2.5 eV to −2.9 eV, preferably of from −2.6 eV to −2.8 eV, more preferably of from −2.65 eV to −2.75 eV, even more preferably of from −2.65 eV to −2.70 eV and a HOMO of from −5.3 eV to −5.6 eV, preferably of from −5.35 eV to −5.5 eV, more preferably of from −5.4 eV to −5.45 eV.

The person skilled in the art, in the context of his common knowledge in the art, is able to identify suitable red phosphorescent emitters without any great effort. Examples of suitable red phosphorescent emitters are the compounds disclosed in WO2008/109824, WO2008/078800, US2010/0133524, US2012/0181511, WO2010/033550, US2015/0295198, US2016/0093808, US2018/097187, US2015/0295199, US2020/0127212 or US2020/0111977.

Preferably, the red phosphorescent emitter, in the layer EMLₓ or EMLₓ₊₁ having an emission maximum wavelength λ_{R}, is selected from compounds of formula (M1):

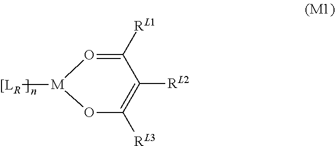

where
M is selected from Ir or Pt;
L_{R} is a bidentate ligand coordinating by one N- and one C-atom;
n is a number equal to 1, if M is Pt, and to 2, if M is Ir;
R^{L1}, R^{L2}, R^{L3} are are on each occurrence, identically or differently, selected from H, D, F, a straight-chain alkyl group having 1 to 40 C atoms or a branched or cyclic alkyl having 3 to 40 C atoms, each of which may be substituted by one or more radicals R^{L}.

R^{L} stands on each occurrence, identically or differently, for H, D, F, CN, a straight-chain alkyl, alkoxy or thioalkyl group having 1 to 20 C atoms or branched or cyclic alkyl, alkoxy or thioalkyl group having 3 to 20 C atoms, where one or more H atoms may be replaced by D or F.

More preferably, the red phosphorescent emitter, in the layer EMLₓ or EMLₓ+1 having an emission maximum wavelength λ_{R}, is selected from compounds of formula (M1-1):

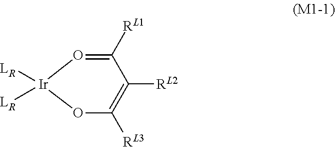

where
L_{R}, R^{L1}, R^{L2}, R^{L3} have the same meaning as above.

Preferably, L_{R} is a ligand of formula (LR-1),

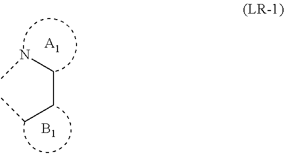

where the dashed bonds indicates the bonds to the iridium atom; and the ring A₁, including the nitrogen atom represented in (LR-1), represents an heteroaryl ring having 5 to 20 aromatic ring atoms, which may in each case be substituted by one or more radicals R^{A1}; and the ring B₁ represents an aryl or heteroaryl ring having 5 to 20 aromatic ring atoms, which may in each case be substituted by one or more radicals R^{B1}
R^{A1}, R^{B1} are the same or different at each instance and is H, D, F, N(R^{R})₂, OR^{R}, SR^{R}, CN, Si(R^{R})₃, B(OR^{R})₂, a straight-chain alkyl group having 1 to 20 carbon atoms or or a branched or cyclic alkyl group having 3 to 20 carbon atoms, where the alkyl may in each case be substituted by one or more R^{R} radicals and where one or more nonadjacent CH₂ groups may be replaced by Si(R^{R})₂, O, S or an aromatic or heteroaromatic ring system which has 5 to 40 aromatic ring atoms and may be substituted in each case by one or more R^{R} radicals; at the same time, two R^{A}1 radicals, two R^{B}1 radicals and/or one R^{A}1 radical and one R^{B}1 radical together may also form a ring system;
R^{R} is the same or different at each instance and is H, D, F, N(R^{R′})₂, CN, Si(R^{R′})₃, B(OR^{R′})₂, a straight-chain alkyl group having 1 to 20 carbon atoms a branched or cyclic alkyl group having 3 to 20 carbon atoms, where the alkyl, may in each case be substituted by one or more R^{R′} radicals and where one or more nonadjacent CH₂ groups may be replaced by Si(R^{R′})₂, O, S, or an aromatic or heteroaromatic ring system which has 5 to 40 aromatic ring atoms and may be substituted in each case by one or more R^{R′} radicals; at the same time, two or more R^{R} radicals together may form a ring system;
R^{R′} is the same or different at each instance and is H, D, F or an aliphatic organic radical, especially a hydrocarbyl radical, having 1 to 20 carbon atoms, in which one or more hydrogen atoms may also be replaced by F.

More preferably, L_{R} is a ligand of formula (LR-1-1):

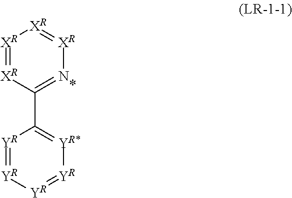

where the symbols “*” indicate the bonding positions to the iridium atom; and
X^{R} is the same or different at each instance and is CR^{A1}, N or two adjacent groups X^{R} form a condensed aryl or heteroaryl ring having 5 to 20 aromatic ring atoms;
Y^{R} is the same or different at each instance and is CR^{B1}, N or two adjacent groups Y^{R} form a condensed aryl or heteroaryl ring having 5 to 20 aromatic ring atoms;
R^{A1}, R^{B1} have the same definition as above.

More preferably, when two adjacent groups X^{R} form a condensed aryl or heteroaryl ring having 5 to 20 aromatic ring atoms, then the condensed aryl or heteroaryl ring is a ring of formula (CyR-1), (CyR-2), (CyR-3), (CyR-4) or (CyR-5),

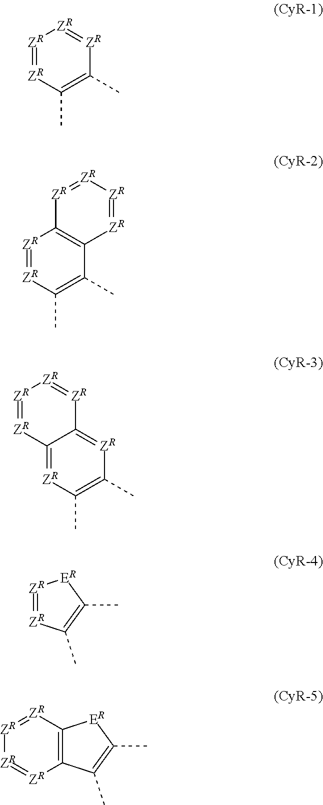

where, in (CyR-1) to (CyR-5), the dashed bonds represent the bonding positions to the adjacent ring in formula (LR-1-1),
Z^{R} is the same or different at each instance and is CR^{A} or N, with the proviso that at most two symbols Z^{R} per ring are N;
E^{R} is S or O;
R^{A1} has the same meaning as above.

Examples of suitable red phosphorescent emitters are depicted in the table below:

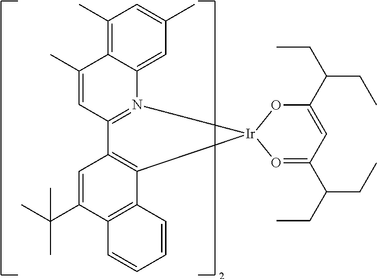

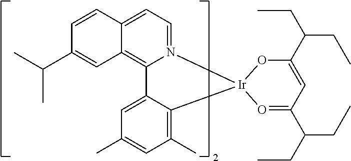

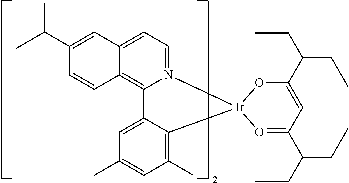

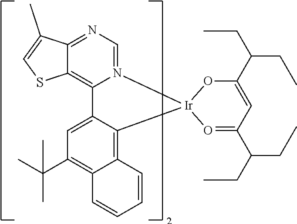

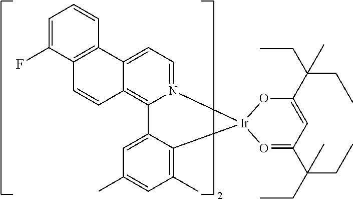

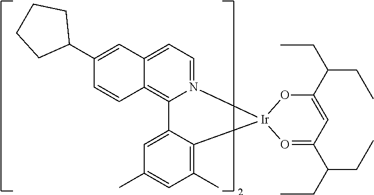

Preferably, the layer EMLₓ or EMLₓ₊₁ having an emission maximum wavelength λ_{BGY} of from 450 to 585 nm comprises at least one emitter selected from blue, green and yellow fluorescent or phosphorescent emitters. More preferably, the layer EMLₓ or EMLₓ₊₁ having an emission maximum wavelength λ_{BGY} of from 450 to 585 nm comprises at least one emitter selected from blue, green and yellow fluorescent or phosphorescent emitters and a host system, where the host system preferably comprises at least two host materials, wherein one host material is a hole-transporting host material and the other host material is an electron-transporting host material.

Preferably, the host system, in the layer EMLₓ or EMLₓ₊₁ having an emission maximum wavelength λ_{BGY} of from 450 to 585 nm, is present in the layer in a proportion of 60-99.5%, preferably 65-99%, more preferably 70-95%, particularly preferably 75-90% and the at least one emitter is present in the layer in a proportion of 0.5-50%, preferably 2-40%, more preferably 5-30%, particularly preferably 10-25%.

When the layer EMLₓ or EMLₓ₊₁ having an emission maximum wavelength λ_{BGY} comprises at least one emitter selected from blue, green and yellow fluorescent or phosphorescent emitters and a host system comprising a hole-transporting host material and an electron-transporting host material, then it is preferred that: the at least one emitter has a LUMO of from −1.65 eV to −2.05 eV, preferably of from −1.75 eV to −1.95 eV, more preferably of from −1.80 eV to −1.90 eV, even more preferably of from −1.85 eV to −1.90 eV and a HOMO of from −4.85 eV to −5.20 eV, preferably of from −4.90 eV to −5.10 eV, more preferably of from −4.95 eV to −5.00 eV;
the hole-transporting host material has a LUMO of from −1.55 eV to −1.90 eV, preferably of from −1.65 eV to −1.80 eV, more preferably of from −1.70 eV to −1.75 eV and a HOMO of from −5.2 eV to −5.45 eV, preferably of from −5.3 eV to −5.40 eV, more preferably of from −5.35 eV to −5.40 eV;
the electron-transporting host material has a LUMO of from −2.35 eV to −2.80 eV, preferably of from −2.45 eV to −2.70 eV, more preferably of from −2.50 eV to −2.60 eV, and even more preferably of from −2.55 eV to −2.60 eV and a HOMO of from −5.3 eV to −5.7 eV, preferably of from −5.4 eV to −5.6 eV, more preferably of from −5.45 eV to −5.55 eV, even more preferably of from −5.50 eV to −5.55 eV.

The person skilled in the art, in the context of his common knowledge in the art, is able to identify suitable blue, green and yellow fluorescent and phosphorescent emitters without any great effort.

Examples of suitable blue fluorescent emitters are disclosed in WO 2021/090932, WO 2020/054676, WO 2020/017931, WO 2020/218079, WO 2018/212169, WO 2019/235452, U.S. Pat. No. 10,249,832 and WO 2021/014001. Examples of blue phosphorescent emitters are disclosed in Sungho Nam et al, Adv. Sci. 2021, 2100586 and Eungdo Kin et al, Sci. Adv. 2022, 8, eabq 1641, EP 3 435 438 A2, CN 109111487, US 2020/0140471, KR2020108705, US 2019/0119312, US 2020/0411775, US2022115607 AA, US2022298193 AA, US2016072082 AA and US2022271236 AA. Examples of suitable yellow emitters are the yellow phosphorescent emitters disclosed in US2020/0111977, WO2010/028151, EP1239526, TW1618710 and JP2017/048184. Examples of suitable green emitters are the green phosphorescent emitters disclosed in US2001/0019782, WO2010/028151, US2001/0019782, WO2010/028151, EP1239526, US2010/0244004, WO2000/070655, US2014/0131676, US2014/0231755, EP3381927, US2018/0287070, EP3623443, DE102020101561, WO2009/116456 and WO2020/165064.

In accordance with a preferred embodiment, the at least one emitter in the layer EMLₓ or EMLₓ₊₁ having an emission maximum wavelength λ_{BGY} of from 450 to 585 nm is a blue emitter selected from blue fluorescent emitters and blue phosphorescent emitters.

More preferably, the at least one emitter in the layer EMLₓ or EMLₓ₊₁ having an emission maximum wavelength λ_{BGY} of from 450 to 585 nm is a blue phosphorescent emitter selected from iridium and platinum complexes.

Even more preferably, the at least one emitter in the layer EMLₓ or EMLₓ₊₁ having an emission maximum wavelength λ_{BGY} of from 450 to 585 nm is a blue phosphorescent emitter selected from tetradentate platinum complexes.

Very suitable blue phosphorescent metal complexes are the compounds of formula (Pt-1) as defined below:

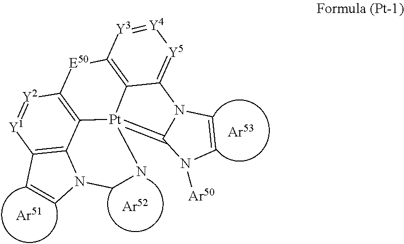

where:
Y¹, Y², Y³, Y⁴, Y⁵ stand, on each occurrence identically or differently, for a group CR^{Y} or N; or Y¹—Y² and/or Y³—Y⁴ or Y⁴—Y⁵ may form a condensed aryl or heteroaryl ring having 5 to 18 aromatic ring atoms, which may in each case also be substituted by one or more radicals R^{P};
E⁵⁰ stands for on each occurrence, identically or differently, for C(R^{CO})₂, NR^{N0}, O or S;
Ar⁵⁰ is, on each occurrence, identically or differently, an aromatic or heteroaromatic ring system having 5 to 60, which may in each case also be substituted by one or more radicals R^{P};
Ar⁵¹, Ar⁵², Ar⁵³ represent, identically or differently, a condensed aryl or heteroaryl ring having 5 to 18 aromatic ring atoms, which may in each case also be substituted by one or more radicals R^{P};
R^{Y} stand on each occurrence, identically or differently, for a radical selected from H, D, F, Cl, Br, I, CHO, CN, C(═O)Ar, P(═O)(Ar)₂, S(═O)Ar, S(═O)₂Ar, N(R^{P})₂, N(Ar)₂, NO₂, Si(R^{P})₃, B(ORP)₂, OSO₂R^{P}, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R^{P}, where in each case one or more non-adjacent CH₂ groups may be replaced by R^{P}C═C^{R}P, C═C, Si(R^{P})₂, Ge(R^{P})₂, Sn(R^{P})₂, C═0, C═S, C═Se, P(═O)(R^{P}), SO, SO₂, O, S or CONR^{P} and where one or more H atoms may be replaced by D, F, Cl, Br, I, CN or NO₂, an aromatic or heteroaromatic ring system having 5 to 60 aromatic ring atoms, which may in each case be substituted by one or more radicals R^{P}, and an aryloxy group having 5 to 60 aromatic ring atoms, which may be substituted by one or more radicals R^{P}; where two radicals R may form an aliphatic, aromatic or heteroaromatic ring system together, which may be substituted by one or more radicals R^{P};
R^{C0} stand on each occurrence, identically or differently, for a radical selected from H, D, a straight-chain alkyl group having 1 to 40 C atoms, which may be substituted by one or more radicals R^{P}, an aryl or heteroaryl group having 6 to 18 aromatic ring atoms, which may in each case be substituted by one or more radicals R^{P}; where two radicals R^{C} may form an aliphatic, aromatic or heteroaromatic ring system together, which may be substituted by one or more radicals R^{P};
R^{N0} stand on each occurrence, identically or differently, for a radical selected from H, D, F, a straight-chain alkyl group having 1 to 40 C atoms or branched or a cyclic alkyl group having 3 to 40 C atoms, each of which may be substituted by one or more radicals R^{P}, and where one or more H atoms may be replaced by D, F or CN, an aromatic or heteroaromatic ring system having 5 to 60 aromatic ring atoms, which may in each case be substituted by one or more radicals R^{P};
R^{P} stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by R′C═CR′, C═C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two radicals R^{P} may form a mono- or polycyclic, aliphatic ring system, aromatic or heteroaromatic ring system, which may be substituted by one or more radicals R′;
Ar is, on each occurrence, identically or differently, an aromatic or heteroaromatic ring system having 5 to 60 aromatic ring atoms, which may in each case also be substituted by one or more radicals R′;
R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms.

In accordance with another preferred embodiment, the at least one emitter in the layer EMLₓ or EMLₓ₊₁ having an emission maximum wavelength λ_{BGY} of from 450 to 585 nm is selected from blue, green and yellow phosphorescent emitters selected from metal complexes of formulae (1) and (2),

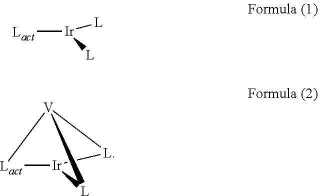

L_{act} in formula (1) represents the optically active ortho-metallated bidentate ligand or, in formula (2), the optically active ortho-metallated bidentate sub-ligand. L is the same or different at each instance in formula (1) and represents the optically inactive ortho-metallated bidentate ligands or, in formula (2), the optically inactive ortho-metallated bidentate sub-ligands. V in formula (2) is a bridging unit that joins the sub-ligands L_{act} and L covalently to one another to form a tripodal hexadentate ligand. Preference is given to the tripodal complexes of the formula (2).

The ligand in formula (2) is a hexadentate tripodal ligand having one bidentate sub-ligand L_{act} and two bidentate sub-ligands L. “Bidentate” means that the particular sub-ligand in the complex coordinates or binds to the iridium via two coordination sites. “Tripodal” means that the ligand has three sub-ligands bonded to the bridge V. Since the ligand has three bidentate sub-ligands, the overall result is a hexadentate ligand, i.e. a ligand which coordinates or binds to the iridium via six coordination sites. The expression “bidentate sub-ligand” in the context of this application means that L_{act} and L would each be a bidentate ligand if the bridge V were absent. However, as a result of the formal abstraction of a hydrogen atom from this bidentate ligand and the attachment to the bridge, it is no longer a separate ligand but a portion of the hexadentate ligand which thus arises, and so the term “sub-ligand” is used therefor.

The bidentate ortho-metallated ligands or sub-ligands L_{act} and L are described hereinafter. The ligands or sub-ligands L_{act} and L coordinate to the iridium via one carbon atom and one nitrogen atom or via two carbon atoms. When L_{act} or L coordinates to the iridium via two carbon atoms, one of the two carbon atoms is a carbene carbon atom. In addition, L is different from L_{act} since L_{act} is an optically active ligand or sub-ligand, while L is optically inactive. In a preferred embodiment of the invention, the two ligands or sub-ligands L are identical.

More preferably, each ligand or sub-ligand L_{act} and L has one carbon atom and one nitrogen atom as coordinating atoms.

It is further preferable when the metallacycle which is formed from the iridium and the ligand or sub-ligand L_{act} and L is a five-membered ring. This is shown schematically hereinafter:

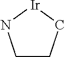

five-membered ring
where N represents a coordinating nitrogen atom and C a coordinating carbon atom, and the carbon atoms shown represent atoms of the ligand or sub-ligand L_{act} or L.

As described above, the structure fragment Ir(L) has a higher triplet energy than the structure fragment Ir(L_{act}) with the optically active ligand or sub-ligand. This achieves the effect that the emission from the complex comes predominantly from the structure fragment Ir(L_{act}).

In a preferred embodiment of the invention, the ligands or sub-ligands L_{act} and L are a structure of the following formula (L-1) or (L-2), where L_{act} and L are different from one another and the two ligands or sub-ligands L may be the same or different, but are preferably the same,

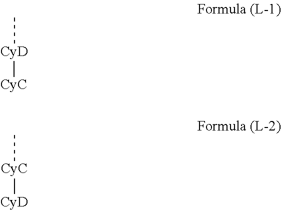

where the dotted bond represents the bond of the sub-ligand to the bridge V in formula (2) and is absent for formula (1) and where the other symbols used are as follows:
CyC is the same or different at each instance and is a substituted or unsubstituted aryl or heteroaryl group which has 5 to 14 aromatic ring atoms and coordinates in each case to the metal via a carbon atom and which is bonded to CyD via a covalent bond;
CyD is the same or different at each instance and is a substituted or unsubstituted heteroaryl group which has 5 to 14 aromatic ring atoms and coordinates to the metal via a nitrogen atom or via a carbene carbon atom and which is bonded to CyC via a covalent bond;
at the same time, two or more of the optional substituents together may form a ring system; the optional radicals are preferably selected from the R radicals defined below.

CyD coordinates via an uncharged nitrogen atom or via a carbene carbon atom, and CyC coordinates via an anionic carbon atom.

When two or more of the substituents, especially two or more R radicals, together form a ring system, it is possible for a ring system to be formed from substituents bonded to directly adjacent carbon atoms. In addition, it is also possible that the substituents on CyC and CyD or on the two CyD groups together form a ring, as a result of which CyC and CyD may also together form a single fused aryl or heteroaryl group as bidentate ligand.

Preferably, all ligands or sub-ligands L_{act} and L have a structure of the formula (L-1), or all ligands or sub-ligands L_{act} and L have a structure of the formula (L-2). L_{act} is different from L, and the two sub-ligands L are preferably the same.

In a preferred embodiment of the present invention, CyC is an aryl or heteroaryl group having 6 to 13 aromatic ring atoms, more preferably having 6 to 10 aromatic ring atoms, most preferably having 6 aromatic ring atoms, which coordinates to the metal via a carbon atom, which may be substituted by one or more R radicals and which is bonded to CyD via a covalent bond.

Preferred embodiments of the CyC group are the structures of the following formulae (CyC-1) to (CyC-19) where the CyC group binds in each case at the position signified by # to CyD and coordinates at the position signified by * to the iridium,

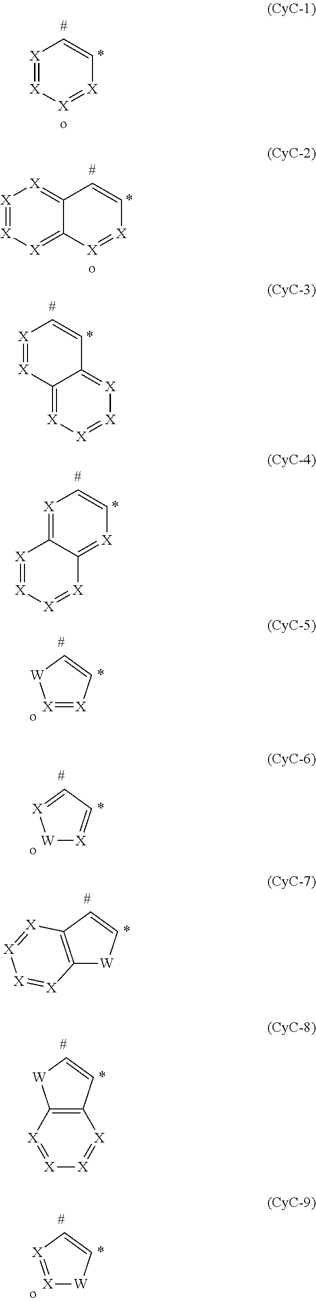

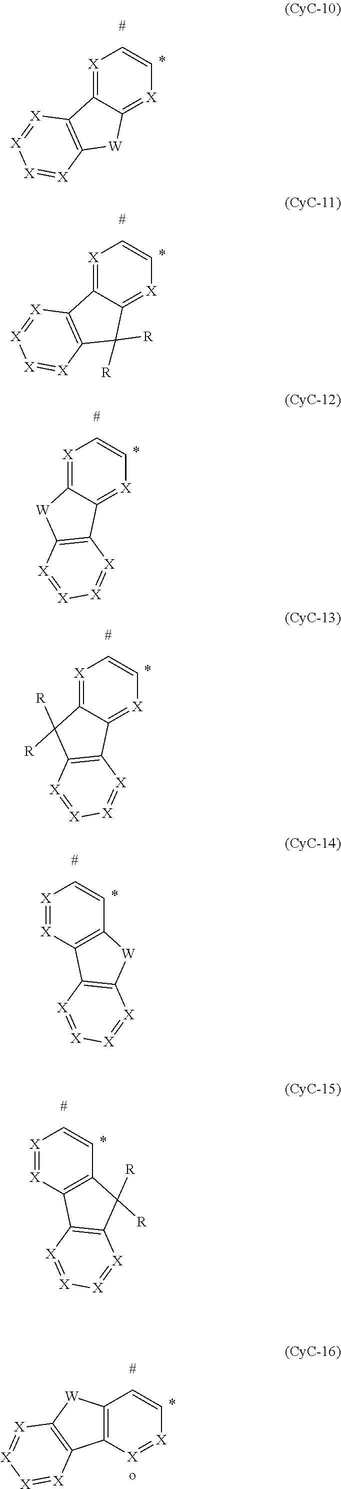

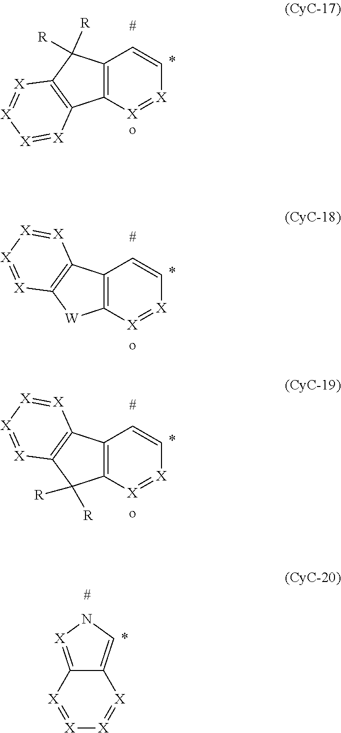

where the symbols used are as follows:
X is the same or different at each instance and is CR or N, with the proviso that at most two symbols X per ring are N;
W is the same or different at each instance and is NR, 0 or S;
R is the same or different at each instance and is H, D, F, Cl, Br, I, N(R¹)₂, OR¹, SR¹, CN, NO₂, COOR¹, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals and where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more nonaromatic R¹ radicals; at the same time, two R radicals together may also form a ring system;
R¹ is the same or different at each instance and is H, D, F, Cl, Br, I, N(R²)₂, OR², SR², CN, NO₂, Si(R²)₃, B(OR²)₂, C(═O)R², P(═O)(R²)₂, S(═O)R², S(═O)₂R², OSO₂R², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals and where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic organic radical, especially a hydrocarbyl radical, having 1 to 20 carbon atoms, in which one or more hydrogen atoms may also be replaced by F;
with the proviso that, when the bridge V is bonded to CyC in formula (2), one symbol X is C and the bridge V is bonded to this carbon atom. When the CyC group is bonded to the bridge V, the bond is preferably via the position marked “o” in the formulae depicted above, and so the symbol X marked “o” in that case is preferably C. The above-depicted structures which do not contain any symbol X marked “o” are preferably not bonded directly to the bridge V, since such a bond to the bridge is not advantageous for steric reasons.

When two R or R¹ radicals together form a ring system, it may be mono- or polycyclic, aliphatic, heteroaliphatic, aromatic or heteroaromatic. In this case, these radicals which together form a ring system may be adjacent, meaning that these radicals are bonded to the same carbon atom or to carbon atoms directly bonded to one another, or they may be further removed from one another. Preference is given to this kind of ring formation in radicals bonded to carbon atoms directly bonded to one another.

The wording that two or more radicals together may form a ring, in the context of the present description, should be understood to mean, inter alia, that the two radicals are joined to one another by a chemical bond with formal elimination of two hydrogen atoms. This is illustrated by the following scheme:

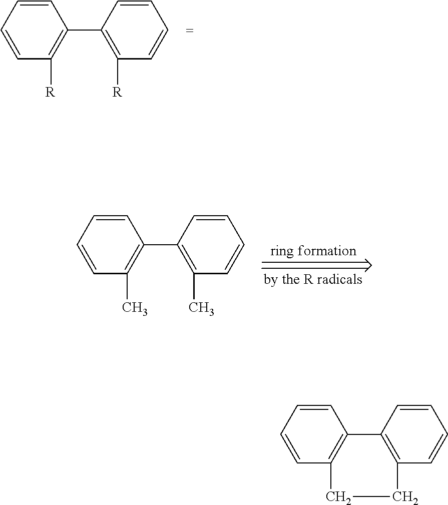

In addition, the abovementioned wording shall also be understood to mean that, if one of the two radicals is hydrogen, the second radical binds to the position to which the hydrogen atom was bonded, forming a ring. This shall be illustrated by the following scheme:

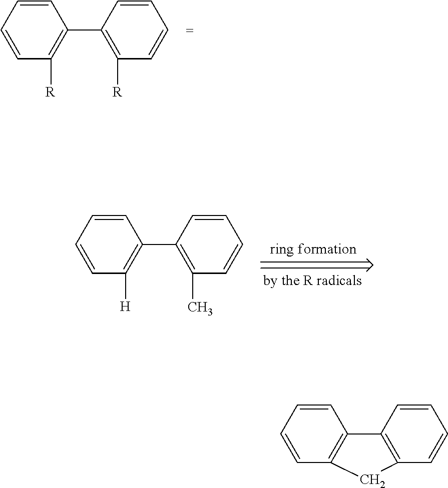

In addition, the abovementioned wording shall also be understood to mean that, if the two radicals are alkenyl groups, the radicals together form a ring, forming a fused-on aryl group. Analogously, the formation of a fused-on benzofuran group is possible in the case of an aryloxy substituent, and the formation of a fused-on indole group in the case of an arylamino substituent. This shall be illustrated by the following schemes:

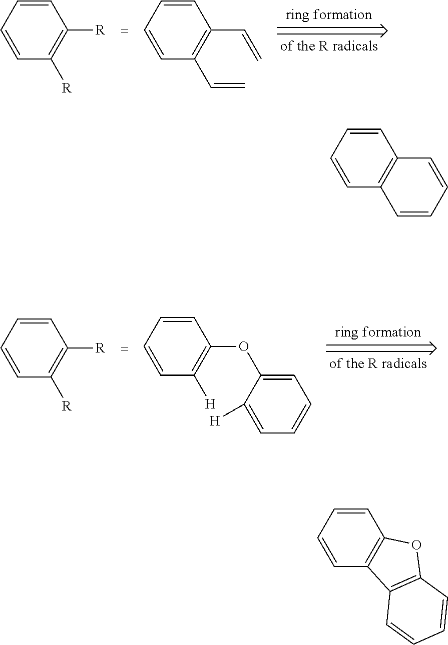

A cyclic alkyl, alkoxy or thioalkoxy group in the context of this invention is understood to mean a monocyclic, bicyclic or polycyclic group.

In the context of the present invention, a C₁- to C₂₀-alkyl group in which individual hydrogen atoms or CH₂ groups may also be replaced by the abovementioned groups is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals. An alkenyl group is understood to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is understood to mean, for example, ethynyl, propynyl, butynyl, pentynyl, hexynyl, heptynyl or octynyl. An OR¹ group is understood to mean, for example, methoxy, trifluoromethoxy, ethoxy, n-propoxy, i-propoxy, n-butoxy, i-butoxy, s-butoxy, t-butoxy or 2-methylbutoxy.

An aryl group in the context of this invention contains 6 to 30 carbon atoms; a heteroaryl group in the context of this invention contains 2 to 30 carbon atoms and at least one heteroatom, with the proviso that the sum total of carbon atoms and heteroatoms is at least 5. The heteroatoms are preferably selected from N, O and/or S. Here, an aryl group or heteroaryl group is understood to mean either a simple aromatic ring, i.e. benzene, or a simple heteroaromatic ring, for example pyridine, pyrimidine, thiophene, etc., or a condensed (fused) aryl or heteroaryl group, for example naphthalene, anthracene, phenanthrene, quinoline, isoquinoline, etc. Aromatic systems joined to one another by a single bond, for example biphenyl, by contrast, are not referred to as an aryl or heteroaryl group but as an aromatic ring system.

An aromatic ring system in the context of this invention contains 6 to 40 carbon atoms, preferably 6 to 30 carbon atoms, in the ring system. A heteroaromatic ring system in the context of this invention contains 2 to 40 carbon atoms, preferably 2 to 30 carbon atoms, and at least one heteroatom in the ring system, with the proviso that the sum total of carbon atoms and heteroatoms is at least 5. The heteroatoms are preferably selected from N, O and/or S. An aromatic or heteroaromatic ring system in the context of this invention shall be understood to mean a system which does not necessarily contain only aryl or heteroaryl groups, but in which it is also possible for two or more aryl or heteroaryl groups to be joined by a nonaromatic unit, for example a carbon, nitrogen or oxygen atom. These shall likewise be understood to mean systems in which two or more aryl or heteroaryl groups are joined directly to one another, for example biphenyl, terphenyl, bipyridine or phenylpyridine. For example, systems such as fluorene, 9,9′-spirobifluorene, 9,9-diarylfluorene, triarylamine, diaryl ethers, stilbene, etc. shall also be regarded as aromatic ring systems in the context of this invention, and likewise systems in which two or more aryl groups are joined, for example, by a short alkyl group. Preferred aromatic or heteroaromatic ring systems are simple aryl or heteroaryl groups and groups in which two or more aryl or heteroaryl groups are joined directly to one another, for example biphenyl or bipyridine, and also fluorene or spirobifluorene.

An aromatic or heteroaromatic ring system which has 5-40 aromatic ring atoms and may also be substituted in each case by the abovementioned R² radicals or a hydrocarbyl radical and which may be joined to the aromatic or heteroaromatic system via any desired positions is understood to mean especially groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole, or groups derived from a combination of these systems.

Preferably, a total of not more than two symbols X in CyC are N, more preferably not more than one symbol X in CyC is N, and most preferably all symbols X are CR, with the proviso that, when the bridge V in formula (2) is bonded to CyC, one symbol X is C and the bridge V is bonded to this carbon atom.

Particularly preferred CyC groups are the groups of the following formulae (CyC-1a) to (CyC-20a):

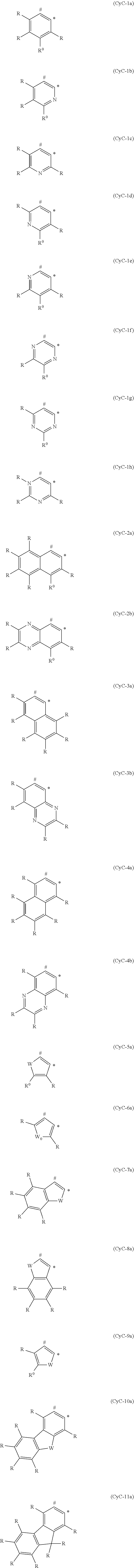

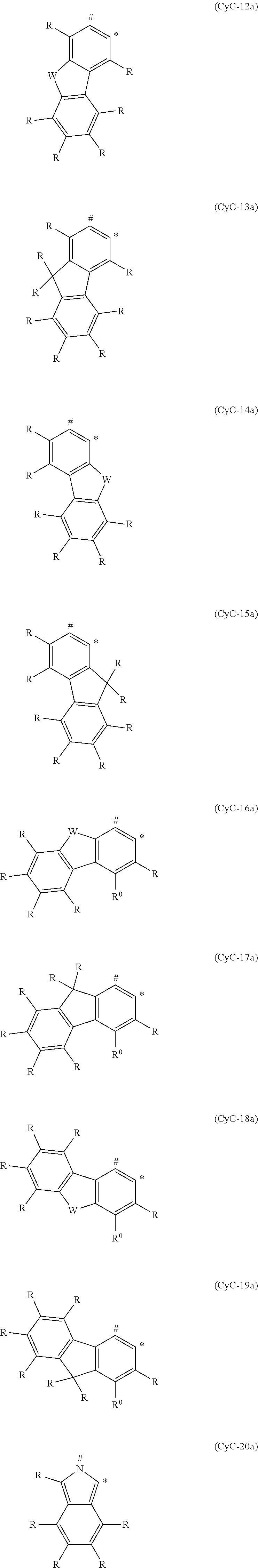

where the symbols used have the definitions given above and, when the bridge V is bonded to CyC in formula (2), one R radical is absent and the bridge V is bonded to the corresponding carbon atom. When the CyC group is bonded to the bridge V, the bond is preferably via the position marked “o” in the formulae depicted above, and so the R radical in this position in that case is preferably absent. The above-depicted structures which do not contain any carbon atom marked “o” are preferably not bonded directly to the bridge V.

Preferred groups among the (CyC-1) to (CyC-19) groups are the (CyC-1), (CyC-3), (CyC-8), (CyC-10), (CyC-12), (CyC-13) and (CyC-16) groups, and particular preference is given to the (CyC-1a), (CyC-3a), (CyC-8a), (CyC-10a), (CyC-12a), (CyC-13a) and (CyC-16a) groups.

In a further preferred embodiment of the invention, CyD is a heteroaryl group having 5 to 13 aromatic ring atoms, more preferably having 6 to 10 aromatic ring atoms, which coordinates to the metal via an uncharged nitrogen atom or via a carbene carbon atom and which may be substituted by one or more R radicals and which is bonded via a covalent bond to CyC.

Preferred embodiments of the CyD group are the structures of the following formulae (CyD-1) to (CyD-18) where the CyD group binds in each case at the position signified by # to CyC and coordinates at the position signified by * to the iridium,

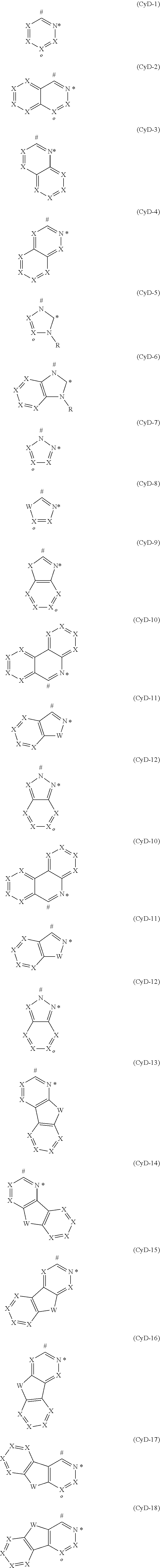

where X, W and R have the definitions given above, with the proviso that, when the bridge V in formula (2) is bonded to CyD, one symbol X is C and the bridge V is bonded to this carbon atom. When the CyD group is bonded to the bridge V, the bond is preferably via the position marked “o” in the formulae depicted above, and so the symbol X marked “o” in that case is preferably C. The above-depicted structures which do not contain any symbol X marked “o” are preferably not bonded directly to the bridge V, since such a bond to the bridge is not advantageous for steric reasons.

In this case, the (CyD-1) to (CyD-4) and (CyD-7) to (CyD-18) groups coordinate to the iridium via an uncharged nitrogen atom, and (CyD-5) and (CyD-6) groups via a carbene carbon atom.

Preferably, a total of not more than two symbols X in CyD are N, more preferably not more than one symbol X in CyD is N, and especially preferably all symbols X are CR, with the proviso that, when the bridge V in formula (2) is bonded to CyD, one symbol X is C and the bridge V is bonded to this carbon atom.

Particularly preferred CyD groups are the groups of the following formulae (CyD-1a) to (CyD-18a):

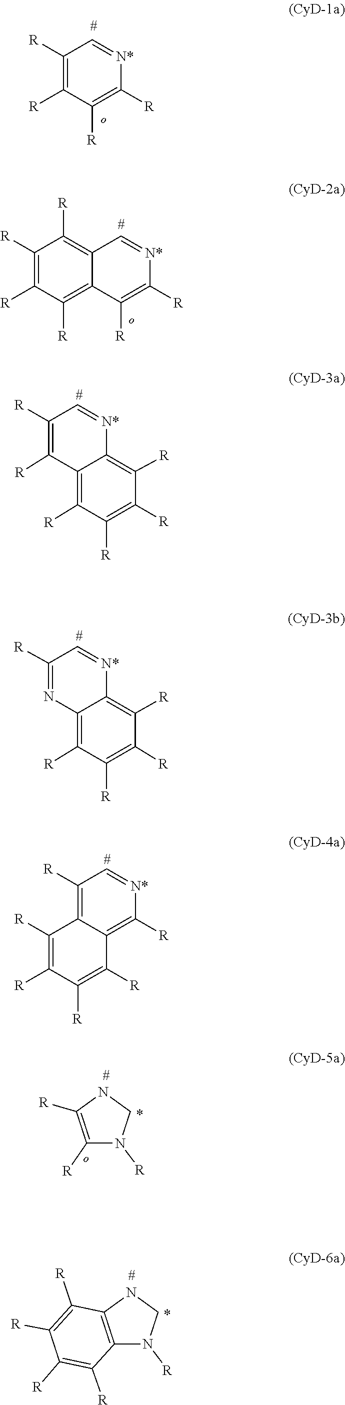

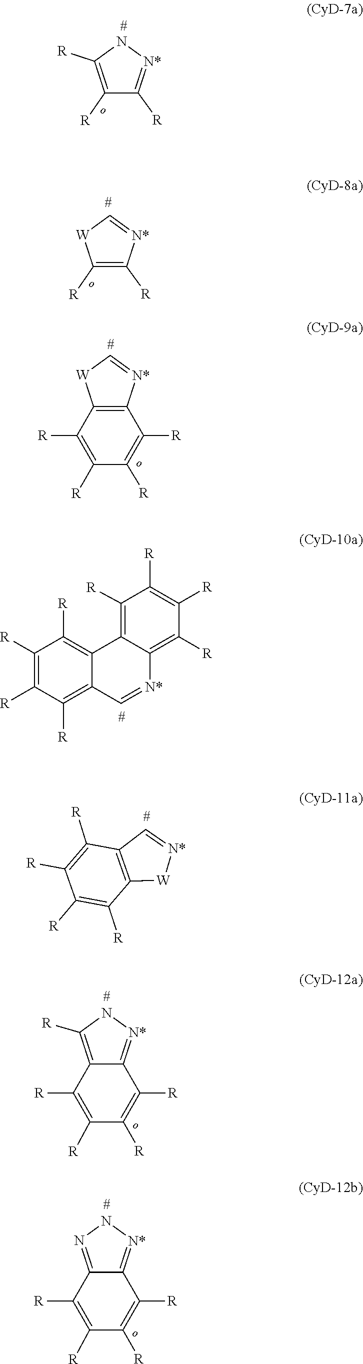

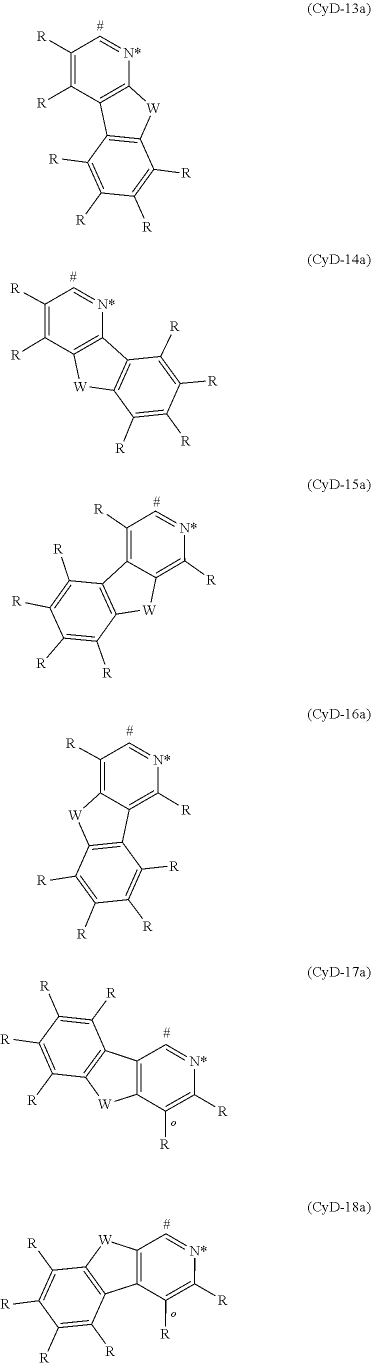

where the symbols used have the definitions given above and, when the bridge V is bonded to CyD in formula (2), one R radical is absent and the bridge V is bonded to the corresponding carbon atom. When the CyD group is bonded to the bridge V, the bond is preferably via the position marked “o” in the formulae depicted above, and so the R radical in this position in that case is preferably absent. The above-depicted structures which do not contain any carbon atom marked “o” are preferably not bonded directly to the bridge V.

Preferred groups among the (CyD-1) to (CyD-12) groups are the (CyD-1), (CyD-2), (CyD-3), (CyD-4), (CyD-5) and (CyD-6) groups, especially (CyD-1), (CyD-2) and (CyD-3), and particular preference is given to the (CyD-1a), (CyD-2a), (CyD-3a), (CyD-4a), (CyD-5a) and (CyD-6a) groups, especially (CyD-1a), (CyD-2a) and (CyD-3a).

In a preferred embodiment of the present invention, CyC is an aryl or heteroaryl group having 6 to 13 aromatic ring atoms, and at the same time CyD is a heteroaryl group having 5 to 13 aromatic ring atoms. More preferably, CyC is an aryl or heteroaryl group having 6 to 10 aromatic ring atoms, and at the same time CyD is a heteroaryl group having 5 to 10 aromatic ring atoms. Most preferably, CyC is an aryl or heteroaryl group having 6 aromatic ring atoms, and CyD is a heteroaryl group having 6 to 10 aromatic ring atoms. At the same time, CyC and CyD may be substituted by one or more R radicals.

The abovementioned preferred groups (CyC-1) to (CyC-20) and (CyD-1) to (CyD-18) may be combined with one another as desired. It is necessary here for compounds of the formula (2) that at least one of the CyC or CyD groups has a suitable linkage site to the bridge V, where suitable linkage sites in the abovementioned formulae are identified by “o”.

It is especially preferable when the CyC and CyD groups mentioned as particularly preferred above, i.e. the groups of the formulae (CyC-1a) to (CyC-20a) and the groups of the formulae (CyD1-a) to (CyD-18a), are combined with one another.

It is very particularly preferable when one of the (CyC-1), (CyC-3), (CyC-8), (CyC-10), (CyC-12), (CyC-13) and (CyC-16) groups, especially the (CyC-1a), (CyC-3a), (CyC-8a), (CyC-10a), (CyC-12a), (CyC-13a) and (CyC-16a) groups, is combined with one of the (CyD-1), (CyD-2) and (CyD-3) groups, especially with one of the (CyD-1a), (CyD-2a) and (CyD-3a) groups.

Preferred sub-ligands (L-1) are the structures of the formulae (L-1-1) and (L-1-2), and preferred sub-ligands (L-2) are the structures of the formulae (L-2-1) to (L-2-4):

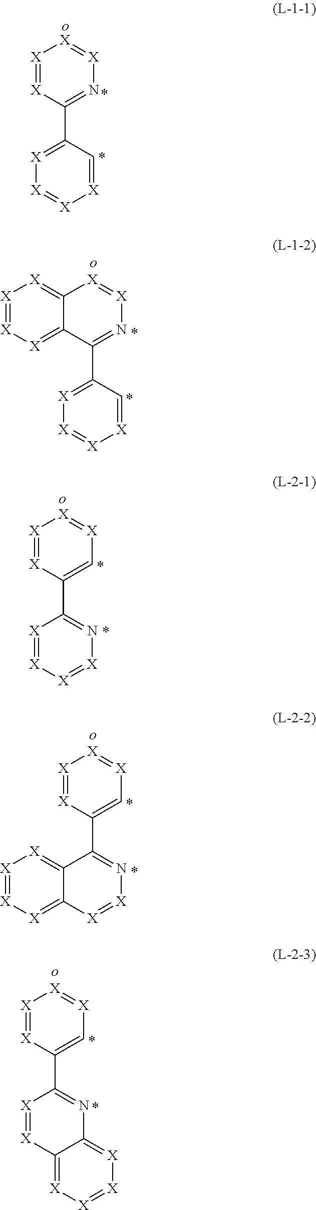

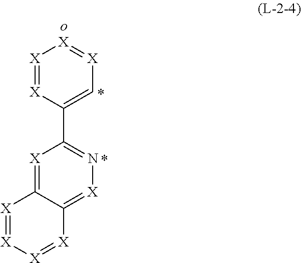

where the symbols used have the definitions given above and “o” in compounds of the formula (2) represents the position of the bond to the bridge V, in which case the corresponding X is C.

Particularly preferred sub-ligands (L-1) are the structures of the formulae (L-1-1a) and (L-1-2b), and particularly preferred sub-ligands (L-2) are the structures of the formulae (L-2-1a) to (L-2-4a)

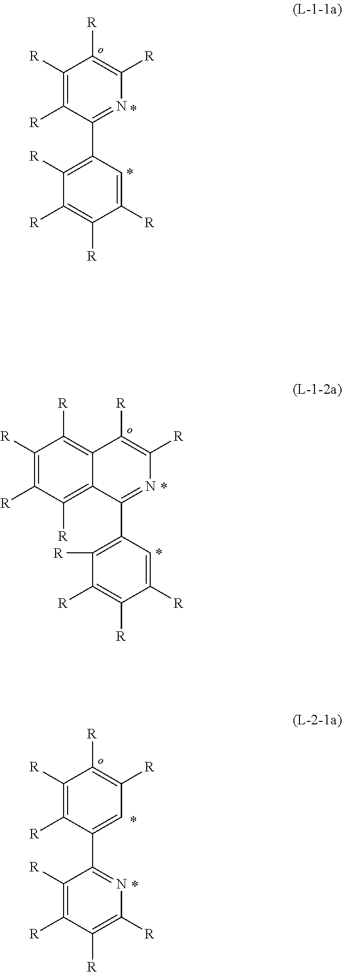

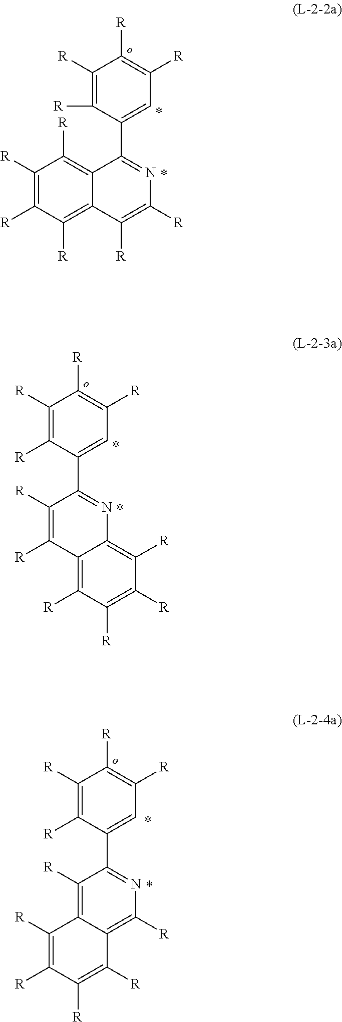

where the symbols used have the definitions given above and “o” in formula (2) represents the position of the bond to the bridge V, in which case the corresponding R radical is absent.

When two R radicals of which one is bonded to CyC and the other to CyD together form an aromatic ring system, this can result in bridged ligands or sub-ligands L¹ or L², in which case some of these bridged sub-ligands overall form a single larger heteroaryl group, for example benzo[h]quinoline, etc. The ring between the substituents on CyC and CyD is preferably formed by a group of one of the following formulae (3) to (12):

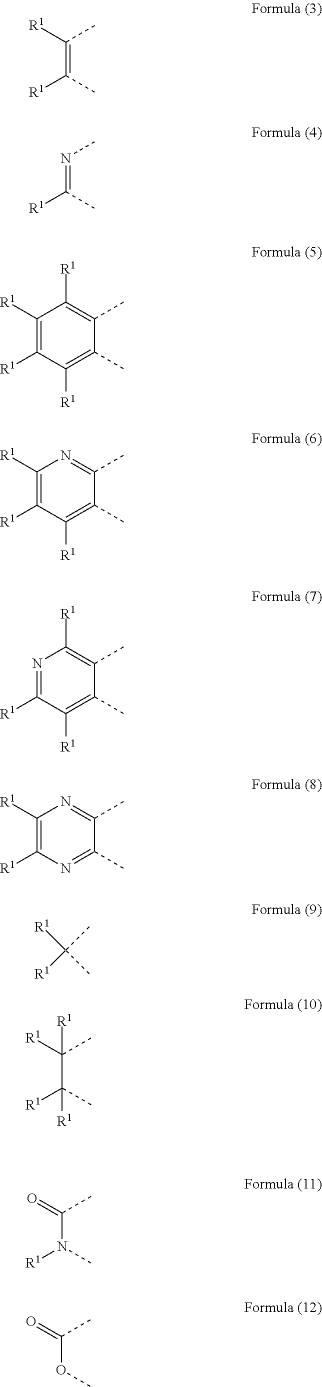

where R¹ has the definitions given above and the dotted bonds signify the bonds to CyC or CyD. It is possible here for the unsymmetric groups among those mentioned above to be incorporated in either of the two ways. For example, in the case of the group of the formula (12), the oxygen atom may bind to the CyC group and the carbonyl group to the CyD group, or the oxygen atom may bind to the CyD group and the carbonyl group to the CyC group.

At the same time, the group of the formula (9) is preferred particularly when this results in ring formation to give a six-membered ring, as shown below, for example, by the formulae (L-21) and (L-22).

Preferred ligands which arise through ring formation between two R radicals on the different cycles are the structures of the formulae (L-3) to (L-30) shown below:

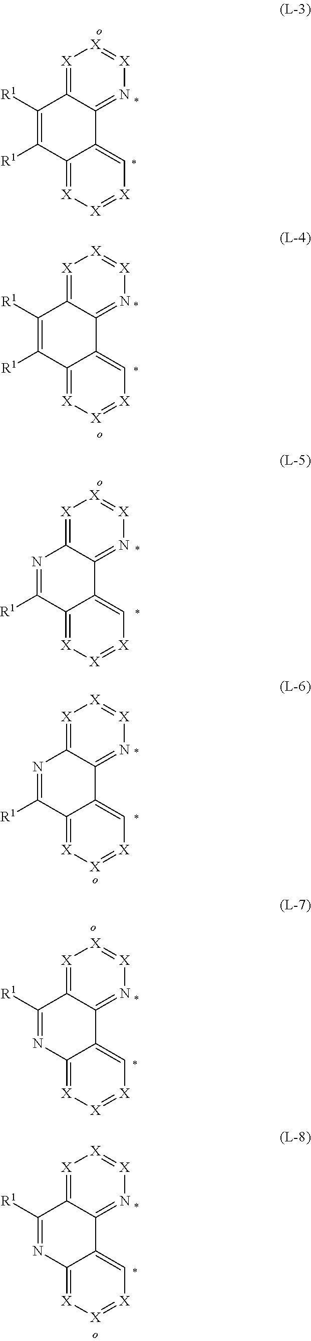

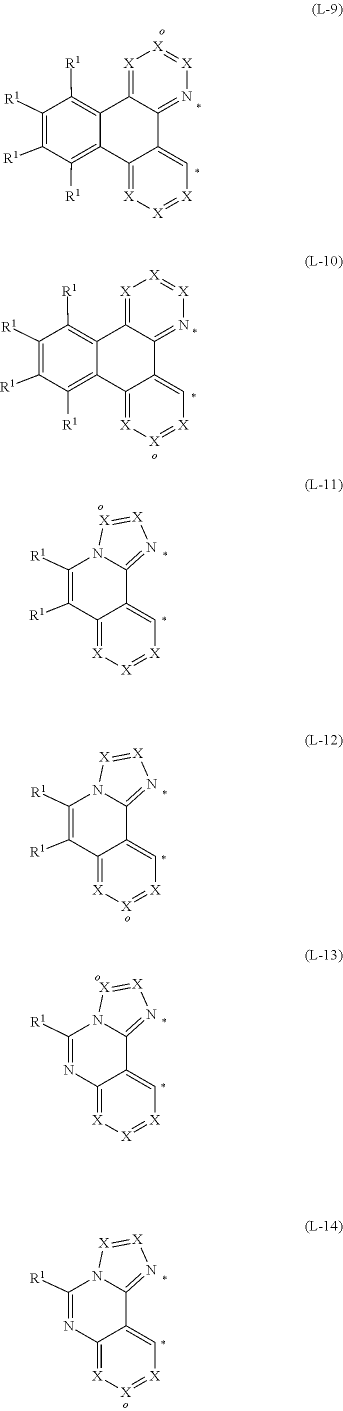

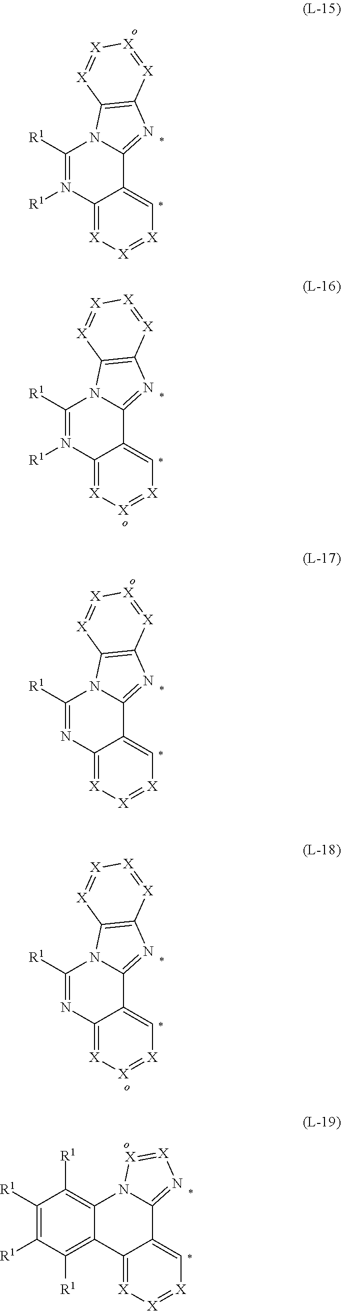

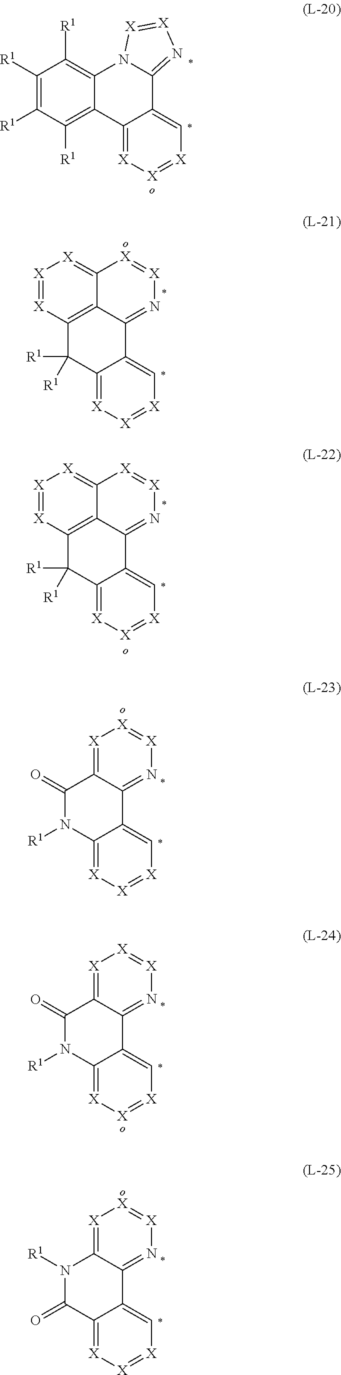

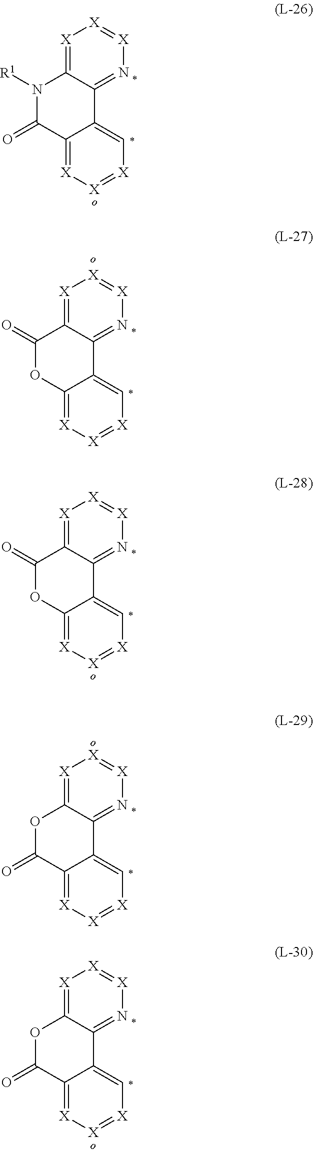

where the symbols used have the definitions given above and “o” in formula (2) indicates the position at which the sub-ligand is joined to the V group.

In a preferred embodiment of the ligands or sub-ligands of the formulae (L-3) to (L-30), a total of one symbol X is N and the other symbols X are CR, or all symbols X are CR.

In a further embodiment of the invention, it is preferable if, in the groups (CyC-1) to (CyC-20) or (CyD-1) to (CyD-18) or in the ligands or sub-ligands (L-3) to (L-30), one of the atoms X is N when an R group bonded as a substituent adjacent to this nitrogen atom is not hydrogen or deuterium. This applies analogously to the preferred structures (CyC-1a) to (CyC-20a) or (CyD-1a) to (CyD-18a) in which a substituent bonded adjacent to a non-coordinating nitrogen atom is preferably an R group which is not hydrogen or deuterium.

In this case, this substituent R is preferably a group selected from CF₃, OCF₃, alkyl groups having 1 to 10 carbon atoms, especially branched or cyclic alkyl groups having 3 to 10 carbon atoms, OR¹ where R¹ is an alkyl group having 1 to 10 carbon atoms, especially a branched or cyclic alkyl group having 3 to 10 carbon atoms, dialkylamino groups having 2 to 10 carbon atoms or aryl or heteroaryl groups having 5 to 10 aromatic ring atoms. These groups are sterically demanding groups. Further preferably, this R radical may also form a cycle with an adjacent R radical.

Further suitable bidentate ligands or sub-ligands are the ligands or sub-ligands of the following formulae (L-31) or (L-32):

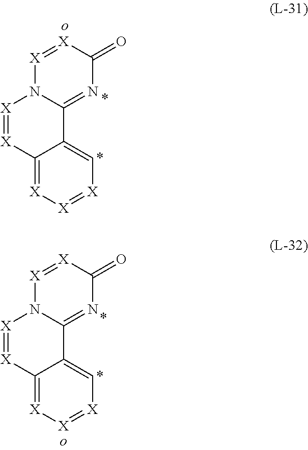

where R has the definitions given above, * represents the position of coordination to the iridium, “o” in formula (2) represents the position of linkage of the sub-ligand to V and the further symbols are as follows:
X is the same or different at each instance and is CR or N, with the proviso that not more than one X symbol per cycle is N.

When two R radicals bonded to adjacent carbon atoms in the ligands or sub-ligands (L-31) and (L-32) form an aromatic cycle with one another, this cycle together with the two adjacent carbon atoms is preferably a structure of the following formula (13):

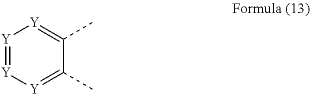

where the dotted bonds symbolize the linkage of this group within the ligand or sub-ligand and Y is the same or different at each instance and is CR¹ or N and preferably not more than one symbol Y is N.

In a preferred embodiment of the ligand or sub-ligand (L-31) or (L-32), not more than one such fused-on group is present. The ligands or sub-ligands are thus preferably of the following formulae (L-33) to (L-38):

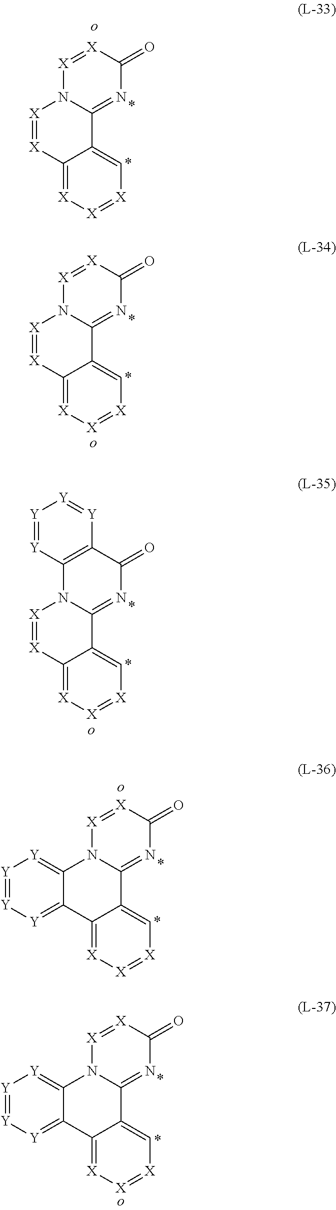

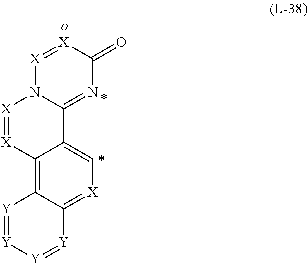

where X is the same or different at each instance and is CR or N, but the R radicals together do not form an aromatic or heteroaromatic ring system and the further symbols have the definitions given above.

In a preferred embodiment of the invention, in the ligand or sub-ligand of the formulae (L-31) to (L-38), a total of 0, 1 or 2 of the symbols X and, if present, Y are N. More preferably, a total of 0 or 1 of the symbols X and, if present, Y are N. Preferred embodiments of the formulae (L-33) to (L-38) are the structures of the following formulae (L-33a) to (L-38f):

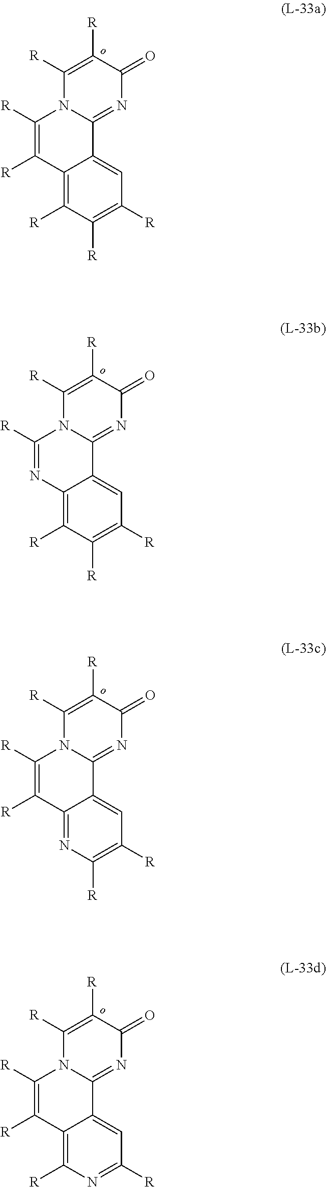

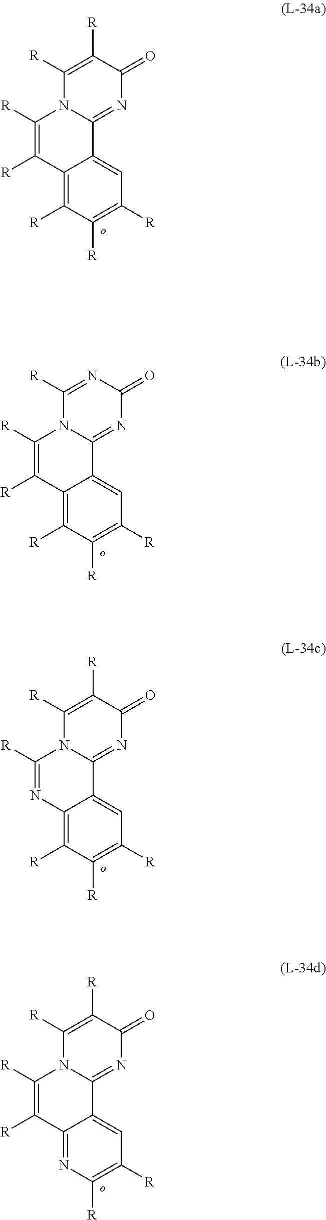

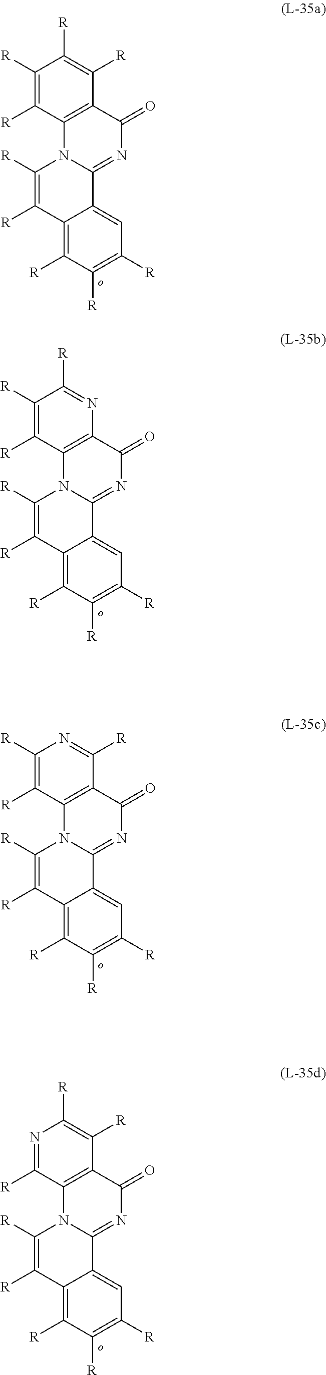

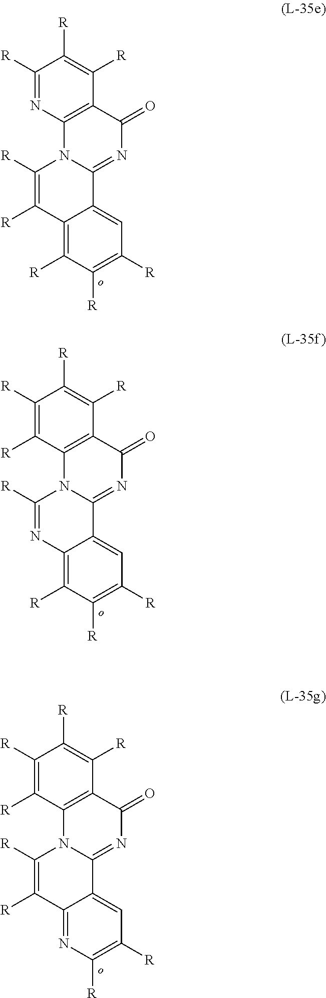

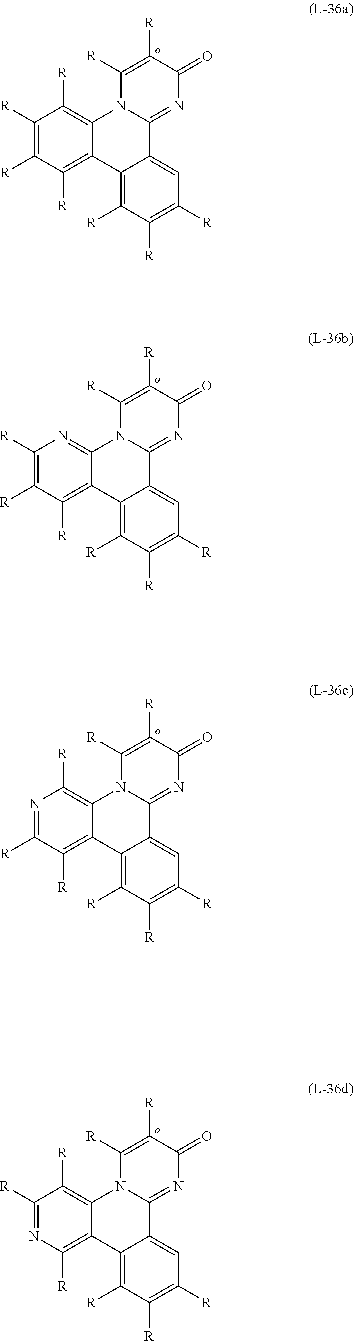

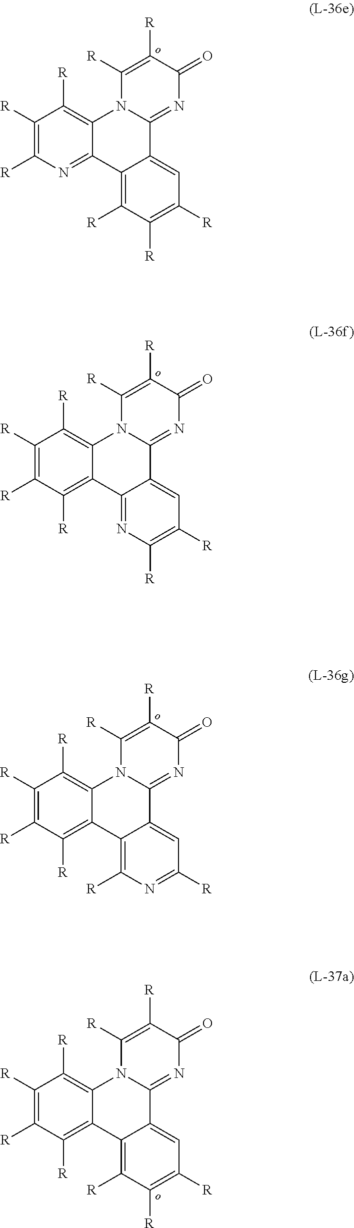

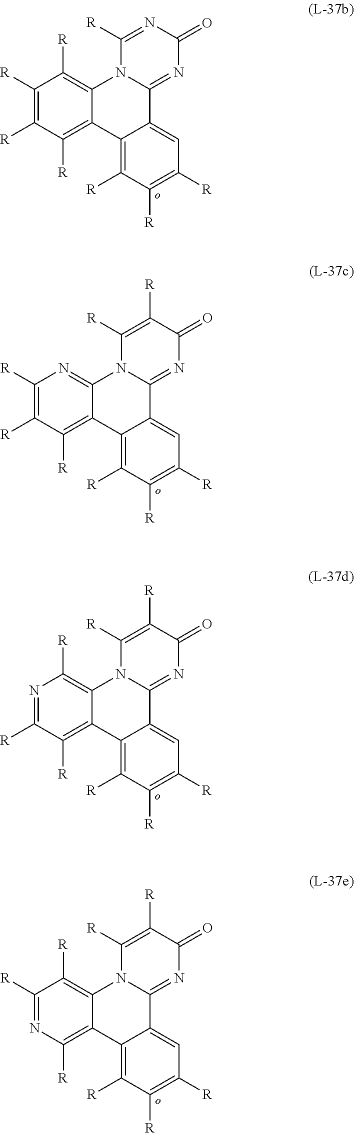

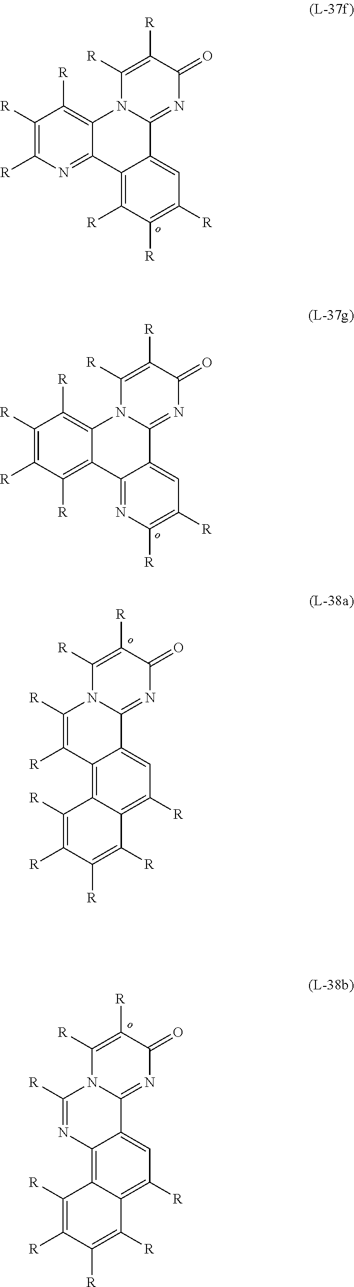

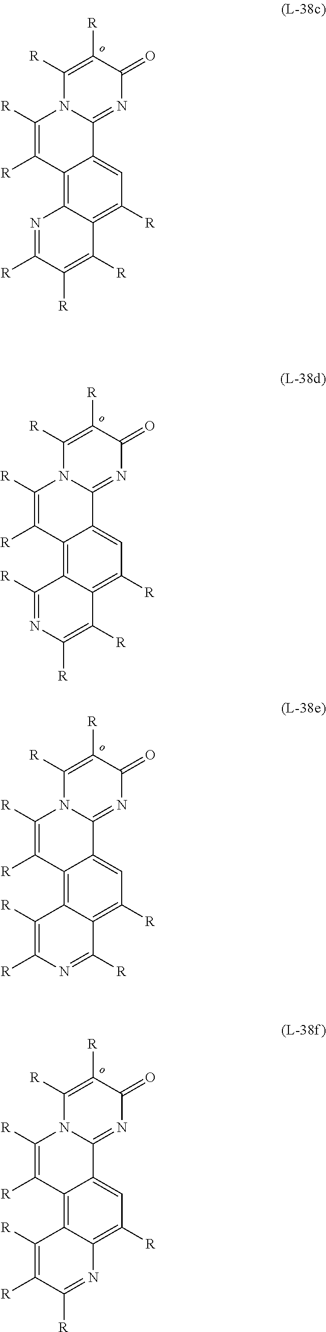

where the symbols used have the definitions given above and “o” indicates the position of the linkage to the bridge V, in which case the corresponding R group is absent.

In a preferred embodiment of the invention, the X group in the ortho position to the coordination to the metal is CR. In this radical, R bonded in the ortho position to the coordination to the metal is preferably selected from the group consisting of H, D, F and methyl.

In a further embodiment of the invention, it is preferable if one of the atoms X is N when a substituent bonded adjacent to this nitrogen atom is an R group which is not H or D. In this case, this substituent R is preferably a group selected from CF₃, OCF₃, alkyl groups having 1 to 10 carbon atoms, especially branched or cyclic alkyl groups having 3 to 10 carbon atoms, OR¹ where R¹ is an alkyl group having 1 to 10 carbon atoms, especially a branched or cyclic alkyl group having 3 to 10 carbon atoms, dialkylamino groups having 2 to 10 carbon atoms or aryl or heteroaryl groups having 5 to 10 aromatic ring atoms. These groups are sterically demanding groups. Further preferably, this R radical may also form a cycle with an adjacent R radical.

In a preferred embodiment of the invention, L_{act} is a ligand or sub-ligand of the following formula (L-39) that coordinates to the iridium via the two D groups and which, when the complex is one of the formula (2), is bonded to V via the dotted bond, in which case the corresponding X is C:

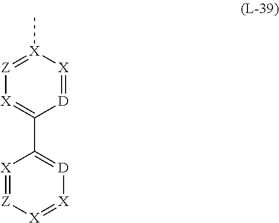

where:
D is C or N, with the proviso that one D is C and the other D is N;
X is the same or different at each instance and is CR or N;
Z is CR′, CR or N, with the proviso that exactly one Z is CR′ and the other Z is CR or N;
where a maximum of one symbol X or Z per cycle is N;
R′ is a group of the following formula (14) or (15):

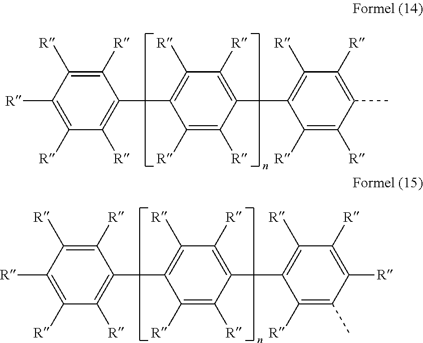

where the dotted bond indicates the attachment of the group;
R″ is the same or different at each instance and is H, D, F, CN, a straight chain alkyl group having 1 to 10 carbon atoms in which one or more hydrogen atoms may also be replaced by D or F, or a branched or cyclic alkyl group having 3 to 10 carbon atoms in which one or more hydrogen atoms may also be replaced by D or F, or an alkenyl group having 2 to 10 carbon atoms in which one or more hydrogen atoms may also be replaced by D or F; at the same time, two adjacent R″ radicals or two R″ radicals on adjacent phenyl groups together may also form a ring system; or two R″ on adjacent phenyl groups together are a group selected from C(R¹)₂, NR¹, O and S, such that the two phenyl rings together with the bridging group are a carbazole, dibenzofuran or dibenzothiophene, and the further R″ are as defined above;
n is 0, 1, 2, 3, 4 or 5.

In the case of ring formation by two substituents R″ on adjacent phenyl groups, the result may also be a fluorene or a phenanthrene or a triphenylene. It is likewise possible, as described above, for two R″ on adjacent phenyl groups together to be a group selected from NR¹, O and S, such that the two phenyl rings together with the bridging group are a carbazole, dibenzofuran or dibenzothiophene.

In a preferred embodiment of the invention, X is the same or different at each instance and is CR. Further preferably, one Z group is CR and the other Z group is CR′. More preferably, in the ligand or sub-ligand of the formula (L-39), the X groups are the same or different at each instance and are CR, and at the same time one Z group is CR and the other Z group is CR′. The ligand or sub-ligand L¹ preferably has a structure of one of the following formulae (L-39a) or (L-39b), where the linkage to the bridge V for polypodal structures of the formula (L-39) is via the position identified by “o” and no R radical is bonded at this position,

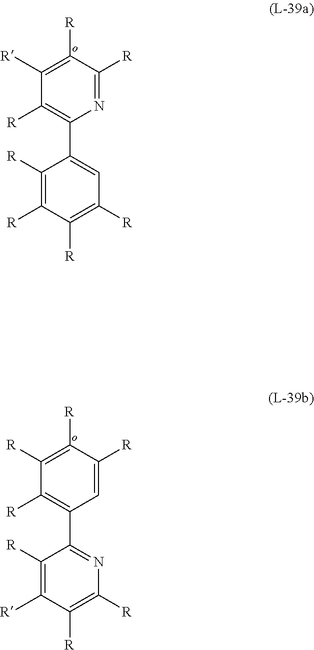

where the symbols used have the meanings given above.

More preferably, the sub-ligand L of the formula (L-39) has a structure of one of the following formulae (L-39a′) or (L-39b′), where the linkage to the bridge V for polypodal structures of the formula (L-39) is via the position identified by “o” and no R radical is bonded at this position,

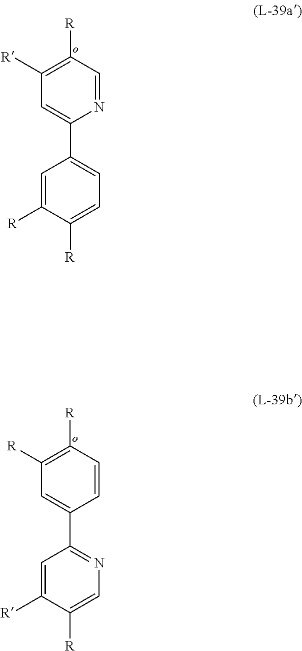

where the symbols used have the meanings given above.

The R radicals in the sub-ligand L_{act} of the formula (L-39) or formulae (L-39a), (L-39b), (L-39a′) and (L-39d′) are preferably selected from the group consisting of H, D, CN, OR¹, a straight-chain alkyl group having 1 to 6 carbon atoms, preferably having 1 to 3 carbon atoms, or a branched or cyclic alkyl group having 3 to 6 carbon atoms or an alkenyl group having 2 to 6 carbon atoms, preferably 2 to 4 carbon atoms, each of which may be substituted by one or more R¹ radicals, or a phenyl group which may be substituted by one or more nonaromatic R¹ radicals. It is also possible here for two or more adjacent R radicals together to form a ring system.

In this case, the substituent R bonded to the coordinating atom in the ortho position is preferably selected from the group consisting of H, D, F and methyl, more preferably H, D and methyl and especially H and D.

In addition, it is preferable when all substituents R that are in the ortho position to R′ are H or D.

When the R radicals in the sub-ligand L_{act} of the formula (L-39) together form a ring system, it is preferably an aliphatic, heteroaliphatic or heteroaromatic ring system. In addition, preference is given to ring formation between two R radicals on the two rings of the sub-ligand L_{act}, preferably forming a phenanthridine, or a phenanthridine which may contain still further nitrogen atoms. When R radicals together form a heteroaromatic ring system, this preferably forms a structure selected from the group consisting of quinoline, isoquinoline, dibenzofuran, dibenzothiophene and carbazole, each of which may be substituted by one or more R¹ radicals, and where individual carbon atoms in the dibenzofuran, dibenzothiophene and carbazole may also be replaced by N. Particular preference is given to quinoline, isoquinoline, dibenzofuran and azadibenzofuran. It is possible here for the fused-on structures to be bonded in any possible position. Preferred sub-ligands L₁ with fused-on benzo groups are the structures of the formulae (L-39c) to (L-39j) listed below, where the linkage to the bridge V for polypodal structures of the formula (L-39) is via the position identified by a dotted bond:

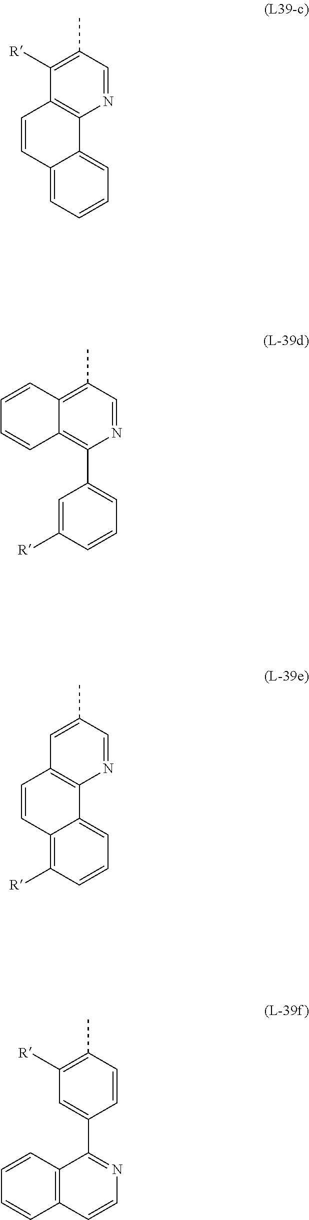

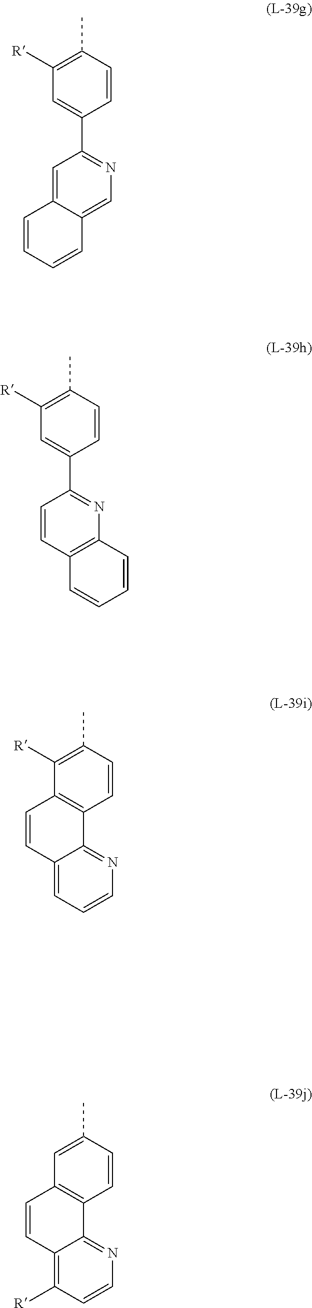

where the ligands may each also be substituted by one or more further R radicals and the fused-on structure may be substituted by one or more R¹ radicals.

Preferably, there are no further R or R¹ radicals present.

Preferred sub-ligands L_{act} of the formula (L-39) with fused-on benzofuran or azabenzofuran groups are the structures of the formulae (L-39k) to (L-39z) listed below, where the linkage to the bridge V for polypodal structures of the formula (L-39) is via the position identified by a dotted bond and no R radical is bonded to this position:

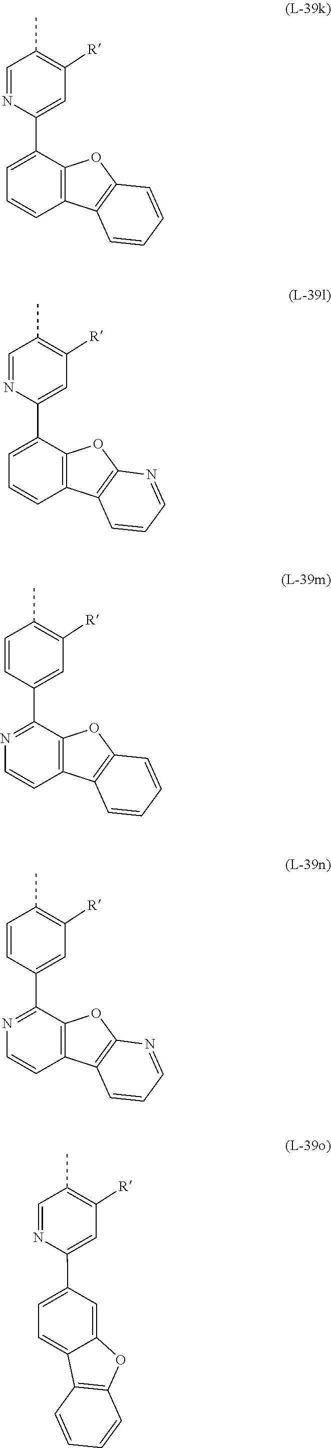

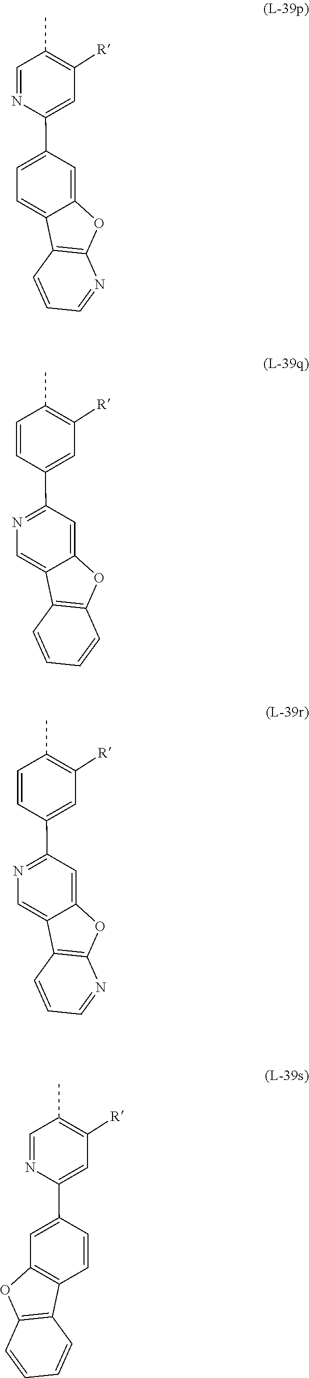

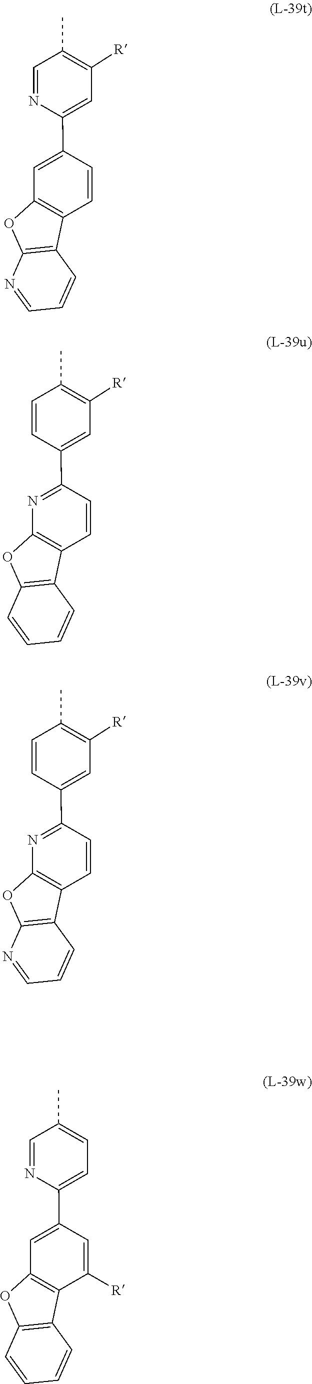

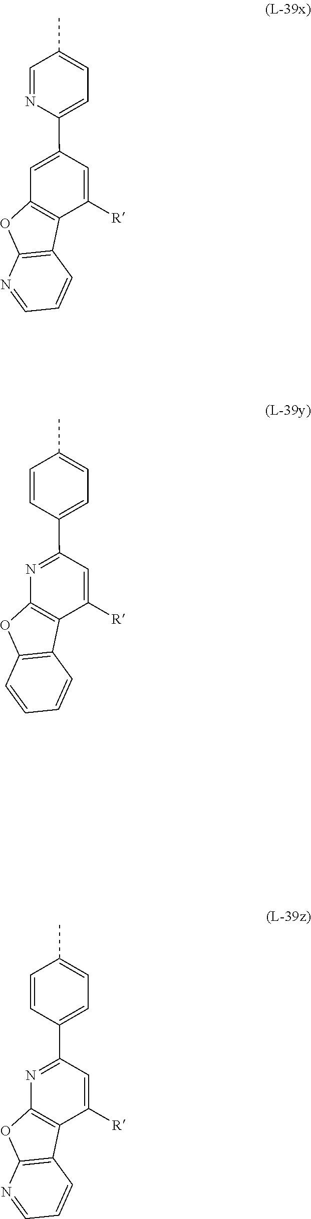

where the ligands may each also be substituted by one or more further R radicals and the fused-on structure may be substituted by one or more R¹ radicals. Preferably, there are no further R or R¹ radicals present. It is likewise possible for O in these structures to be replaced by S or NR¹.

As described above, R′ is a group of the formula (14) or (15). The two groups here differ merely in that the group of the formula (14) is bonded to the ligand or sub-ligand L¹ in the para position and the group of the formula (15) in the meta position.

In a preferred embodiment of the invention, n=0, 1 or 2, preferably 0 or 1 and most preferably 0.

In a further preferred embodiment of the invention, both substituents R″ bonded in the ortho positions to the carbon atom by which the group of the formula (14) or (15) is bonded to the phenylpyridine ligands are the same or different and are H or D.

Preferred embodiments of the structure of the formula (14) are the structures of the formulae (14a) to (14h), and preferred embodiments of the structure of the formula (15) are the structures of the formulae (15a) to (15h):

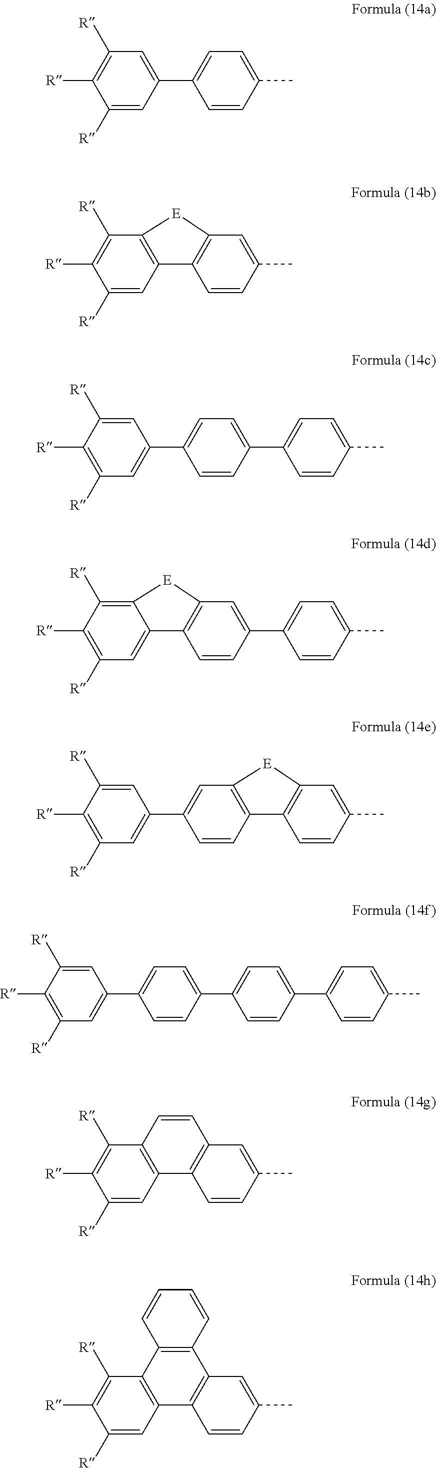

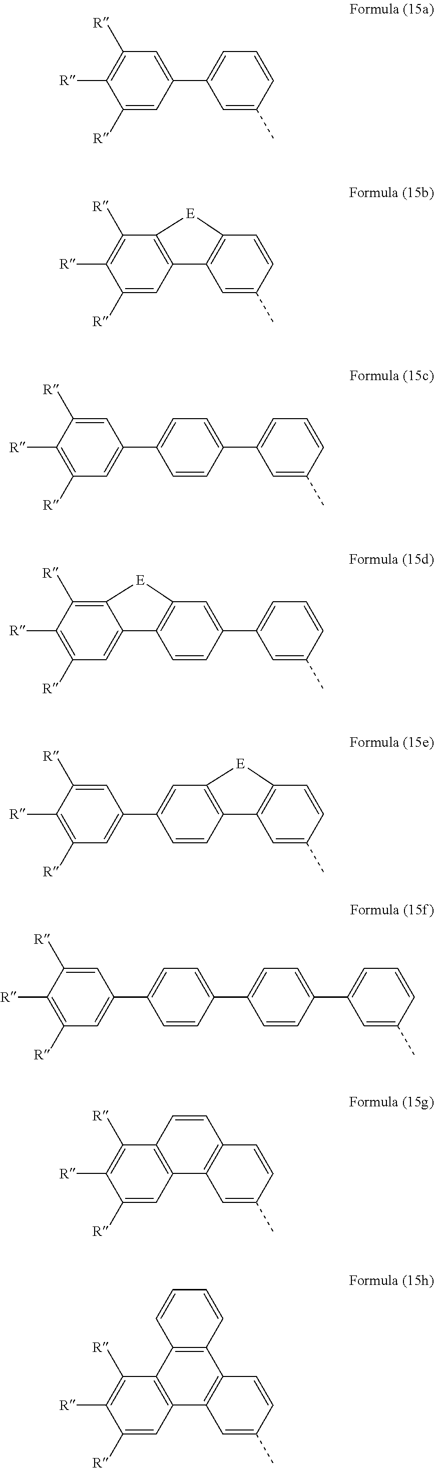

where E is C(R¹)₂, NR¹, O or S and the further symbols used have the definitions given above. R¹ here, when E=C(R¹)₂, is preferably the same or different at each instance and is an alkyl group having 1 to 6 carbon atoms, preferably having 1 to 4 carbon atoms, more preferably methyl. In addition, when E=NR¹, R¹ is preferably an aromatic or heteroaromatic ring system having 5 to 30 aromatic ring atoms, preferably having 6 to 24 aromatic ring atoms, more preferably having 6 to 12 aromatic ring atoms, especially phenyl.

Preferred substituents R″ on the groups of the formula (14) or (15) or the preferred embodiments are selected from the group consisting of H, D, CN and an alkyl group having 1 to 4 carbon atoms, more preferably H, D or methyl.

The complexes of the formula (2) are complexes having a tripodal hexadentate ligand, where the three sub-ligands L_{act} and L are covalently bonded to one another by a bridging unit V. These have the advantage over complexes of the formula (1) that they have a higher stability through the covalent linkage of the sub-ligands Laca and L.

In a preferred embodiment of the invention, the bridging unit V is a group of the following formula (16), where the dotted bonds represent the position of the linkage of the sub-ligands L_{act} and L:

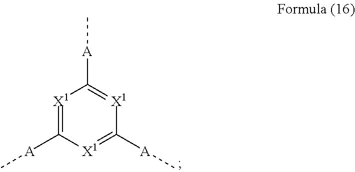

where:
X¹ is the same or different at each instance and is CR or N;
X² is the same or different at each instance and is CR or N;
A is the same or different at each instance and is CR₂—CR₂, CR₂—O, CR₂—NR, C(═O)—O, C(═O)—NR or a group of the following formula (17):

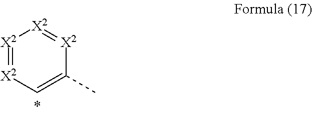

where the dotted bond in each case represents the position of the bond of the bidentate sub-ligands L_{act} or L to this structure, * represents the position of the linkage of the unit of the formula (17) to the central trivalent aryl or heteroaryl group.

Preferred substituents in the group of the formula (17) when X²═CR are selected from the above-described substituents R.

In a preferred embodiment of the invention, A is the same or different at each instance and is CR₂—CR₂ or a group of the formula (17). Preference is given here to the following embodiments:
all three A groups are the same group of the formula (17);
two A groups are the same group of the formula (17), and the third A group is CR₂—CR₂;
one A group is a group of the formula (17), and the two other A groups are the same CR₂—CR₂ group; or
all three A groups are the same CR₂—CR₂ group.

What is meant here by “the same group of the formula (17)” is that these groups all have the same base skeleton and the same substitution. Moreover, what is meant by “the same CR₂—CR₂ group” is that these groups all have the same substitution. When A is CR₂—CR₂, R is preferably the same or different at each instance and is H or D, more preferably H.

The group of the formula (17) is an aromatic or heteroaromatic six-membered ring. In a preferred embodiment of the invention, the group of the formula (17) contains not more than one heteroatom in the aryl or heteroaryl group. This does not mean that any substituents bonded to this group cannot also contain heteroatoms. In addition, this definition does not mean that formation of rings by substituents does not give rise to fused aromatic or heteroaromatic structures, for example naphthalene, benzimidazole, etc. The group of the formula (17) is preferably selected from benzene, pyridine, pyrimidine, pyrazine and pyridazine.

Preferred embodiments of the group of the formula (17) are the structures of the following formulae (18) to (25):

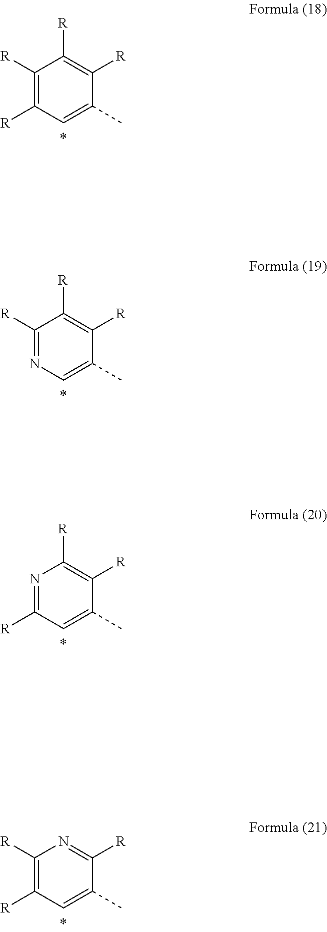

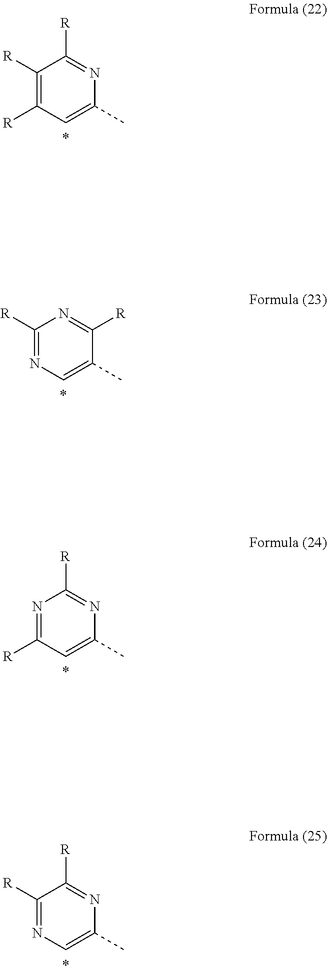

where the symbols used have the meanings given above.

Particular preference is given to the optionally substituted six-membered aromatic rings and six-membered heteroaromatic rings of the formulae (18) to (22). Very particular preference is given to ortho-phenylene, i.e. a group of the formula (18).

At the same time, as also detailed above in the description of the substituent, it is also possible for adjacent substituents together to form a ring system, such that fused structures, including fused aryl and heteroaryl groups, for example naphthalene, quinoline, benzimidazole, carbazole, dibenzofuran or dibenzothiophene, can form.

Stated hereinafter are preferred embodiments of the bridgehead V, i.e. the structure of the formula (16). Preferred embodiments of the group of the formula (16) are the structures of the following formulae (26) to (29):

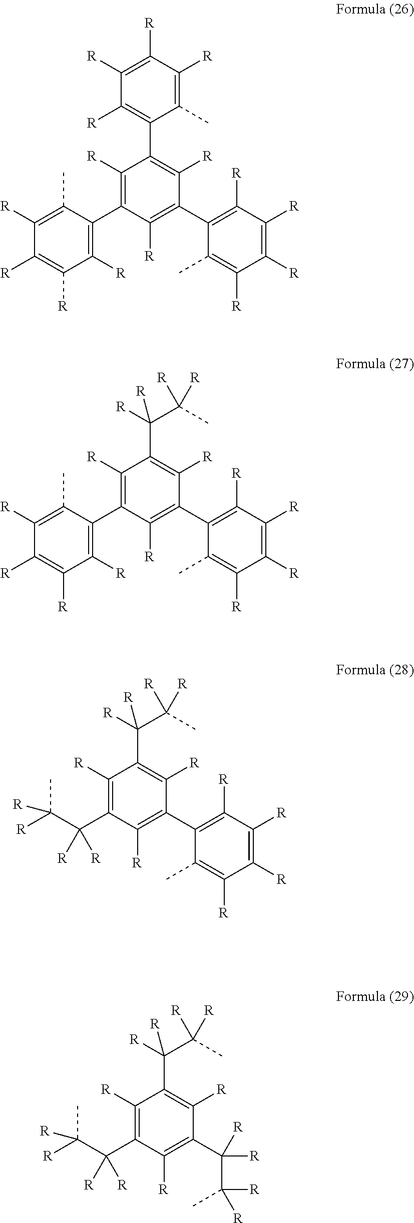

where the symbols used have the meanings given above.

More preferably, all substituents R in the central ring of the formulae (26) to (29) are H, and so the structures are preferably selected from the formulae (26a) to (29a)

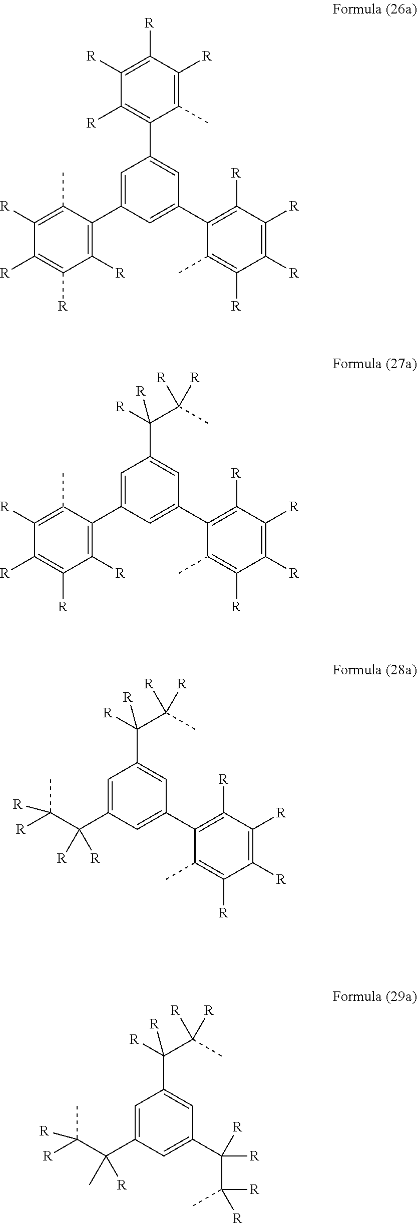

where the symbols used have the meanings given above.

More preferably, the groups of the formulae (26) to (29) are selected from the structures of the following formulae (26b) to (29b):

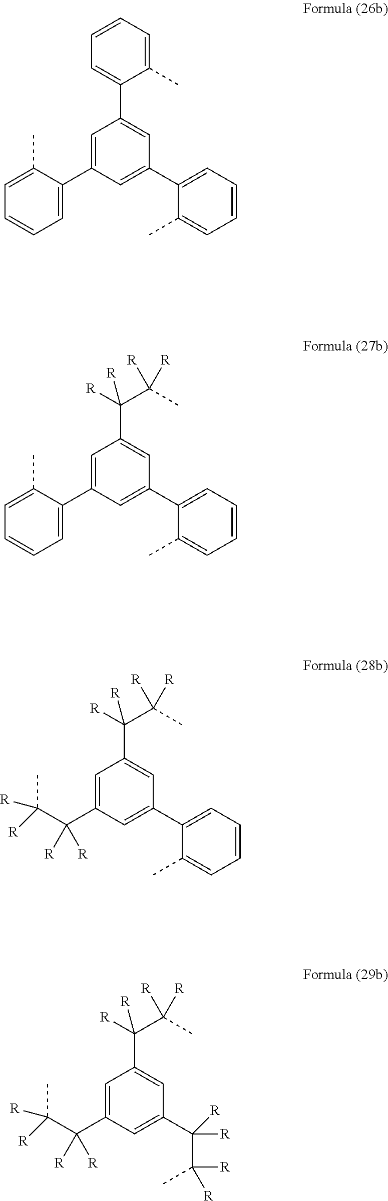

where R is the same or different at each instance and is H or D, preferably H.

Further examples of suitable bridgeheads V are the structures depicted below:

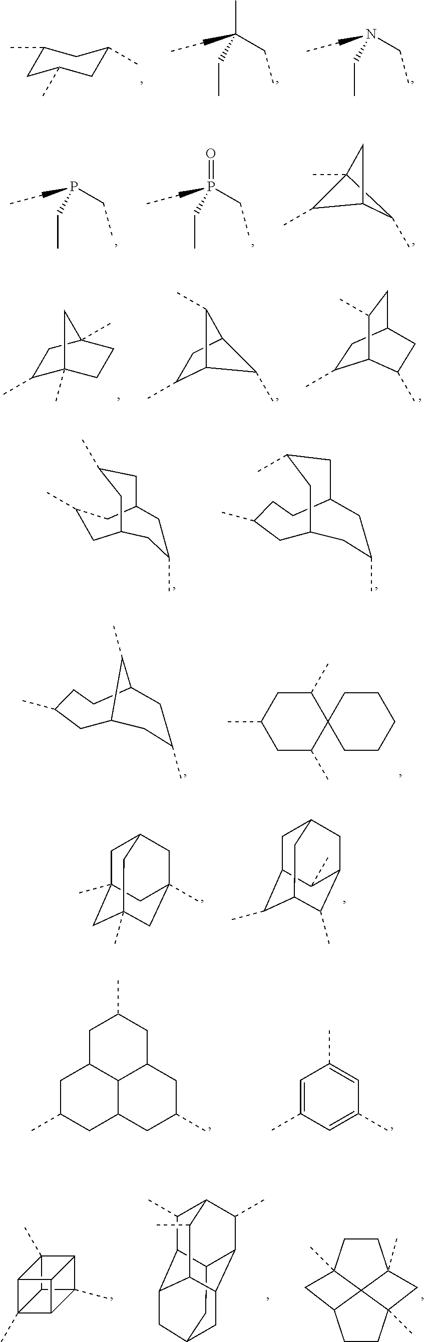

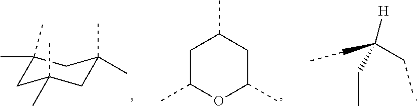

There follows a description of preferred substituents as may be present on the above-described sub-ligands L_{act} and/or L, but also on the bivalent arylene or heteroarylene group in the structure of the formula (16), i.e. in the structure of the formula (17).

In a further embodiment of the invention, the metal complex of the invention contains two R substituents or two R¹ substituents which are bonded to adjacent carbon atoms and together form an aliphatic ring according to one of the formulae described hereinafter. In this case, the two R substituents which form this aliphatic ring may be present on the bridge of the formula (16) and/or on one or more of the bidentate sub-ligands. The aliphatic ring which is formed by the ring formation by two R substituents together or by two R¹ substituents together is preferably described by one of the following formulae (30) to (36):

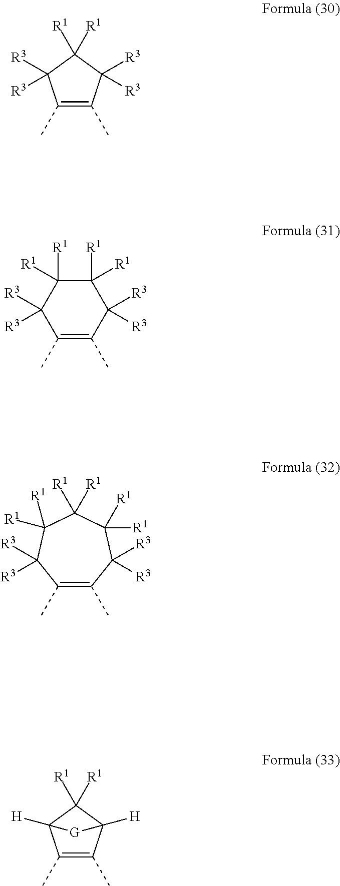

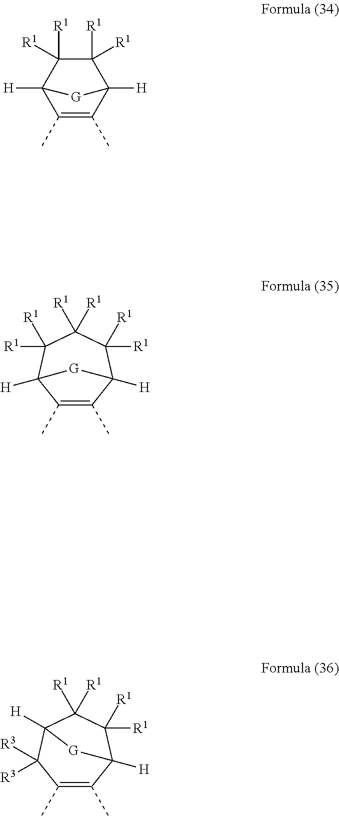

where R¹ and R² have the definitions given above, the dotted bonds signify the attachment of the two carbon atoms in the ligand, and in addition:
G is an alkylene group which has 1, 2 or 3 carbon atoms and may be substituted by one or more R² radicals, —CR²═CR²— or an ortho-bonded arylene or heteroarylene group which has 5 or 6 aromatic ring atoms and may be substituted by one or more R² radicals;
R³ is the same or different at each instance and is H, F, OR², a straight-chain alkyl group having 1 to 10 carbon atoms, a branched or cyclic alkyl group having 3 to 10 carbon atoms, where the alkyl group in each case may be substituted by one or more R² radicals, where one or more nonadjacent CH₂ groups may be replaced by R²C═CR², C═C, Si(R²)₂, C═O, NR², O, S or CONR², or an aryl or heteroaryl group which has 5 or 6 aromatic ring atoms and may be substituted in each case by one or more R² radicals; at the same time, two R³ radicals which are bonded to the same carbon atom may together form an aliphatic ring system and thus form a spiro system; in addition, R³ with an adjacent R or R¹ radical may form an aliphatic ring system.

In the above-depicted structures of the formulae (30) to (36) and the further embodiments of these structures specified as preferred, a double bond is depicted in a formal sense between the two carbon atoms. This is a simplification of the chemical structure when these two carbon atoms are incorporated into an aromatic or heteroaromatic system and hence the bond between these two carbon atoms is formally between the bonding level of a single bond and that of a double bond.

Preferred embodiments of the groups of the formulae (30) to (36) can be found in patent applications WO 2014/023377, WO 2015/104045 and WO 2015/117718.

When R radicals are bonded within the bidentate ligands or sub-ligands L_{act} or L or within the bivalent arylene or heteroarylene groups of the formula (17) bonded within the formula (16) or the preferred embodiments, these R radicals are the same or different at each instance and are preferably selected from the group consisting of H, D, F, Br, I, N(R¹)₂, CN, Si(R¹)₃, B(OR¹)₂, C(═O)R¹, a straight-chain alkyl group having 1 to 10 carbon atoms or an alkenyl group having 2 to 10 carbon atoms or a branched or cyclic alkyl group having 3 to 10 carbon atoms, where the alkyl or alkenyl group may be substituted in each case by one or more R¹ radicals, or a phenyl group which may be substituted by one or more nonaromatic R¹ radicals, or a heteroaryl group which has 5 or 6 aromatic ring atoms and may be substituted by one or more nonaromatic R¹ radicals; at the same time, two adjacent R radicals together or R together with R¹ may also form a mono- or polycyclic, aliphatic or aromatic ring system. More preferably, these R radicals are the same or different at each instance and are selected from the group consisting of H, D, F, N(R¹)₂, a straight-chain alkyl group having 1 to 6 carbon atoms or a branched or cyclic alkyl group having 3 to 10 carbon atoms, where one or more hydrogen atoms may be replaced by D or F, or a phenyl group which may be substituted by one or more nonaromatic R¹ radicals, or a heteroaryl group which has 6 aromatic ring atoms and may be substituted by one or more nonaromatic R¹ radicals; at the same time, two adjacent R radicals together or R together with R¹ may also form a mono- or polycyclic, aliphatic or aromatic ring system.

Preferred R¹ radicals bonded to R are the same or different at each instance and are H, D, F, N(R²)₂, CN, a straight-chain alkyl group having 1 to 10 carbon atoms or an alkenyl group having 2 to 10 carbon atoms or a branched or cyclic alkyl group having 3 to 10 carbon atoms, where the alkyl group may be substituted in each case by one or more R² radicals, or a phenyl group which may be substituted by one or more R² radicals, or a heteroaryl group which has 5 or 6 aromatic ring atoms and may be substituted by one or more R² radicals; at the same time, two or more adjacent R¹ radicals together may form a mono- or polycyclic aliphatic ring system. Particularly preferred R¹ radicals bonded to R are the same or different at each instance and are H, F, CN, a straight-chain alkyl group having 1 to 5 carbon atoms or a branched or cyclic alkyl group having 3 to 5 carbon atoms, each of which may be substituted by one or more R² radicals, or a phenyl group which may be substituted by one or more R² radicals, or a heteroaryl group which has 5 or 6 aromatic ring atoms and may be substituted by one or more R² radicals; at the same time, two or more adjacent R¹ radicals together may form a mono- or polycyclic aliphatic ring system.

Preferred R² radicals are the same or different at each instance and are H, F or an aliphatic hydrocarbyl radical having 1 to 5 carbon atoms or an aromatic hydrocarbyl radical having 6 to 12 carbon atoms; at the same time, two or more R² substituents together may also form a mono- or polycyclic aliphatic ring system.

The abovementioned preferred embodiments are combinable with one another as desired within the limits of claim 1. In a particularly preferred embodiment of the invention, the abovementioned preferred embodiments apply simultaneously.

The iridium complexes of the invention are chiral structures. Both the tripodal complexes and the heteroleptic complexes of bidentate sub-ligands of the IrL₂L′ or IrLL′L″ type have C, symmetry. If the tripodal ligand of the complexes is additionally also chiral or bears three different sub-ligands (analogously in the case of the heteroleptic complexes with three different sub-ligands, i.e. of the IrLL′L″ type), the formation of diastereomers and multiple pairs of enantiomers is possible.

In that case, the complexes of the invention include both the mixtures of the different diastereomers or the corresponding racemates and the individual isolated diastereomers or enantiomers.

Examples of suitables emitters for the emitting layer having an emission maximum wavelength λ_{BGY} from 450 to 585 nm are the emitters depicted in the table below:

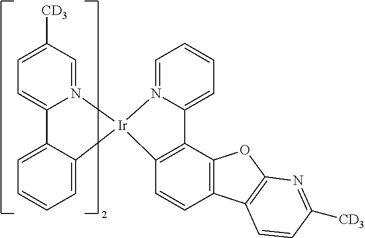

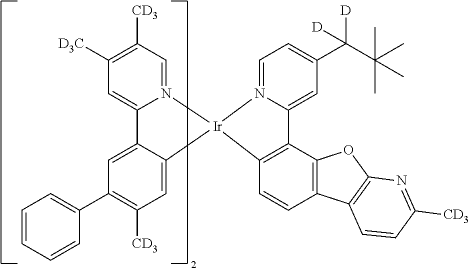

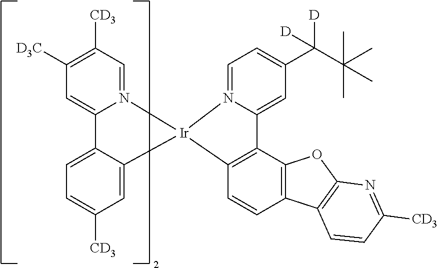

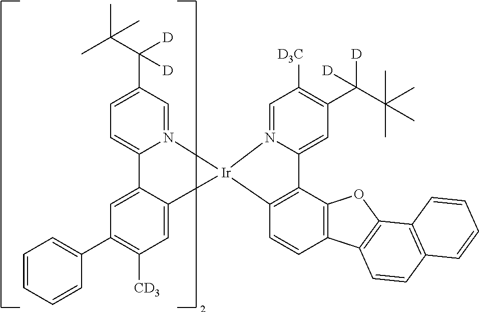

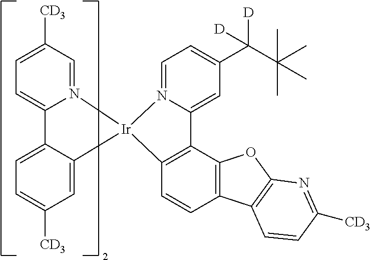

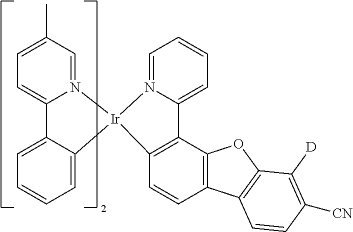

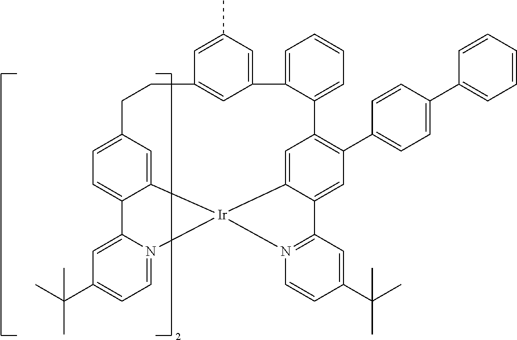

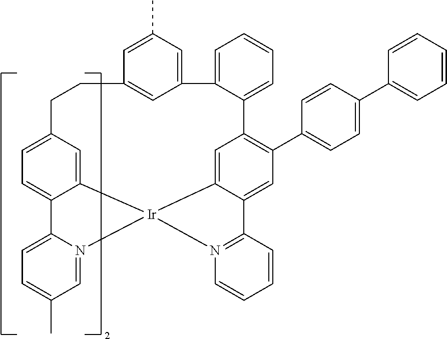

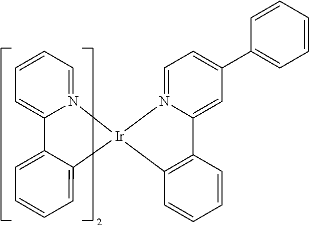

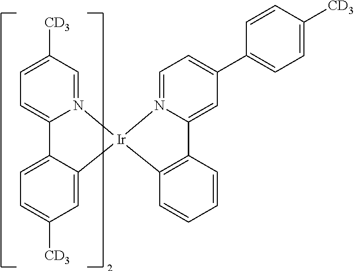

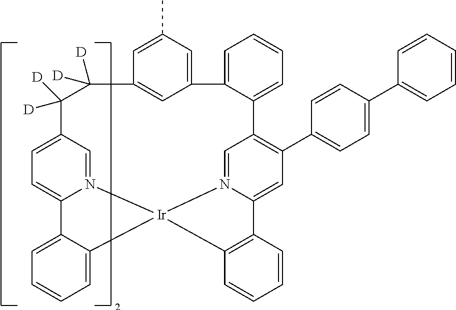

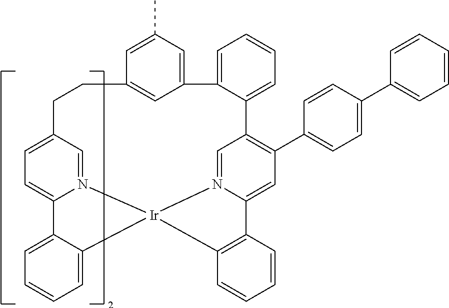

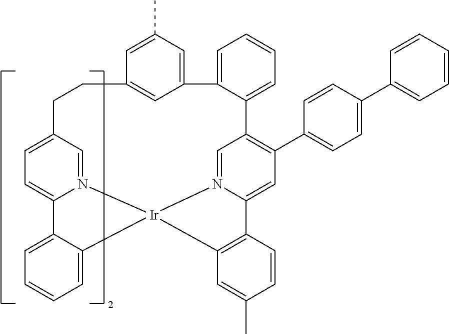

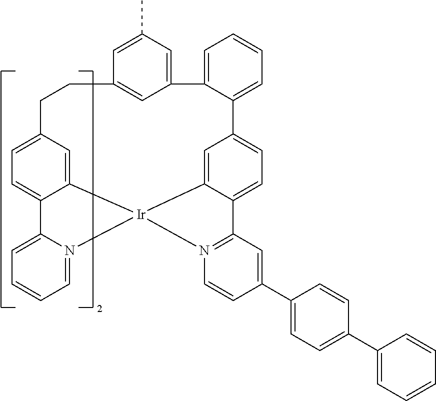

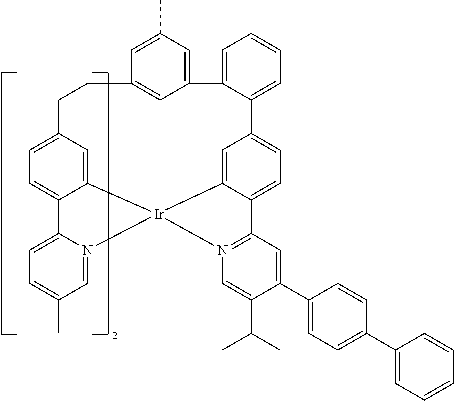

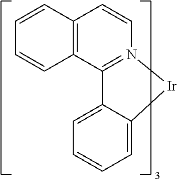

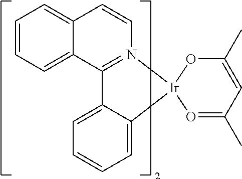

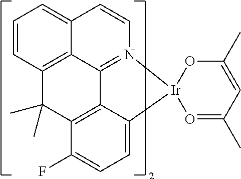

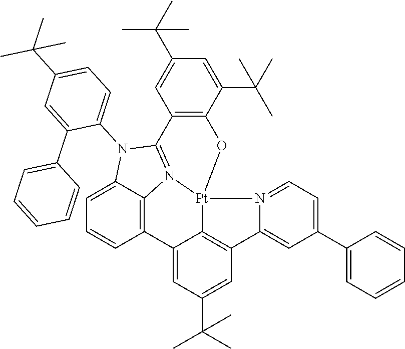

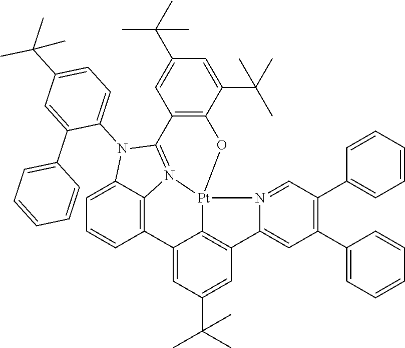

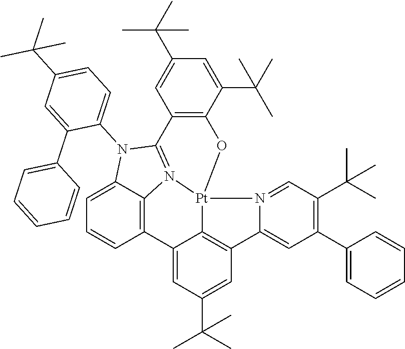

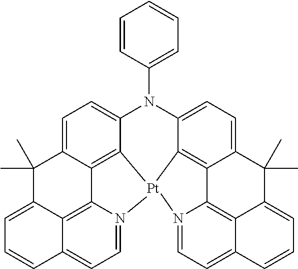

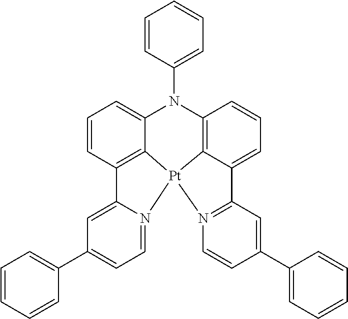

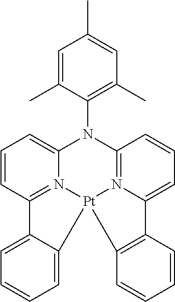

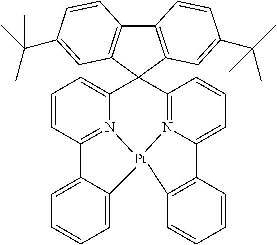

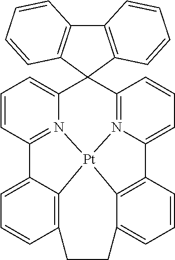

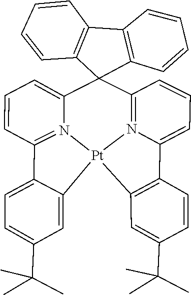

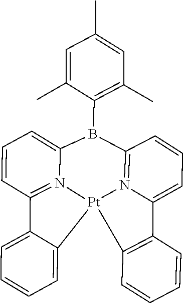

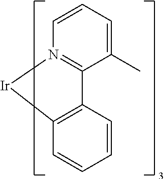

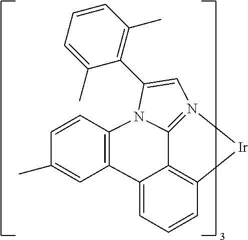

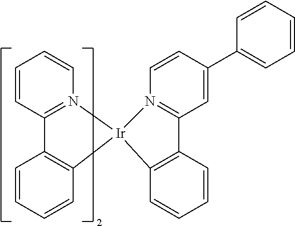

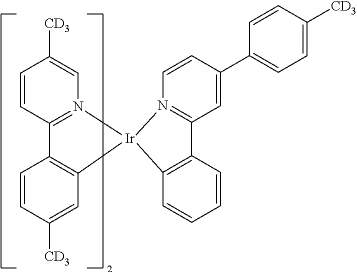

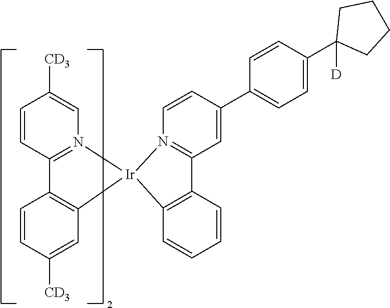

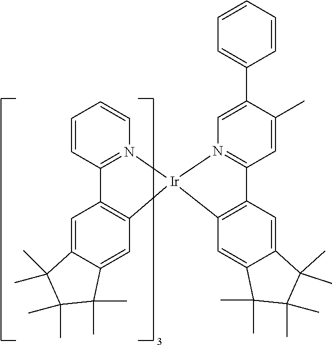

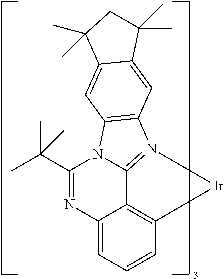

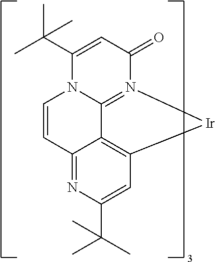

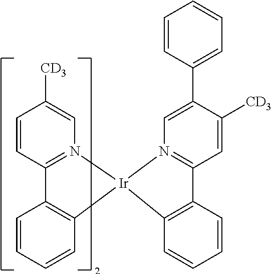

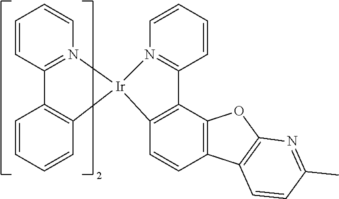

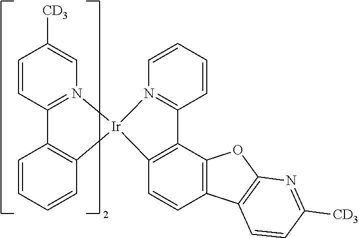

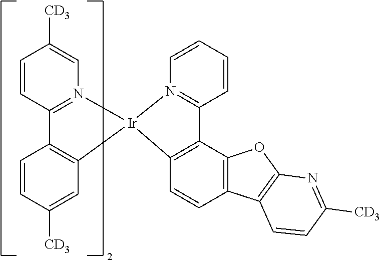

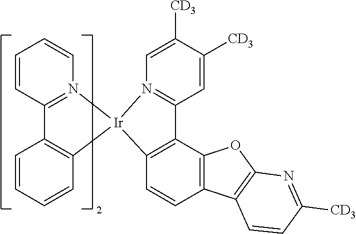

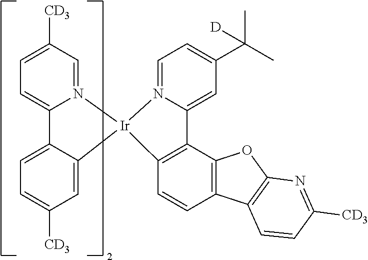

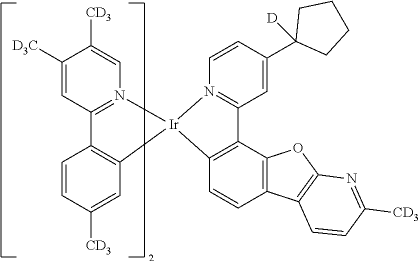

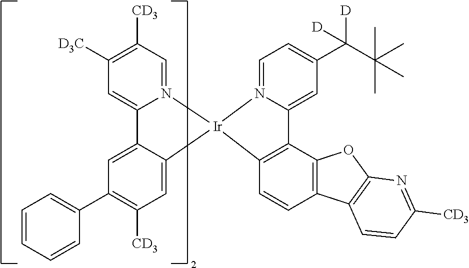

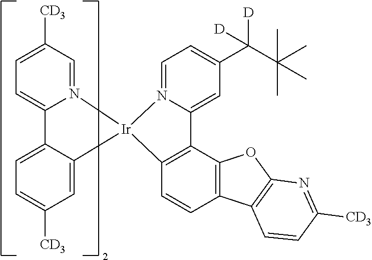

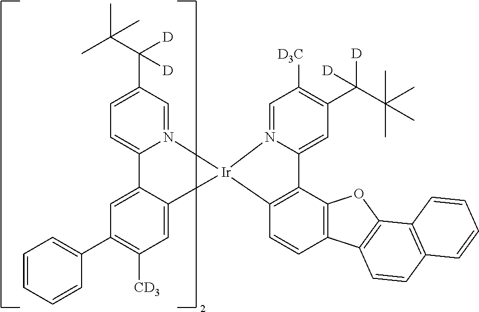

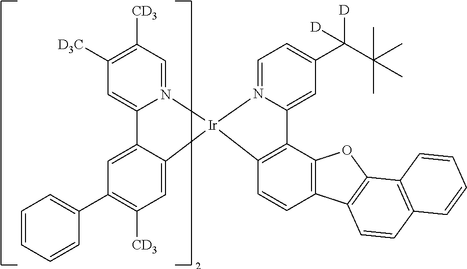

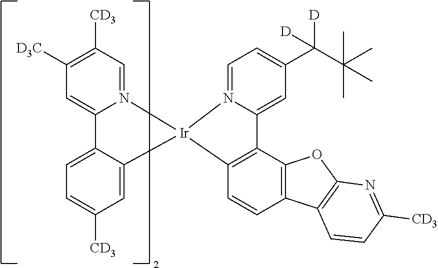

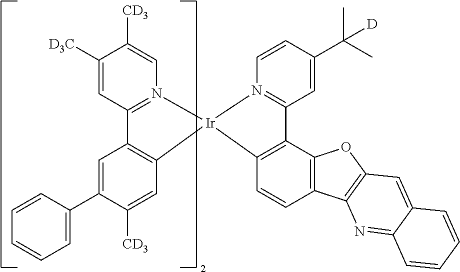

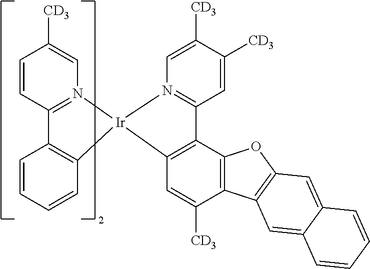

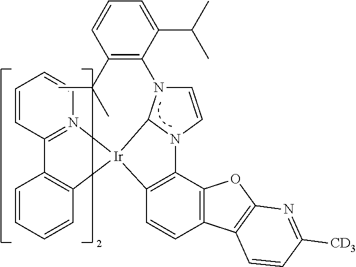

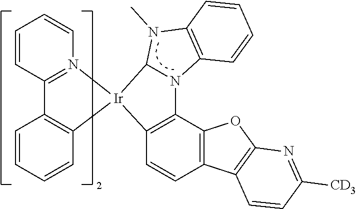

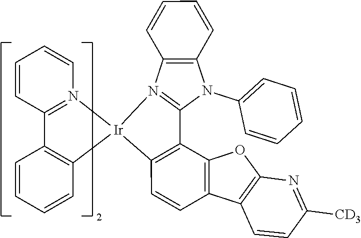

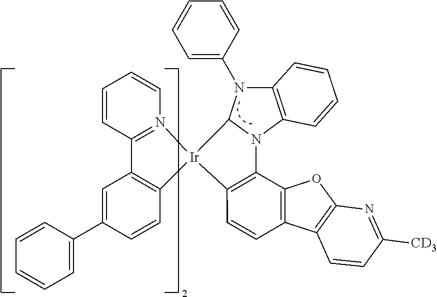

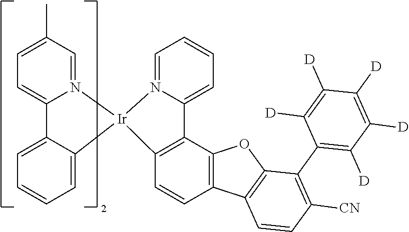

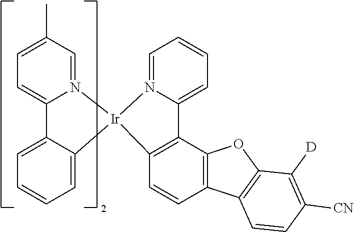

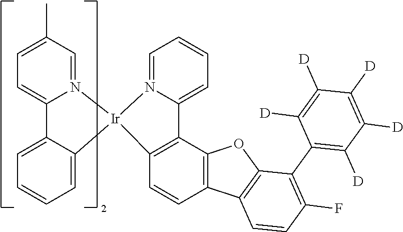

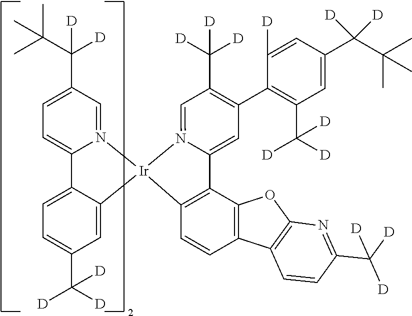

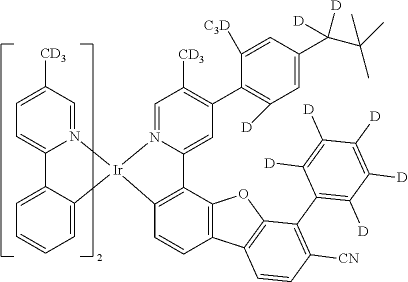

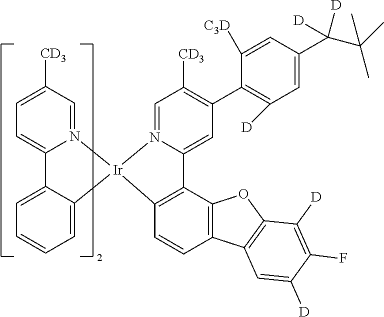

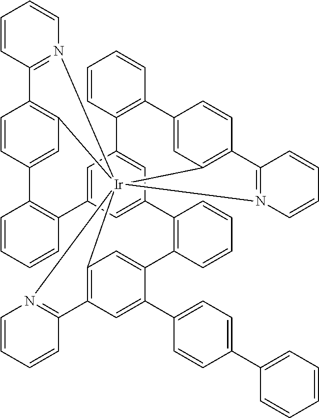

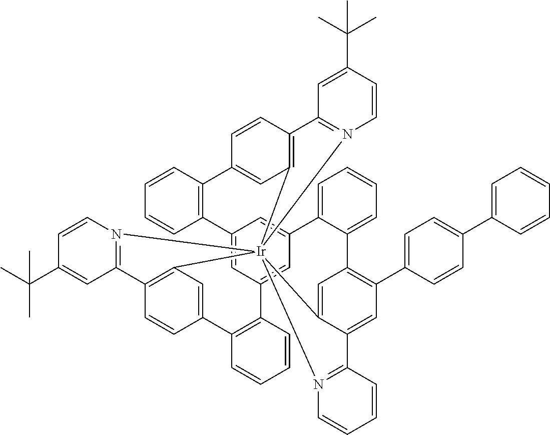

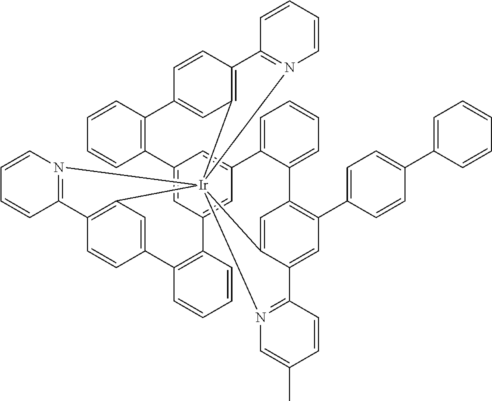

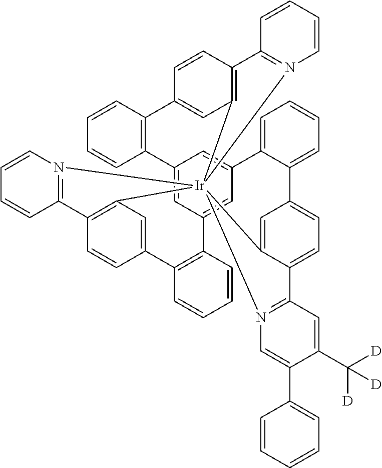

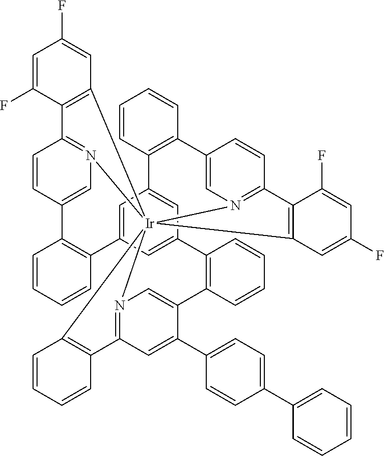

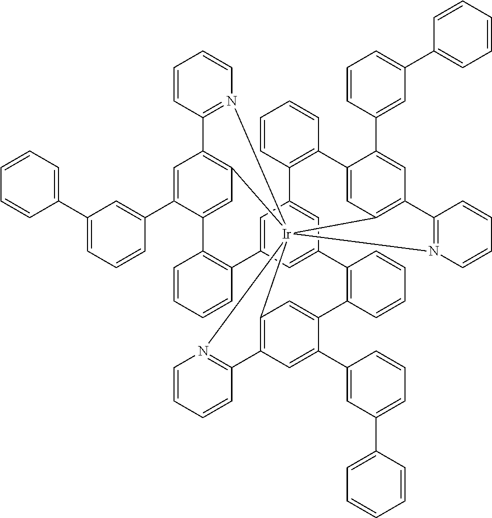

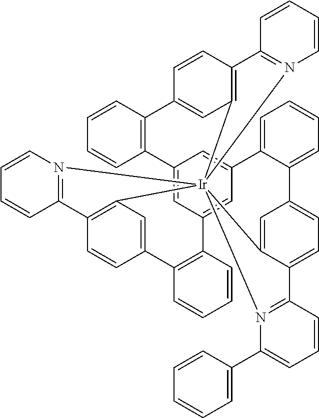

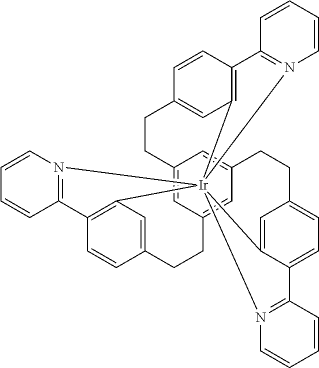

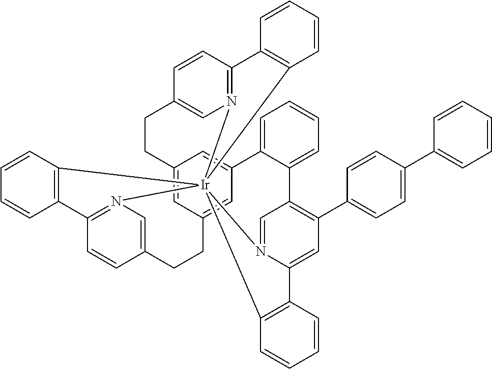

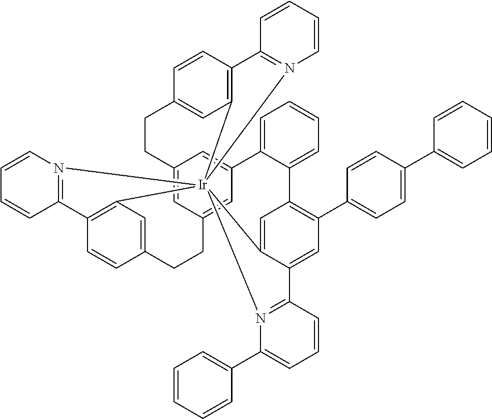

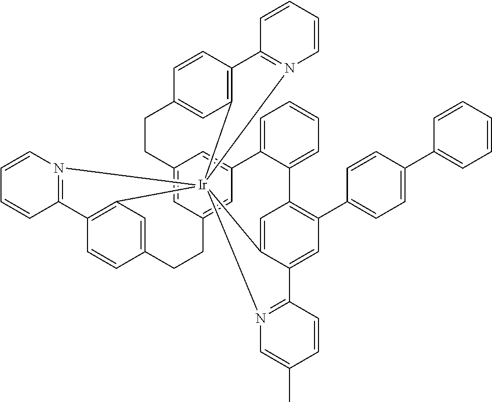

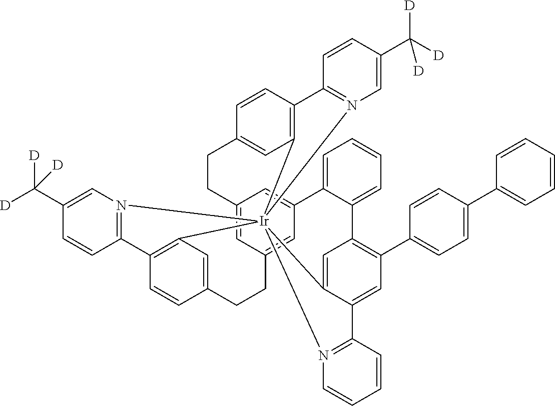

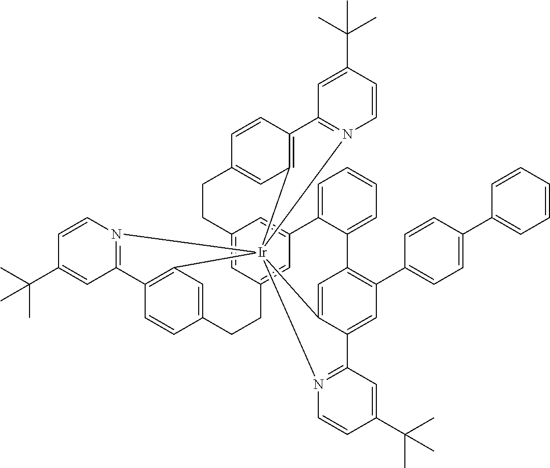

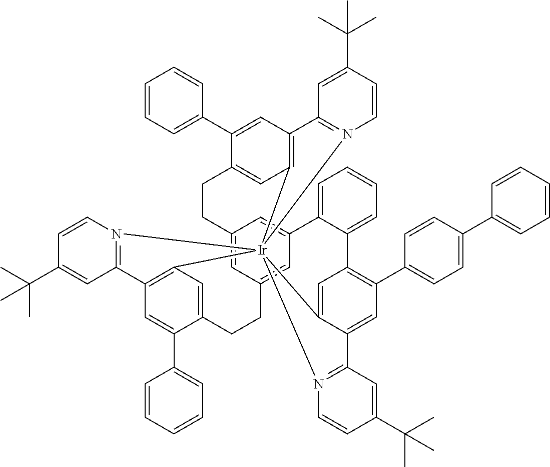

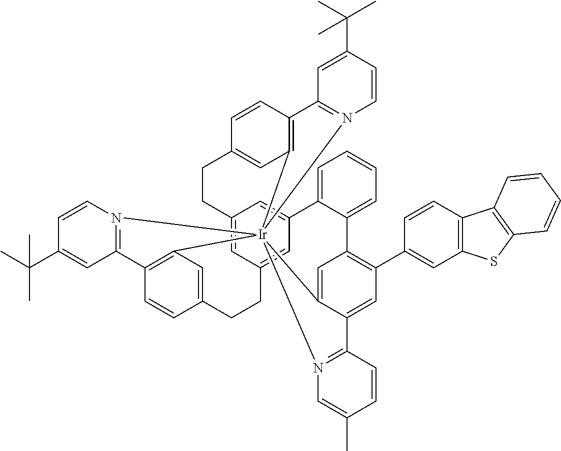

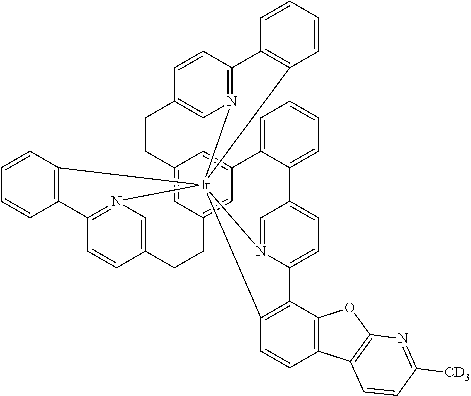

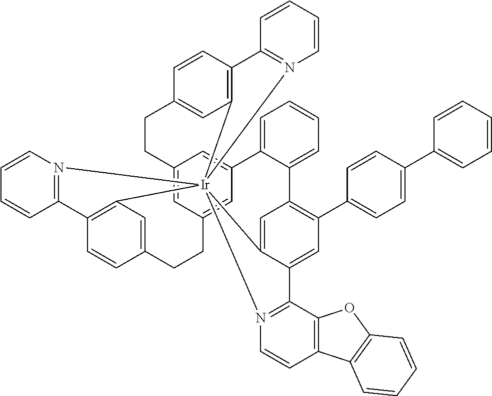

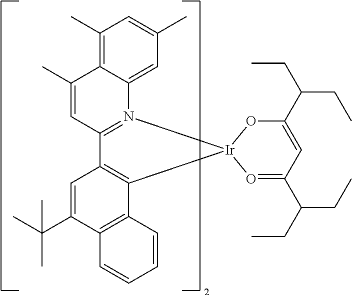

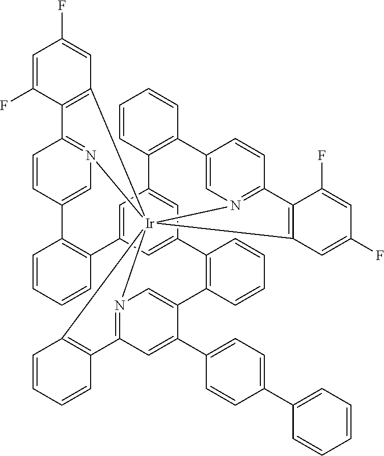

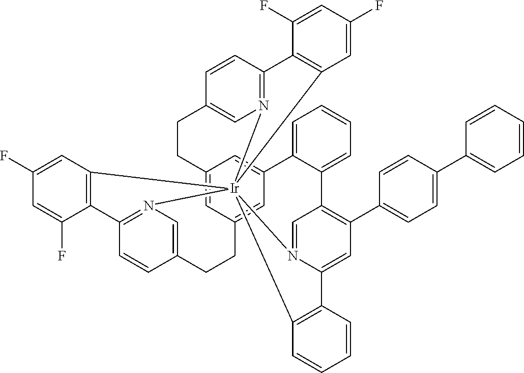

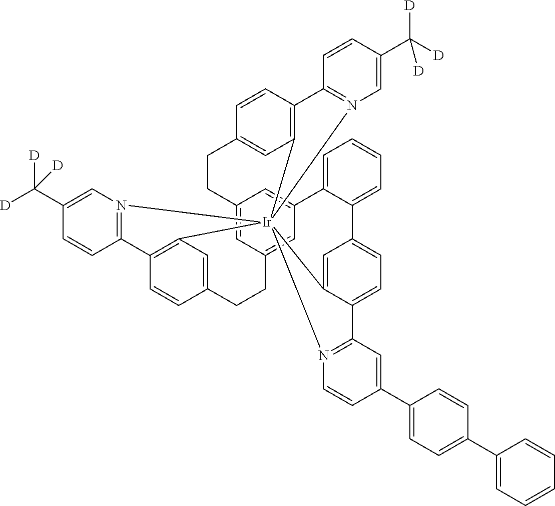

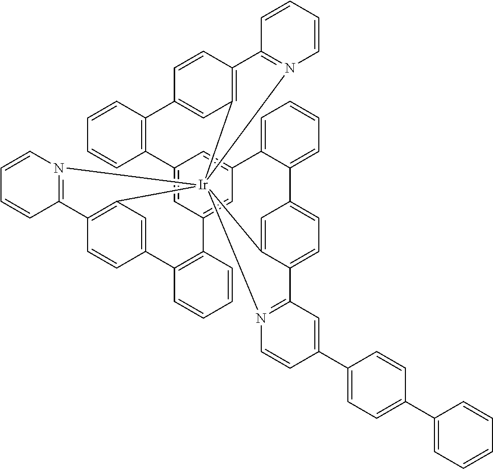

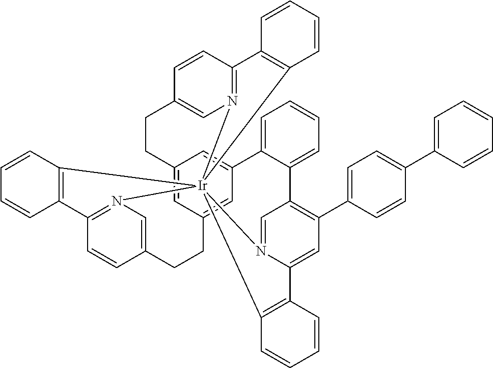

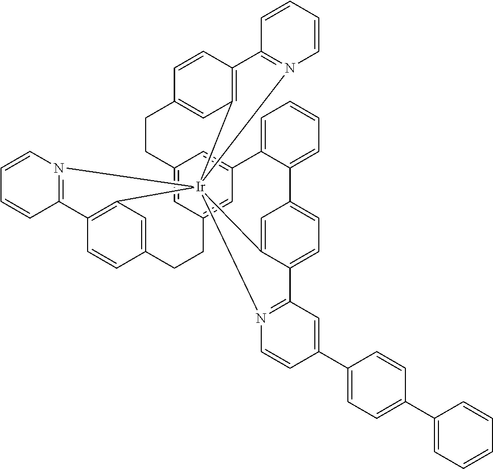

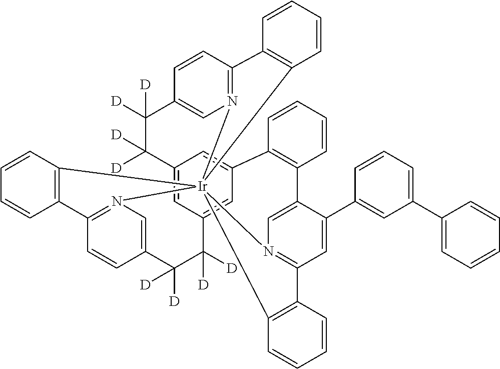

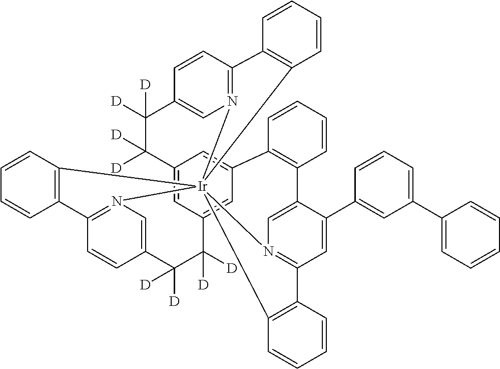

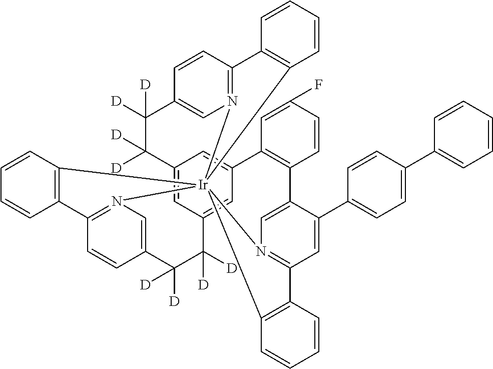

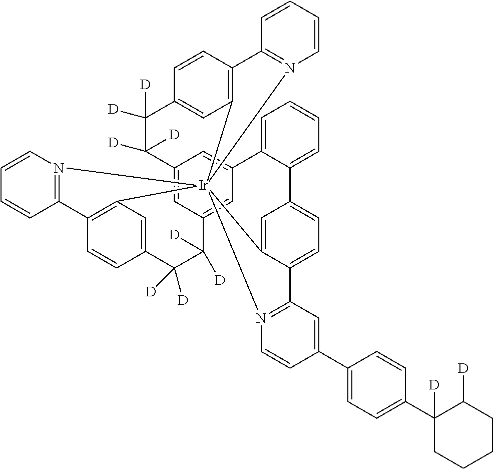

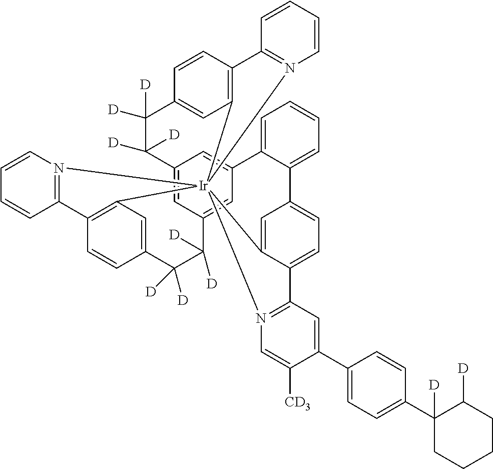

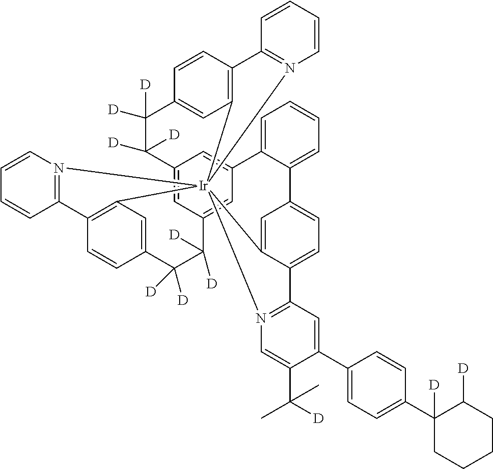

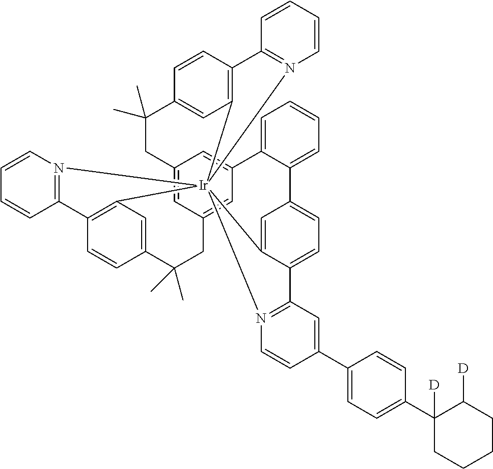

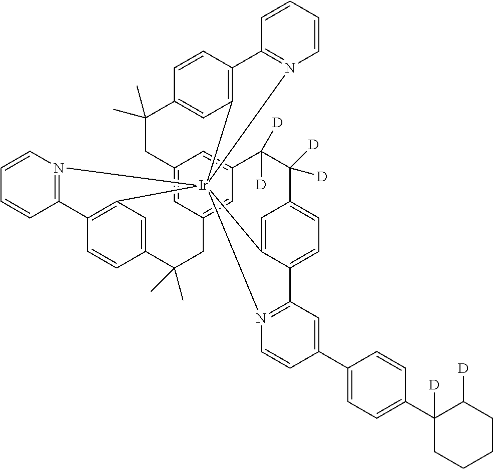

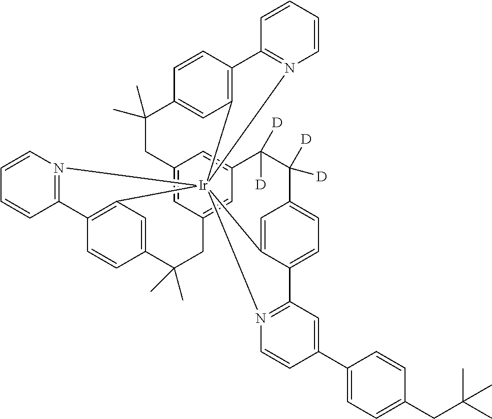

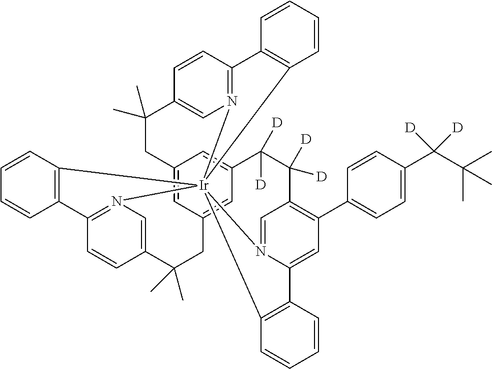

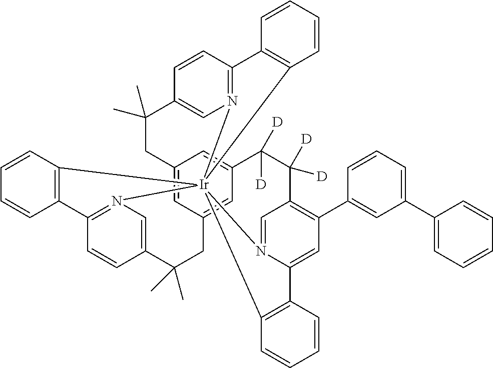

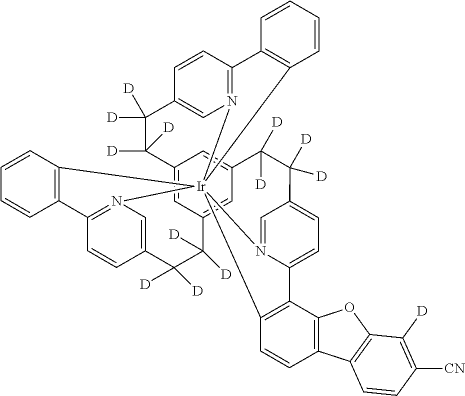

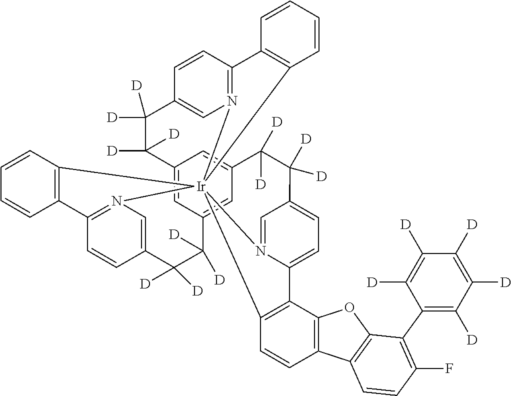

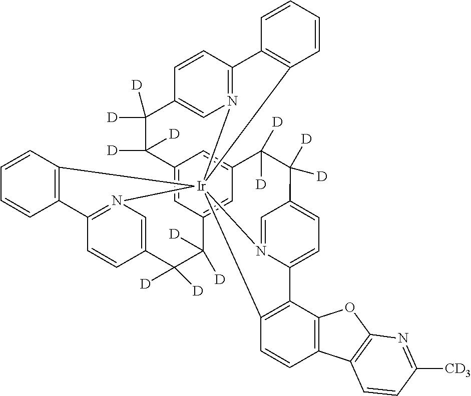

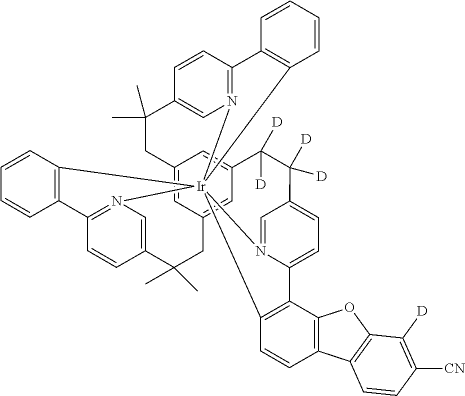

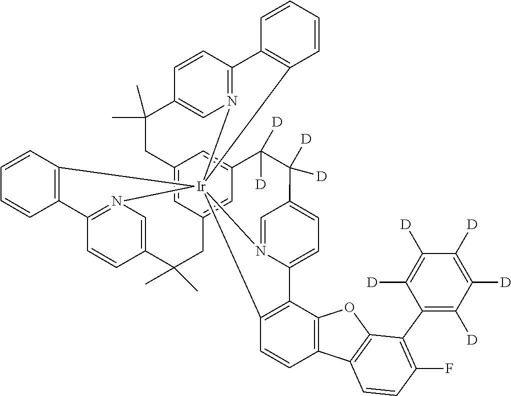

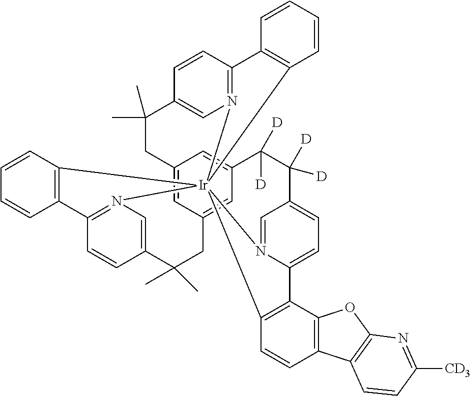

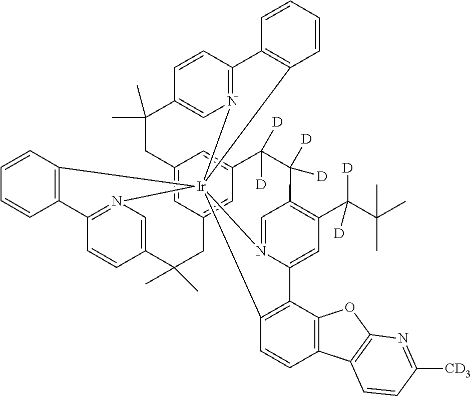

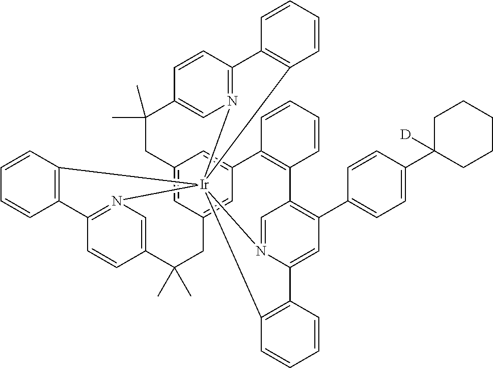

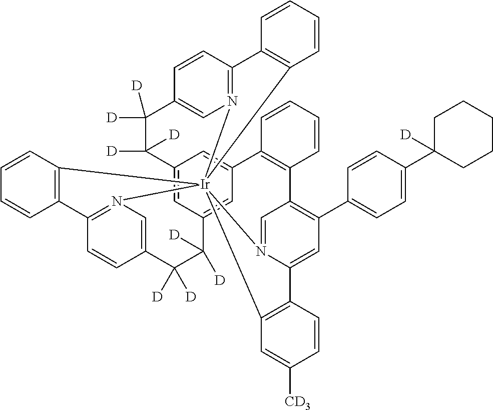

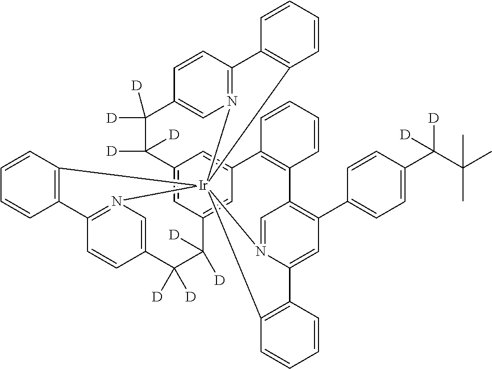

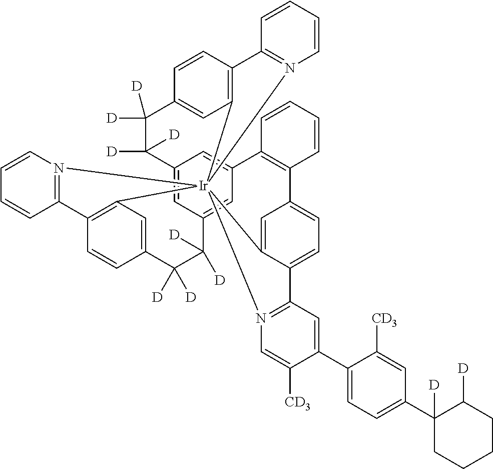

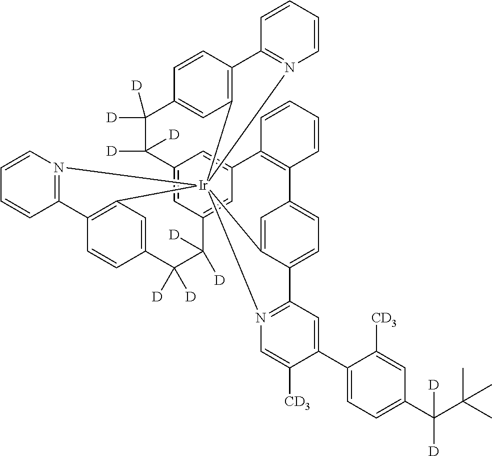

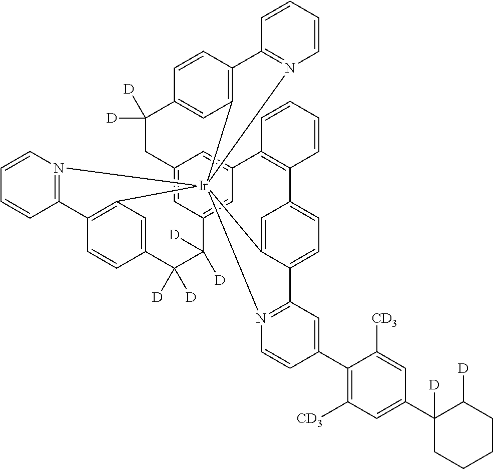

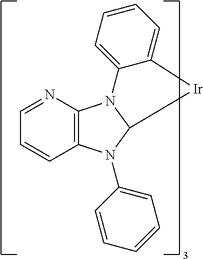

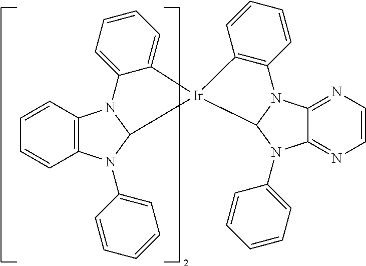

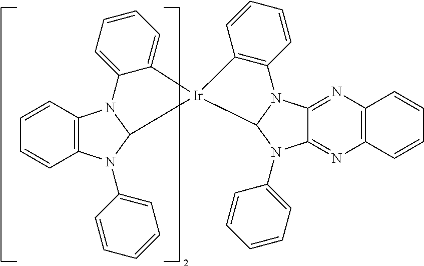

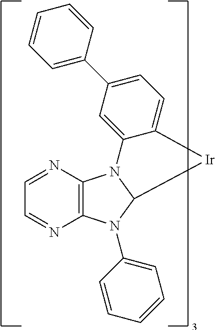

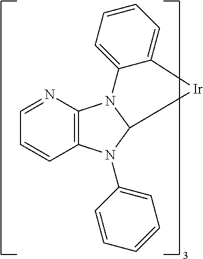

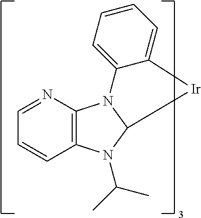

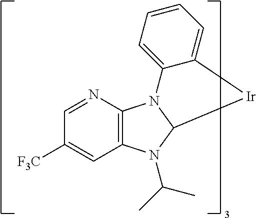

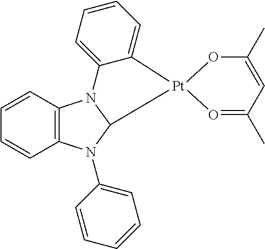

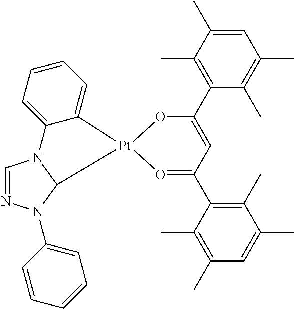

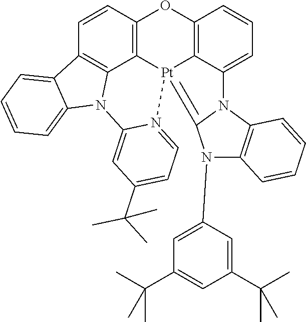

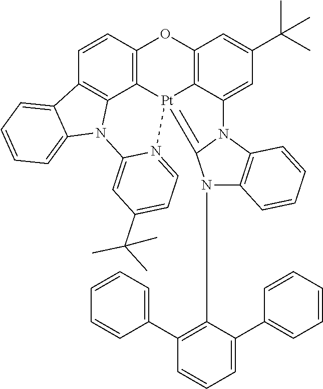

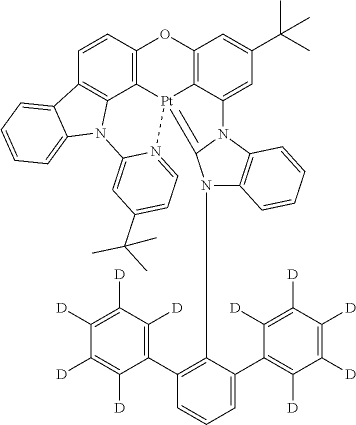

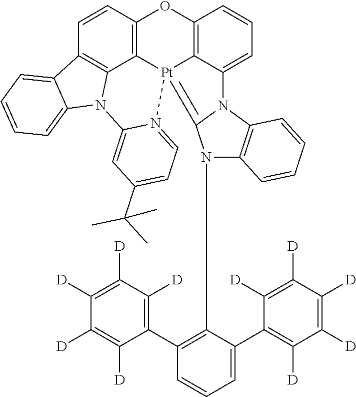

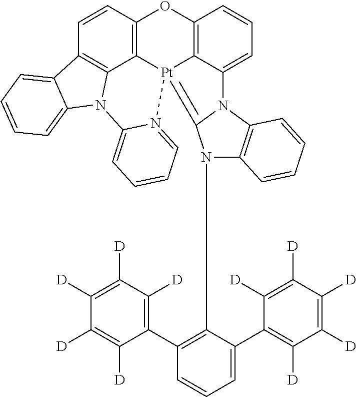

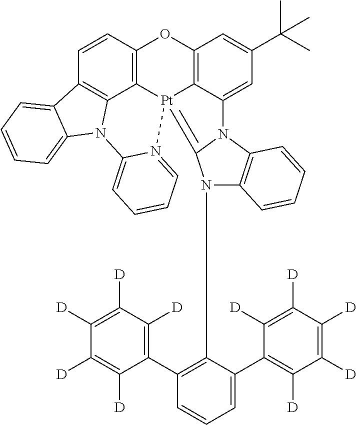

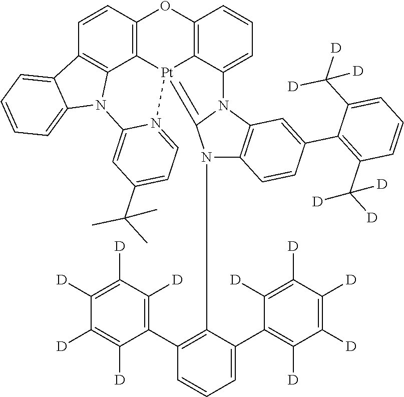

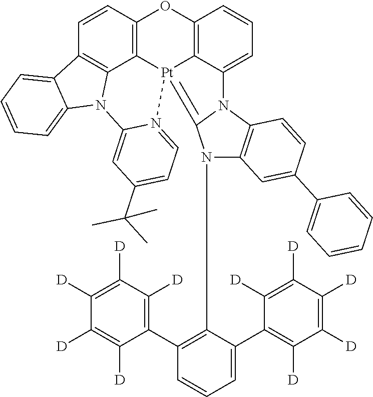

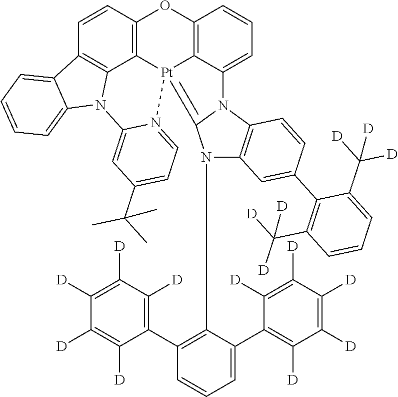

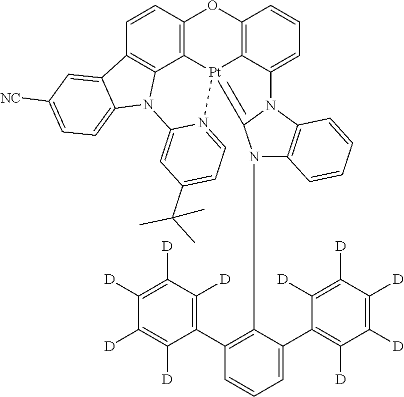

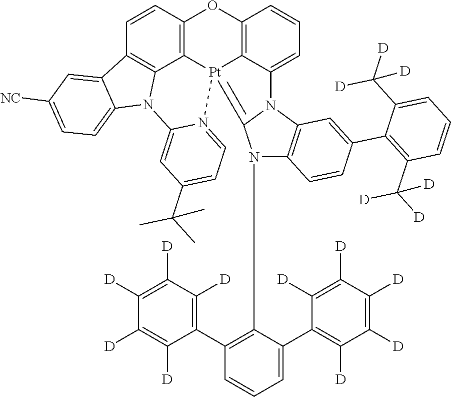

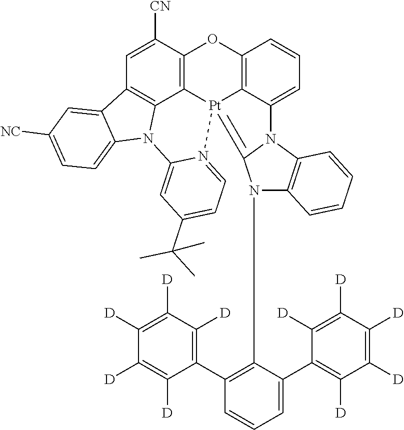

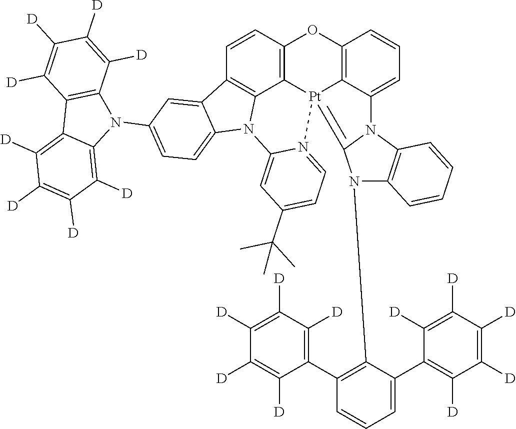

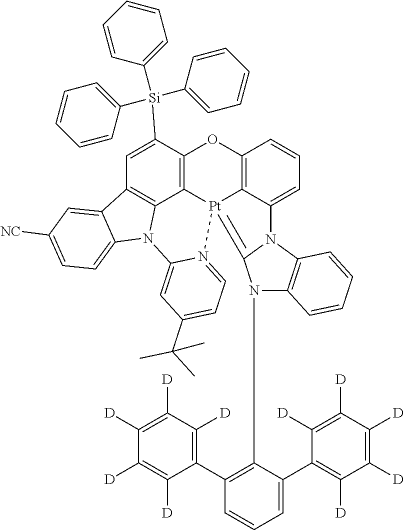

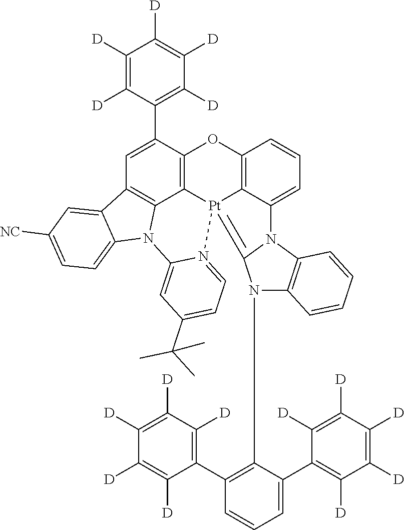

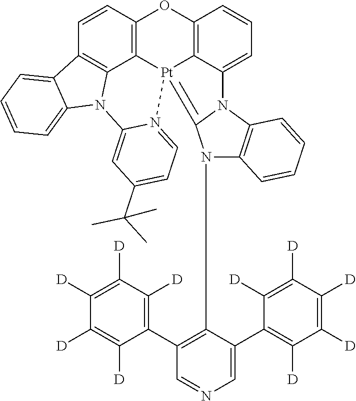

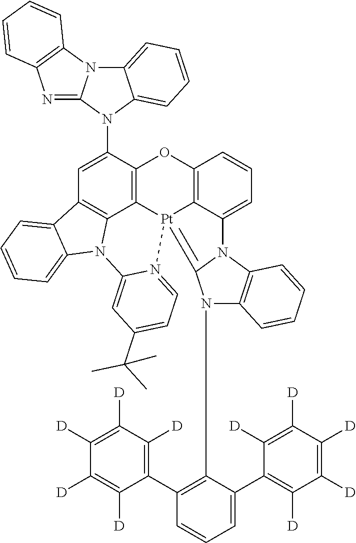

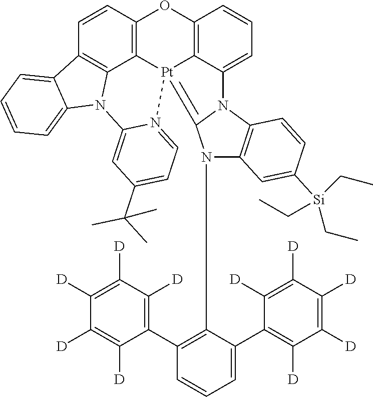

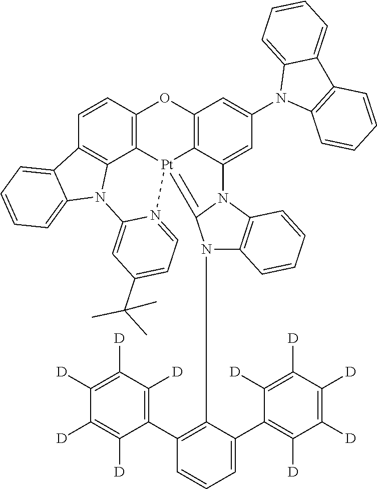

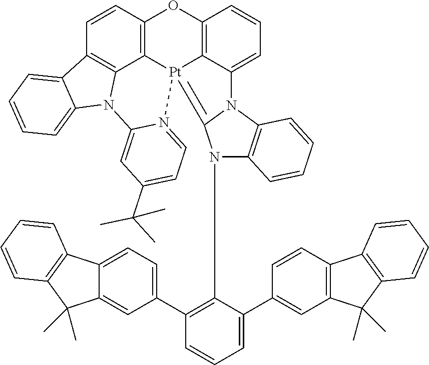

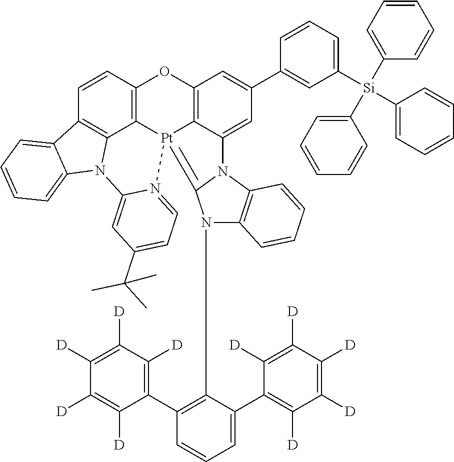

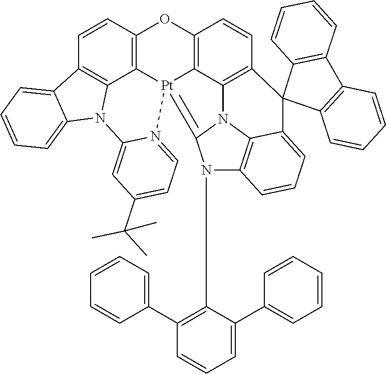

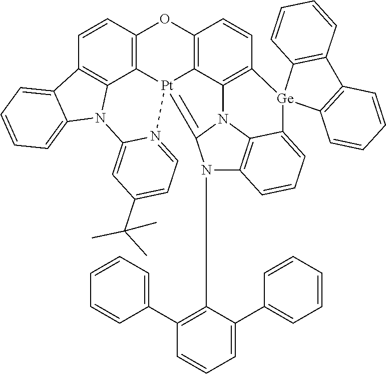

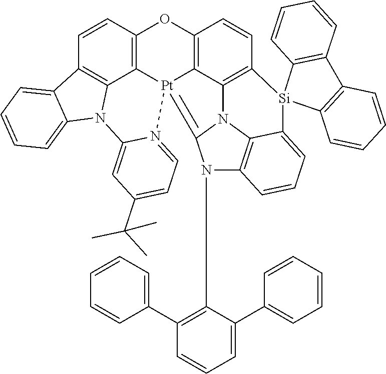

As described above, the emitting layers EMLₓ and/or EMLₓ₊₁ preferably comprise a host system, where the host system comprises at least two host materials, wherein one host material is a hole-transporting host material and the other host material is an electron-transporting host material.

An electron-transporting host in the context of the present invention is a compound having a LUMO≤−2.35 eV. Preferably, the LUMO is ≤−2.50 eV. The LUMO is the lowest unoccupied molecular orbital. The value of the LUMO of the compound is determined by quantum-chemical calculation, as described in general terms in the examples section at the back.

A hole-transporting host in the context of the present invention is a compound having a HOMO≥−5.5 eV. The HOMO is preferably ≥−5.4 eV. The HOMO is the highest occupied molecular orbital. The value of the HOMO of the compound is determined by quantum-chemical calculation, as described in general terms in the examples section at the back.

Electron-transporting host are preferably selected from the substance classes of the triazines, the pyrimidines, the lactams, the metal complexes, especially the Be, Zn and Al complexes, the aromatic ketones, the aromatic phosphine oxides, the azaphospholes, the azaboroles substituted by at least one electron-conducting substituent, and the quinoxalines.

In a preferred embodiment of the invention, the electron-transporting host is a purely organic compound, i.e. a compound containing no metals.

Example of suitable electron-transporting hosts are the compounds of formulae (eH-1) to (eH-6):

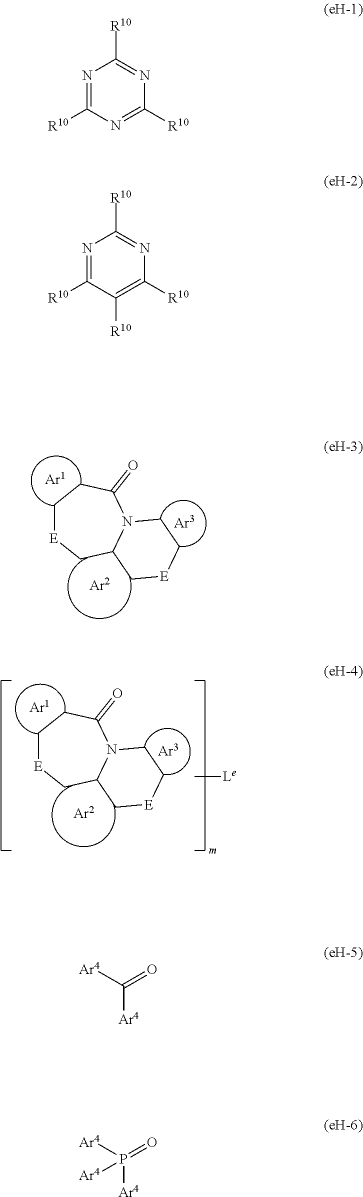

where the symbols used are as follows:
R¹⁰ is the same or different at each instance and is selected from the group consisting of H, D, F, Cl, Br, I, CN, NO₂, N(Ar¹⁰)₂, N(R¹¹)₂, C(═O)Ar¹⁰, C(═O)R¹¹, P(═O)(Ar1°)₂, a straight-chain alkyl, alkoxy or thioalkyl group having 1 to 40 carbon atoms or a branched or cyclic alkyl, alkoxy or thioalkyl group having 3 to 40 carbon atoms or an alkenyl or alkynyl group having 2 to 40 carbon atoms, each of which may be substituted by one or more R¹¹ radicals, where one or more nonadjacent CH₂ groups may be replaced by R¹¹C═CR¹¹, C═C, Si(R¹¹)₂, C═0, C═S, C═NR¹¹, P(═O)(R¹¹), SO, SO₂, NR¹¹, O, S or CONR¹¹ and where one or more hydrogen atoms may be replaced by D, F, Cl, Br, I, CN or NO₂, an aromatic or heteroaromatic ring system which has 5 to 80, preferably 5 to 60, aromatic ring atoms and may be substituted in each case by one or more R¹¹ radicals, an aryloxy or heteroaryloxy group which has 5 to 60 aromatic ring atoms and may be substituted by one or more R¹¹ radicals, or an aralkyl or heteroaralkyl group which has 5 to 60 aromatic ring atoms and may be substituted by one or more R¹ radicals, where it is optionally possible for two or more adjacent R¹⁰ substituents to form a monocyclic or polycyclic, aliphatic, aromatic or heteroaromatic ring system which may be substituted by one or more R¹¹ radicals;
R¹¹ is the same or different at each instance and is selected from the group consisting of H, D, F, C, Br, I, CN, NO₂, N(Ar¹⁰)₂, N(R¹²)₂, C(═O)Ar¹⁰, C(═O)R¹², P(═O)(Ar¹⁰)₂, a straight-chain alkyl, alkoxy or thioalkyl group having 1 to 40 carbon atoms or a branched or cyclic alkyl, alkoxy or thioalkyl group having 3 to 40 carbon atoms or an alkenyl or alkynyl group having 2 to 40 carbon atoms, each of which may be substituted by one or more R¹² radicals, where one or more nonadjacent CH₂ groups may be replaced by R¹²C═CR¹², C═C, Si(R¹²)₂, C═0, C═S, C═NR¹², P(═O)(R¹²), SO, SO₂, NR¹², O, S or CONR¹² and where one or more hydrogen atoms may be replaced by D, F, C, Br, I, CN or NO₂, an aromatic or heteroaromatic ring system which has 5 to 60 aromatic ring atoms and may be substituted in each case by one or more R¹² radicals, an aryloxy or heteroaryloxy group which has 5 to 60 aromatic ring atoms and may be substituted by one or more R¹² radicals, or an aralkyl or heteroaralkyl group having 5 to 60 aromatic ring atoms, where it is optionally possible for two or more adjacent R¹¹ substituents to form a monocyclic or polycyclic, aliphatic, aromatic or heteroaromatic ring system which may be substituted by one or more R¹² radicals;
Ar¹⁰ is the same or different at each instance and is an aromatic or heteroaromatic ring system which has 5-60 aromatic ring atoms and may be substituted by one or more nonaromatic R¹² radicals; at the same time, two Ar¹⁰ radicals bonded to the same nitrogen atom or phosphorus atom may also be bridged to one another by a single bond or a bridge selected from N(R¹²), C(R¹²)₂, O and S;
R¹² is selected from the group consisting of H, D, F, CN, an aliphatic hydrocarbyl radical having 1 to 20 carbon atoms, an aromatic or heteroaromatic ring system having 5 to 30 aromatic ring atoms in which one or more hydrogen atoms may be replaced by D, F, Cl, Br, I or CN, where two or more adjacent R¹² substituents together may form a mono- or polycyclic, aliphatic, aromatic or heteroaromatic ring system.

E is the same or different at each instance and is a single bond, NR¹⁰, CR¹⁰², O, S, SiR¹⁰₂, BR¹⁰, PR¹⁰ and P(═O)R¹⁰;
Ar¹, Ar², Ar³ is the same or different at each instance and, together with the carbon atoms shown explicitly, is an aromatic or heteroaromatic ring system which has 5 to 30 aromatic ring atoms and may be substituted by one or more R¹⁰ radicals;
Ar⁴ is the same or different at each instance and is an aromatic or heteroaromatic ring system which has 5 to 80 aromatic ring atoms, preferably up to 60 aromatic ring atoms, each of which may be substituted by one or more R¹⁰ groups;
L^{e} when m=2 is a single bond or a bivalent group, or when m=3 is a trivalent group, or when m=4 is a tetravalent group, each of which is bonded at any desired position to Ar¹, Ar² or Ar³ or in place of an R¹⁰ radical to E;
m is 2, 3 or 4.

Examples of electron-transporting hosts are depicted in the table below:

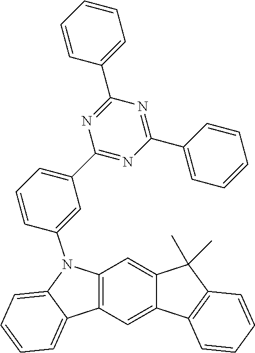 [SMILES: CC1(C)c2ccccc2-c2cc3c4ccccc4n(-c4cccc(-c5nc(-c6ccccc6)nc(-c6ccccc6)n5)c4)c3cc21]

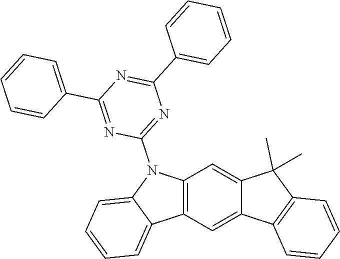 [SMILES: CC1(C)c2ccccc2-c2cc3c4ccccc4n(-c4nc(-c5ccccc5)nc(-c5ccccc5)n4)c3cc21]

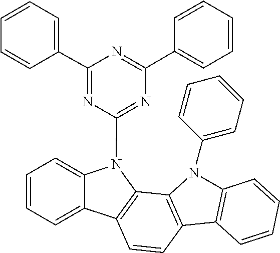 [SMILES: c1ccc(-c2nc(-c3ccccc3)nc(-n3c4ccccc4c4ccc5c6ccccc6n(-c6ccccc6)c5c43)n2)cc1]

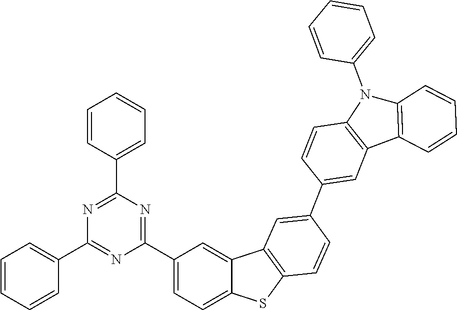 [SMILES: c1ccc(-c2nc(-c3ccccc3)nc(-c3ccc4sc5ccc(-c6ccc7c(c6)c6ccccc6n7-c6ccccc6)cc5c4c3)n2)cc1]

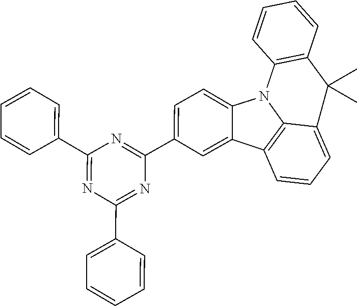 [SMILES: CC1(C)c2ccccc2-n2c3ccc(-c4nc(-c5ccccc5)nc(-c5ccccc5)n4)cc3c3cccc1c32]

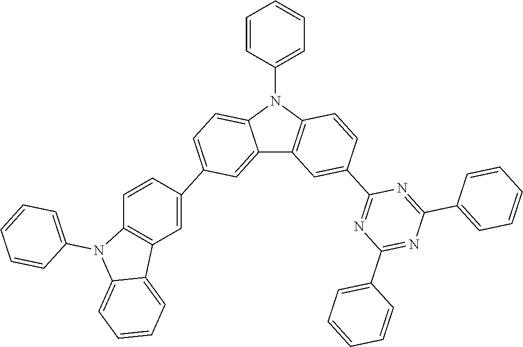 [SMILES: c1ccc(-c2nc(-c3ccccc3)nc(-c3ccc4c(c3)c3cc(-c5ccc6c(c5)c5ccccc5n6-c5ccccc5)ccc3n4-c3ccccc3)n2)cc1]

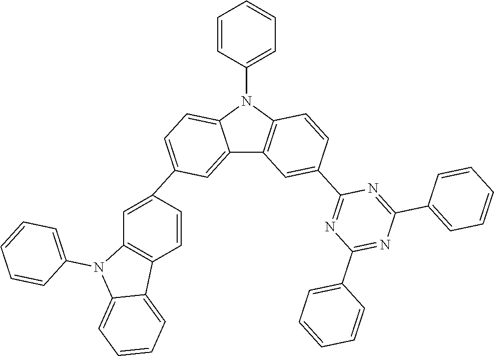 [SMILES: c1ccc(-c2nc(-c3ccccc3)nc(-c3ccc4c(c3)c3cc(-c5ccc6c7ccccc7n(-c7ccccc7)c6c5)ccc3n4-c3ccccc3)n2)cc1]

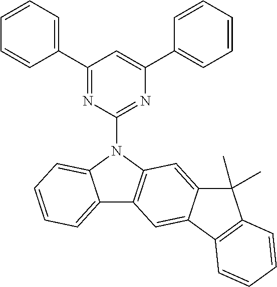 [SMILES: CC1(C)c2ccccc2-c2cc3c4ccccc4n(-c4nc(-c5ccccc5)cc(-c5ccccc5)n4)c3cc21]

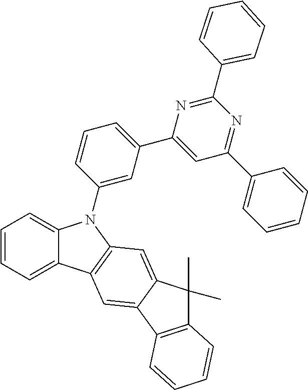 [SMILES: CC1(C)c2ccccc2-c2cc3c4ccccc4n(-c4cccc(-c5cc(-c6ccccc6)nc(-c6ccccc6)n5)c4)c3cc21]

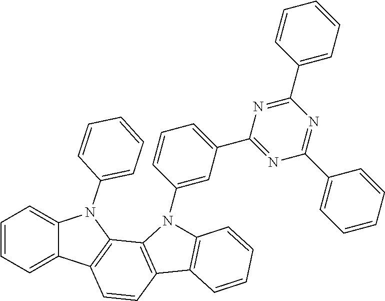 [SMILES: c1ccc(-c2nc(-c3ccccc3)nc(-c3cccc(-n4c5ccccc5c5ccc6c7ccccc7n(-c7ccccc7)c6c54)c3)n2)cc1]

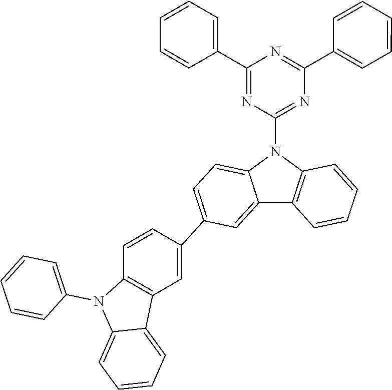 [SMILES: c1ccc(-c2nc(-c3ccccc3)nc(-n3c4ccccc4c4cc(-c5ccc6c(c5)c5ccccc5n6-c5ccccc5)ccc43)n2)cc1]

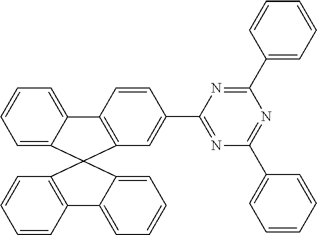 [SMILES: c1ccc(-c2nc(-c3ccccc3)nc(-c3ccc4c(c3)C3(c5ccccc5-c5ccccc53)c3ccccc3-4)n2)cc1]

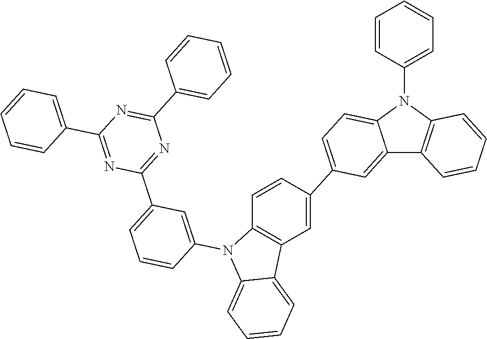 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

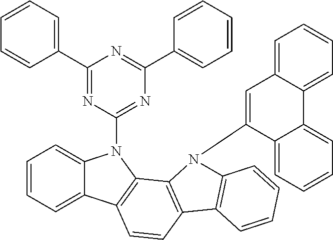 [SMILES: c1ccc(-c2nc(-c3ccccc3)nc(-n3c4ccccc4c4ccc5c6ccccc6n(-c6cc7ccccc7c7ccccc67)c5c43)n2)cc1]

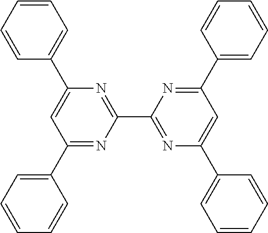 [SMILES: c1ccc(-c2cc(-c3ccccc3)nc(-c3nc(-c4ccccc4)cc(-c4ccccc4)n3)n2)cc1]

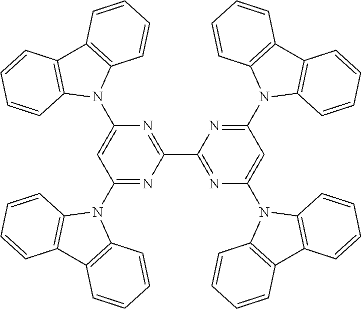 [SMILES: c1ccc2c(c1)c1ccccc1n2-c1cc(-n2c3ccccc3c3ccccc32)nc(-c2nc(-n3c4ccccc4c4ccccc43)cc(-n3c4ccccc4c4ccccc43)n2)n1]

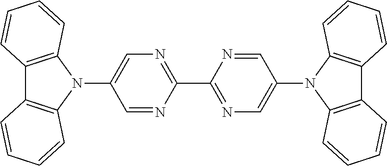 [SMILES: c1ccc2c(c1)c1ccccc1n2-c1cnc(-c2ncc(-n3c4ccccc4c4ccccc43)cn2)nc1]

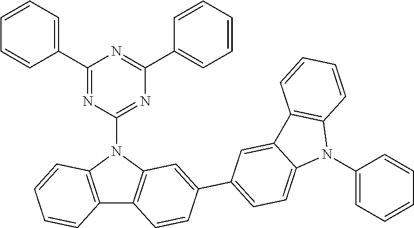 [SMILES: c1ccc(-c2nc(-c3ccccc3)nc(-n3c4ccccc4c4ccc(-c5ccc6c(c5)c5ccccc5n6-c5ccccc5)cc43)n2)cc1]

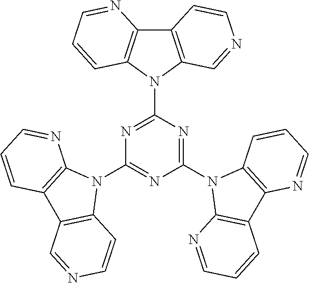 [SMILES: c1cnc2c(c1)c1cnccc1n2-c1nc(-n2c3cnccc3c3ncccc32)nc(-n2c3cccnc3c3cccnc32)n1]

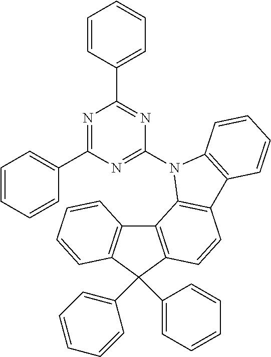 [SMILES: c1ccc(-c2nc(-c3ccccc3)nc(-n3c4ccccc4c4ccc5c(c43)-c3ccccc3C5(c3ccccc3)c3ccccc3)n2)cc1]

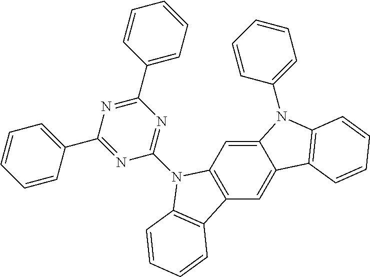 [SMILES: c1ccc(-c2nc(-c3ccccc3)nc(-n3c4ccccc4c4cc5c6ccccc6n(-c6ccccc6)c5cc43)n2)cc1]

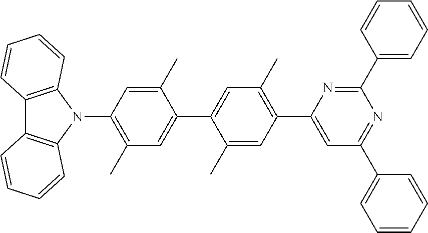 [SMILES: Cc1cc(-c2cc(C)c(-n3c4ccccc4c4ccccc43)cc2C)c(C)cc1-c1cc(-c2ccccc2)nc(-c2ccccc2)n1]

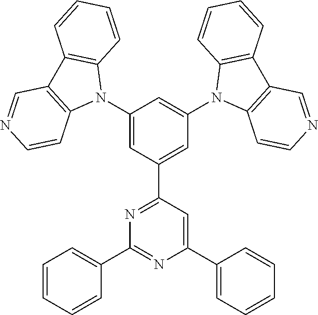 [SMILES: c1ccc(-c2cc(-c3cc(-n4c5ccccc5c5cnccc54)cc(-n4c5ccccc5c5cnccc54)c3)nc(-c3ccccc3)n2)cc1]

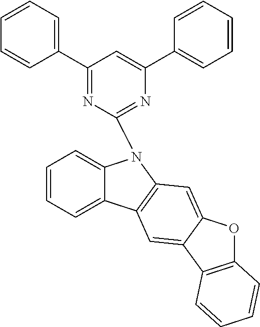 [SMILES: c1ccc(-c2cc(-c3ccccc3)nc(-n3c4ccccc4c4cc5c(cc43)oc3ccccc35)n2)cc1]

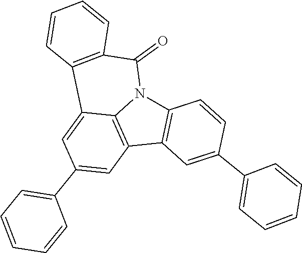 [SMILES: O=c1c2ccccc2c2cc(-c3ccccc3)cc3c4cc(-c5ccccc5)ccc4n1c23]

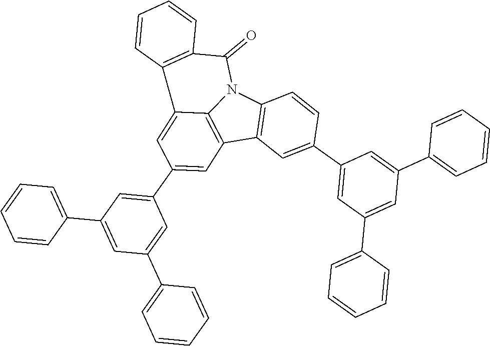 [SMILES: O=c1c2ccccc2c2cc(-c3cc(-c4ccccc4)cc(-c4ccccc4)c3)cc3c4cc(-c5cc(-c6ccccc6)cc(-c6ccccc6)c5)ccc4n1c23]

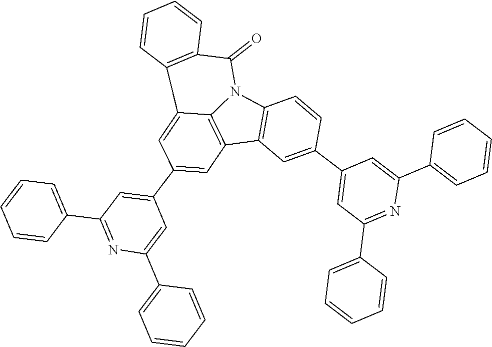 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

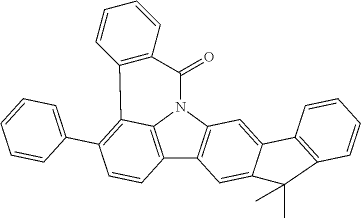 [SMILES: CC1(C)c2ccccc2-c2cc3c(cc21)c1ccc(-c2ccccc2)c2c4ccccc4c(=O)n3c12]

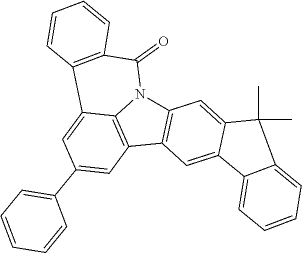 [SMILES: CC1(C)c2ccccc2-c2cc3c4cc(-c5ccccc5)cc5c6ccccc6c(=O)n(c3cc21)c54]

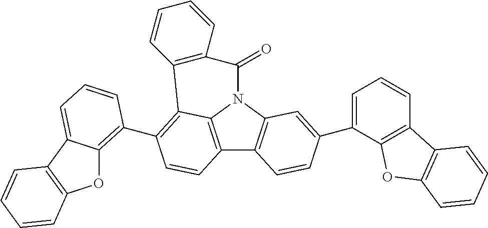 [SMILES: O=c1c2ccccc2c2c(-c3cccc4c3oc3ccccc34)ccc3c4ccc(-c5cccc6c5oc5ccccc56)cc4n1c32]

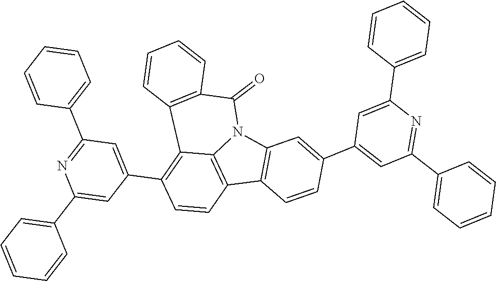 [SMILES: O=c1c2ccccc2c2c(-c3cc(-c4ccccc4)nc(-c4ccccc4)c3)ccc3c4ccc(-c5cc(-c6ccccc6)nc(-c6ccccc6)c5)cc4n1c32]

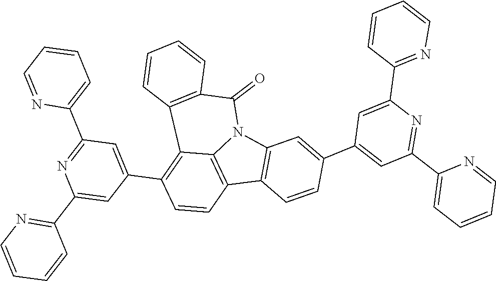 [SMILES: O=c1c2ccccc2c2c(-c3cc(-c4ccccn4)nc(-c4ccccn4)c3)ccc3c4ccc(-c5cc(-c6ccccn6)nc(-c6ccccn6)c5)cc4n1c32]

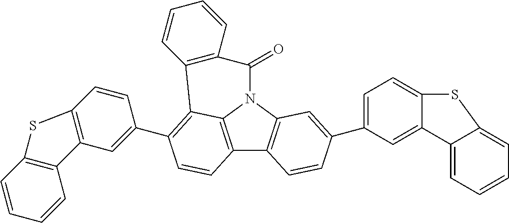 [SMILES: O=c1c2ccccc2c2c(-c3ccc4sc5ccccc5c4c3)ccc3c4ccc(-c5ccc6sc7ccccc7c6c5)cc4n1c32]

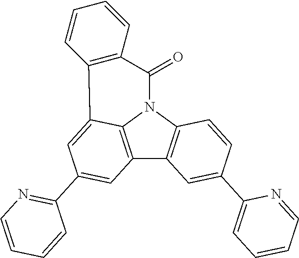 [SMILES: O=c1c2ccccc2c2cc(-c3ccccn3)cc3c4cc(-c5ccccn5)ccc4n1c23]

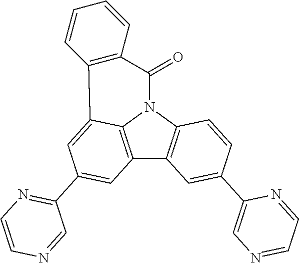 [SMILES: O=c1c2ccccc2c2cc(-c3cnccn3)cc3c4cc(-c5cnccn5)ccc4n1c23]

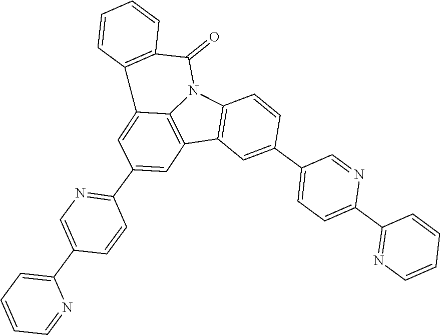 [SMILES: O=c1c2ccccc2c2cc(-c3ccc(-c4ccccn4)cn3)cc3c4cc(-c5ccc(-c6ccccn6)nc5)ccc4n1c23]

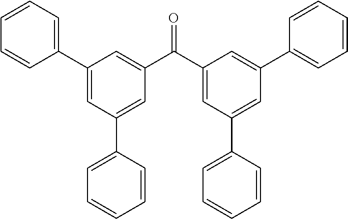 [SMILES: O=C(c1cc(-c2ccccc2)cc(-c2ccccc2)c1)c1cc(-c2ccccc2)cc(-c2ccccc2)c1]

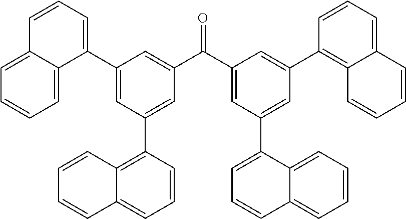 [SMILES: O=C(c1cc(-c2cccc3ccccc23)cc(-c2cccc3ccccc23)c1)c1cc(-c2cccc3ccccc23)cc(-c2cccc3ccccc23)c1]

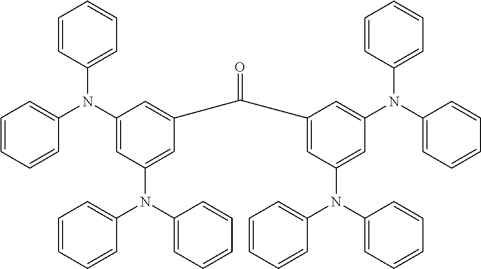 [SMILES: O=C(c1cc(N(c2ccccc2)c2ccccc2)cc(N(c2ccccc2)c2ccccc2)c1)c1cc(N(c2ccccc2)c2ccccc2)cc(N(c2ccccc2)c2ccccc2)c1]

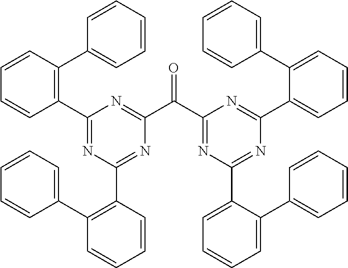 [SMILES: O=C(c1nc(-c2ccccc2-c2ccccc2)nc(-c2ccccc2-c2ccccc2)n1)c1nc(-c2ccccc2-c2ccccc2)nc(-c2ccccc2-c2ccccc2)n1]

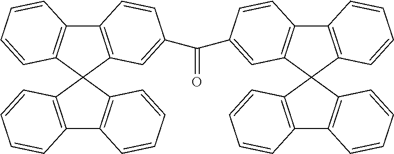 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2]

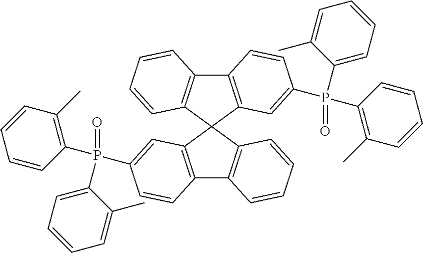 [SMILES: Cc1ccccc1P(=O)(c1ccc2c(c1)C1(c3ccccc3-2)c2ccccc2-c2ccc(P(=O)(c3ccccc3C)c3ccccc3C)cc21)c1ccccc1C]

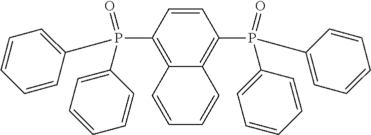 [SMILES: O=P(c1ccccc1)(c1ccccc1)c1ccc(P(=O)(c2ccccc2)c2ccccc2)c2ccccc12]

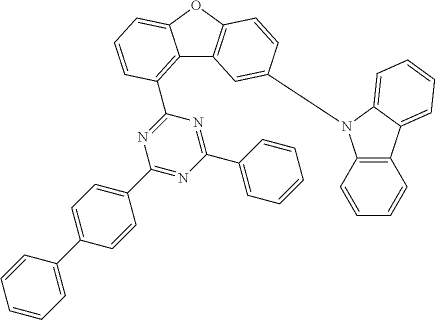 [SMILES: c1ccc(-c2ccc(-c3nc(-c4ccccc4)nc(-c4cccc5oc6ccc(-n7c8ccccc8c8ccccc87)cc6c45)n3)cc2)cc1]

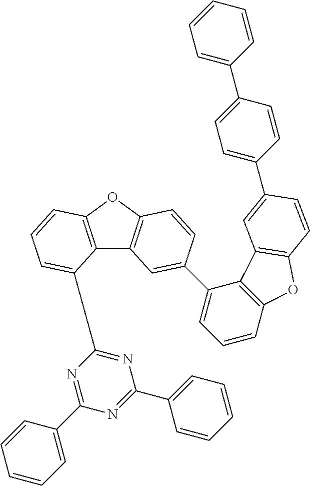 [SMILES: c1ccc(-c2ccc(-c3ccc4oc5cccc(-c6ccc7oc8cccc(-c9nc(-c%10ccccc%10)nc(-c%10ccccc%10)n9)c8c7c6)c5c4c3)cc2)cc1]

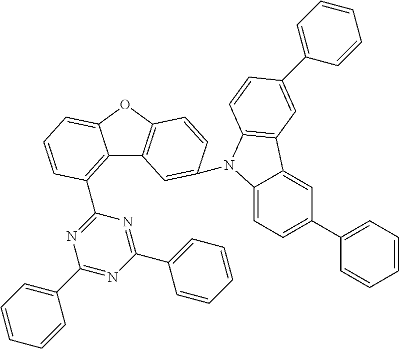 [SMILES: c1ccc(-c2ccc3c(c2)c2cc(-c4ccccc4)ccc2n3-c2ccc3oc4cccc(-c5nc(-c6ccccc6)nc(-c6ccccc6)n5)c4c3c2)cc1]

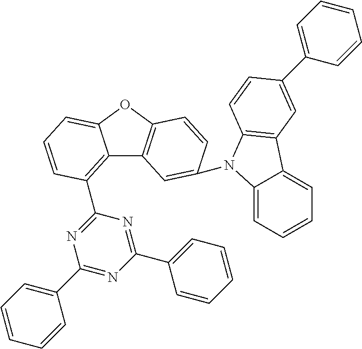 [SMILES: c1ccc(-c2ccc3c(c2)c2ccccc2n3-c2ccc3oc4cccc(-c5nc(-c6ccccc6)nc(-c6ccccc6)n5)c4c3c2)cc1]

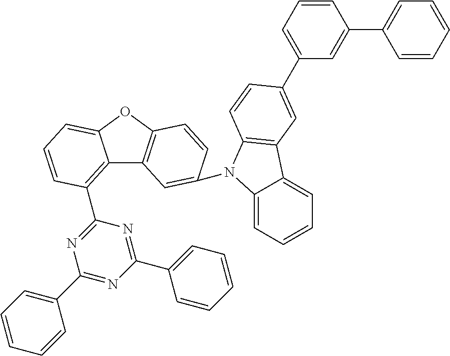 [SMILES: c1ccc(-c2cccc(-c3ccc4c(c3)c3ccccc3n4-c3ccc4oc5cccc(-c6nc(-c7ccccc7)nc(-c7ccccc7)n6)c5c4c3)c2)cc1]

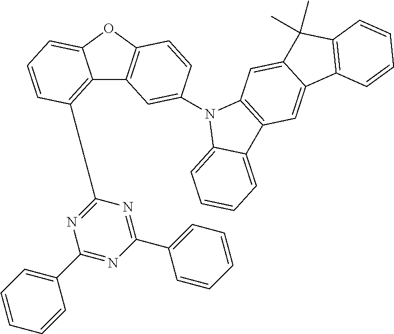 [SMILES: CC1(C)c2ccccc2-c2cc3c4ccccc4n(-c4ccc5oc6cccc(-c7nc(-c8ccccc8)nc(-c8ccccc8)n7)c6c5c4)c3cc21]

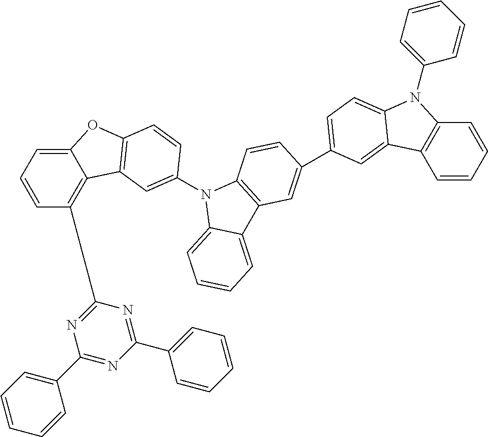 [SMILES: c1ccc(-c2nc(-c3ccccc3)nc(-c3cccc4oc5ccc(-n6c7ccccc7c7cc(-c8ccc9c(c8)c8ccccc8n9-c8ccccc8)ccc76)cc5c34)n2)cc1]

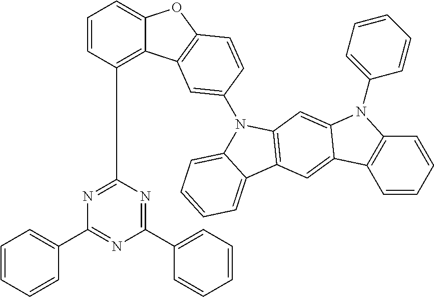 [SMILES: c1ccc(-c2nc(-c3ccccc3)nc(-c3cccc4oc5ccc(-n6c7ccccc7c7cc8c9ccccc9n(-c9ccccc9)c8cc76)cc5c34)n2)cc1]

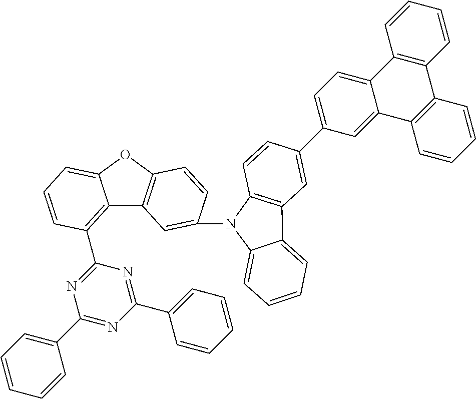 [SMILES: c1ccc(-c2nc(-c3ccccc3)nc(-c3cccc4oc5ccc(-n6c7ccccc7c7cc(-c8ccc9c%10ccccc%10c%10ccccc%10c9c8)ccc76)cc5c34)n2)cc1]

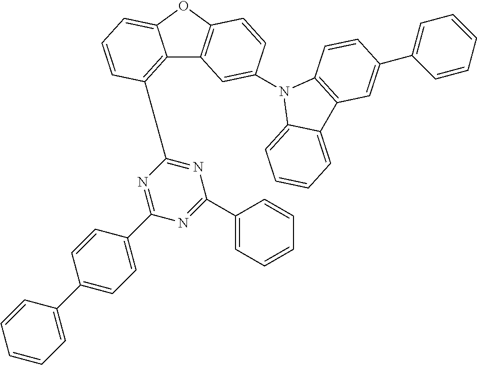 [SMILES: c1ccc(-c2ccc(-c3nc(-c4ccccc4)nc(-c4cccc5oc6ccc(-n7c8ccccc8c8cc(-c9ccccc9)ccc87)cc6c45)n3)cc2)cc1]

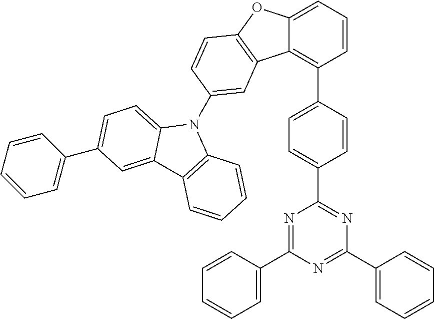 [SMILES: c1ccc(-c2ccc3c(c2)c2ccccc2n3-c2ccc3oc4cccc(-c5ccc(-c6nc(-c7ccccc7)nc(-c7ccccc7)n6)cc5)c4c3c2)cc1]

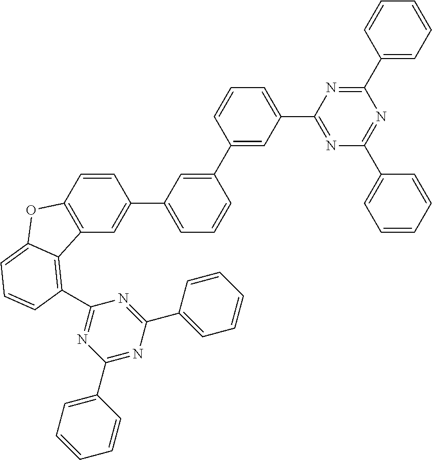 [SMILES: c1ccc(-c2nc(-c3ccccc3)nc(-c3cccc(-c4cccc(-c5ccc6oc7cccc(-c8nc(-c9ccccc9)nc(-c9ccccc9)n8)c7c6c5)c4)c3)n2)cc1]

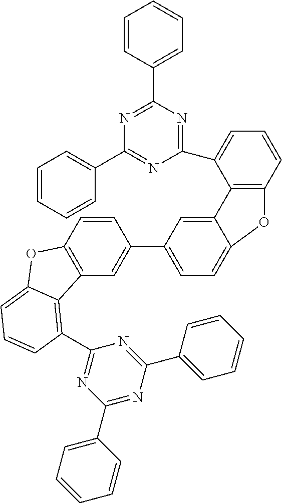 [SMILES: c1ccc(-c2nc(-c3ccccc3)nc(-c3cccc4oc5ccc(-c6ccc7oc8cccc(-c9nc(-c%10ccccc%10)nc(-c%10ccccc%10)n9)c8c7c6)cc5c34)n2)cc1]

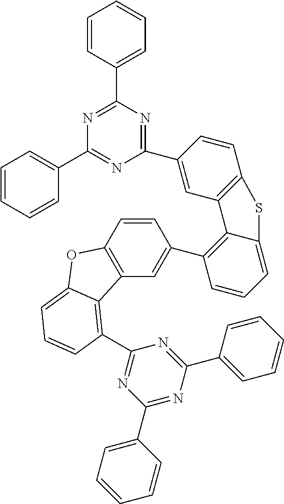 [SMILES: c1ccc(-c2nc(-c3ccccc3)nc(-c3ccc4sc5cccc(-c6ccc7oc8cccc(-c9nc(-c%10ccccc%10)nc(-c%10ccccc%10)n9)c8c7c6)c5c4c3)n2)cc1]

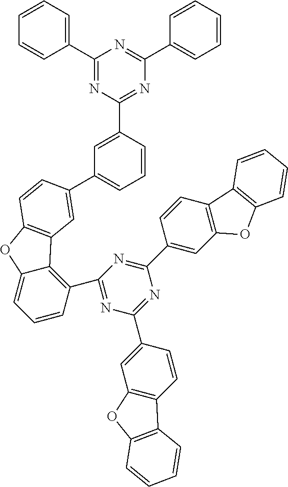 [SMILES: c1ccc(-c2nc(-c3ccccc3)nc(-c3cccc(-c4ccc5oc6cccc(-c7nc(-c8ccc9c(c8)oc8ccccc89)nc(-c8ccc9c(c8)oc8ccccc89)n7)c6c5c4)c3)n2)cc1]

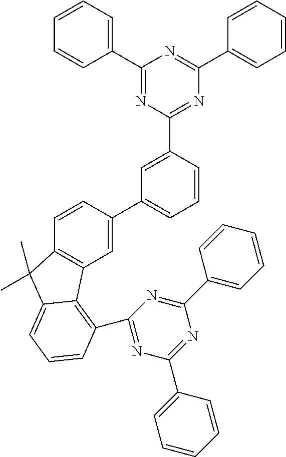 [SMILES: CC1(C)c2ccc(-c3cccc(-c4nc(-c5ccccc5)nc(-c5ccccc5)n4)c3)cc2-c2c(-c3nc(-c4ccccc4)nc(-c4ccccc4)n3)cccc21]

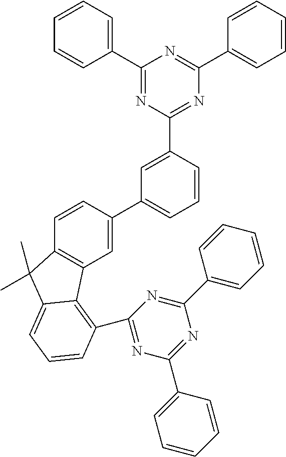 [SMILES: CC1(C)c2ccc(-c3cccc(-c4nc(-c5ccccc5)nc(-c5ccccc5)n4)c3)cc2-c2c(-c3nc(-c4ccccc4)nc(-c4ccccc4)n3)cccc21]

Hole-transporting hosts are preferably selected from the group of the carbazole and triarylamine derivatives, especially the biscarbazoles, the bridged carbazoles, the triarylamines, the dibenzofuran-carbazole derivatives or dibenzofuran-amine derivatives, and the carbazoleamines.

Examples of compounds suitable as hole-transporting hosts are depicted in the table below:

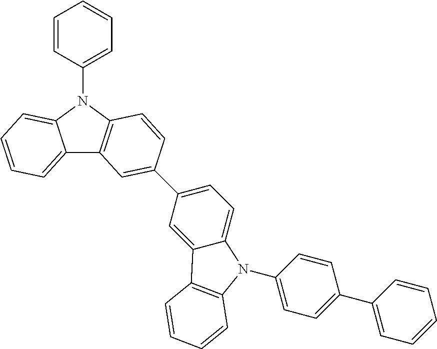 [SMILES: c1ccc(-c2ccc(-n3c4ccccc4c4cc(-c5ccc6c(c5)c5ccccc5n6-c5ccccc5)ccc43)cc2)cc1]

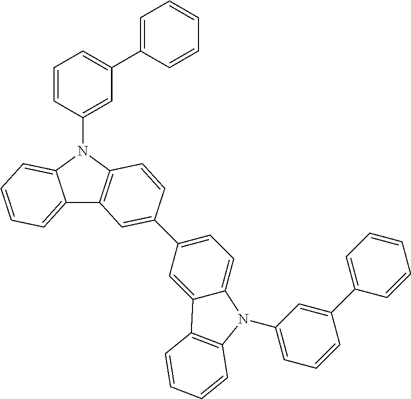 [SMILES: c1ccc(-c2cccc(-n3c4ccccc4c4cc(-c5ccc6c(c5)c5ccccc5n6-c5cccc(-c6ccccc6)c5)ccc43)c2)cc1]

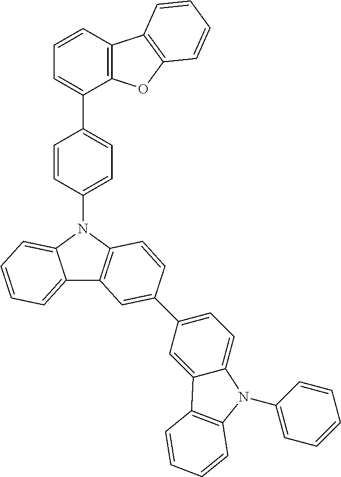 [SMILES: c1ccc(-n2c3ccccc3c3cc(-c4ccc5c(c4)c4ccccc4n5-c4ccc(-c5cccc6c5oc5ccccc56)cc4)ccc32)cc1]

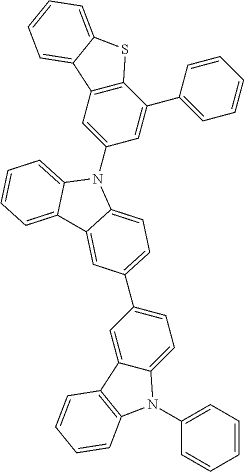 [SMILES: c1ccc(-c2cc(-n3c4ccccc4c4cc(-c5ccc6c(c5)c5ccccc5n6-c5ccccc5)ccc43)cc3c2sc2ccccc23)cc1]

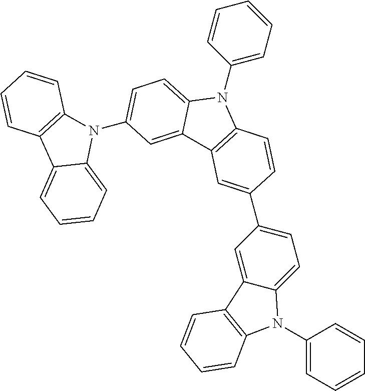 [SMILES: c1ccc(-n2c3ccccc3c3cc(-c4ccc5c(c4)c4cc(-n6c7ccccc7c7ccccc76)ccc4n5-c4ccccc4)ccc32)cc1]

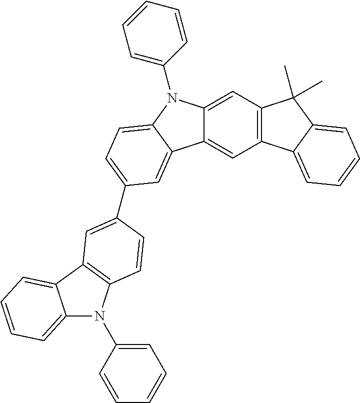 [SMILES: CC1(C)c2ccccc2-c2cc3c4cc(-c5ccc6c(c5)c5ccccc5n6-c5ccccc5)ccc4n(-c4ccccc4)c3cc21]

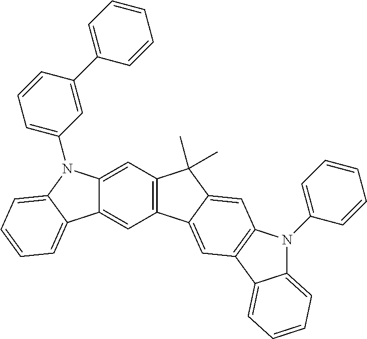 [SMILES: CC1(C)c2cc3c(cc2-c2cc4c5ccccc5n(-c5cccc(-c6ccccc6)c5)c4cc21)c1ccccc1n3-c1ccccc1]

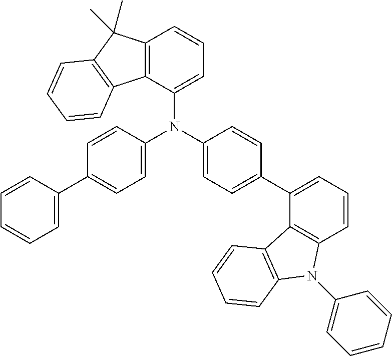 [SMILES: CC1(C)c2ccccc2-c2c(N(c3ccc(-c4ccccc4)cc3)c3ccc(-c4cccc5c4c4ccccc4n5-c4ccccc4)cc3)cccc21]

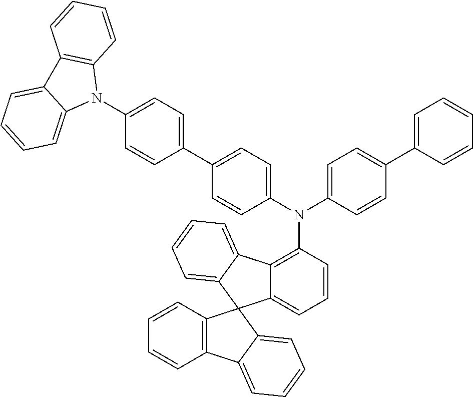 [SMILES: c1ccc(-c2ccc(N(c3ccc(-c4ccc(-n5c6ccccc6c6ccccc65)cc4)cc3)c3cccc4c3-c3ccccc3C43c4ccccc4-c4ccccc43)cc2)cc1]

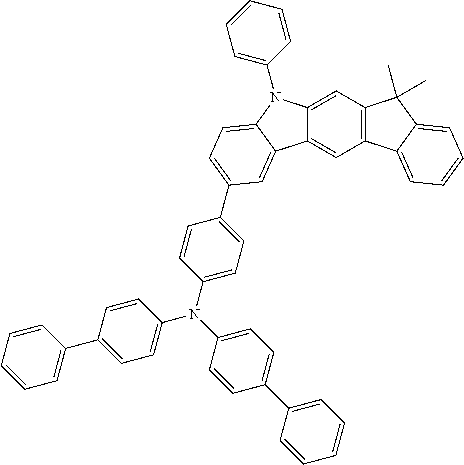 [SMILES: CC1(C)c2ccccc2-c2cc3c4cc(-c5ccc(N(c6ccc(-c7ccccc7)cc6)c6ccc(-c7ccccc7)cc6)cc5)ccc4n(-c4ccccc4)c3cc21]

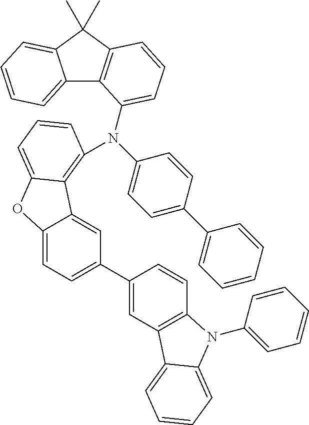 [SMILES: CC1(C)c2ccccc2-c2c(N(c3ccc(-c4ccccc4)cc3)c3cccc4oc5ccc(-c6ccc7c(c6)c6ccccc6n7-c6ccccc6)cc5c34)cccc21]

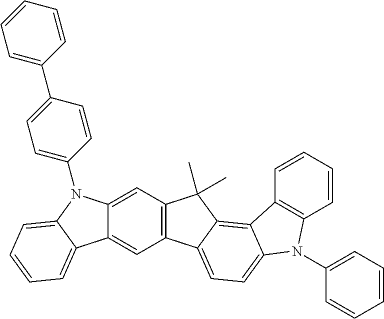 [SMILES: CC1(C)c2cc3c(cc2-c2ccc4c(c21)c1ccccc1n4-c1ccccc1)c1ccccc1n3-c1ccc(-c2ccccc2)cc1]

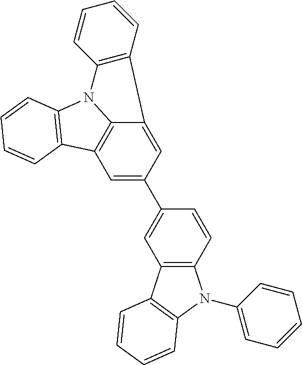 [SMILES: c1ccc(-n2c3ccccc3c3cc(-c4cc5c6ccccc6n6c7ccccc7c(c4)c56)ccc32)cc1]

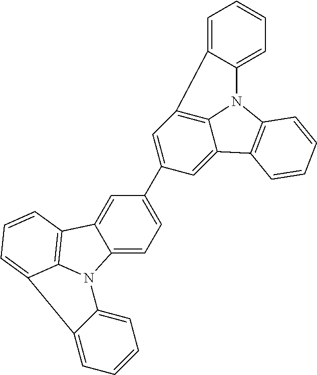 [SMILES: c1ccc2c(c1)c1cccc3c4cc(-c5cc6c7ccccc7n7c8ccccc8c(c5)c67)ccc4n2c13]

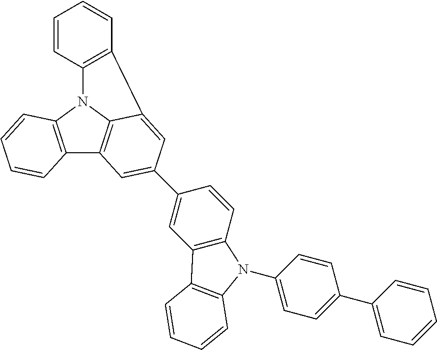 [SMILES: c1ccc(-c2ccc(-n3c4ccccc4c4cc(-c5cc6c7ccccc7n7c8ccccc8c(c5)c67)ccc43)cc2)cc1]

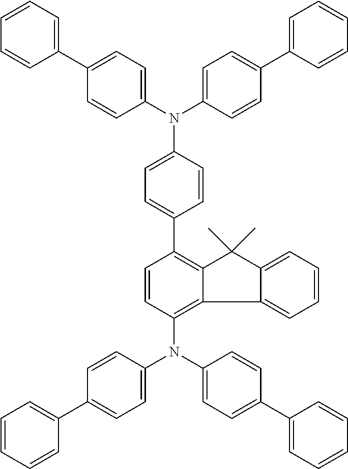 [SMILES: CC1(C)c2ccccc2-c2c(N(c3ccc(-c4ccccc4)cc3)c3ccc(-c4ccccc4)cc3)ccc(-c3ccc(N(c4ccc(-c5ccccc5)cc4)c4ccc(-c5ccccc5)cc4)cc3)c21]

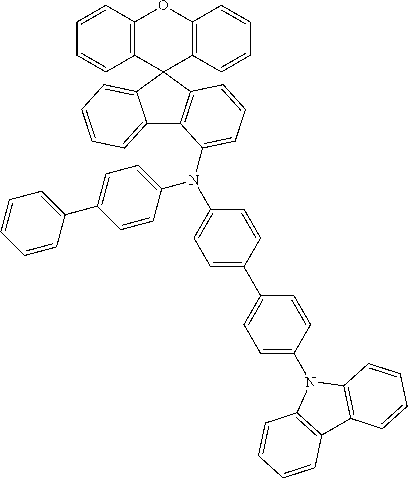 [SMILES: c1ccc(-c2ccc(N(c3ccc(-c4ccc(-n5c6ccccc6c6ccccc65)cc4)cc3)c3cccc4c3-c3ccccc3C43c4ccccc4Oc4ccccc43)cc2)cc1]

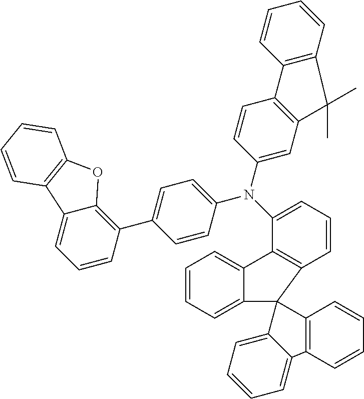 [SMILES: CC1(C)c2ccccc2-c2ccc(N(c3ccc(-c4cccc5c4oc4ccccc45)cc3)c3cccc4c3-c3ccccc3C43c4ccccc4-c4ccccc43)cc21]

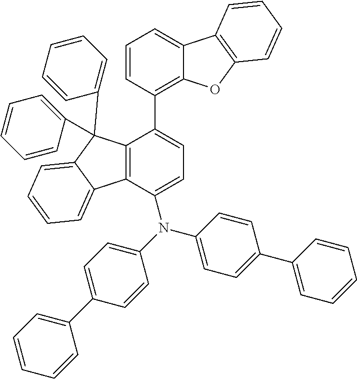 [SMILES: c1ccc(-c2ccc(N(c3ccc(-c4ccccc4)cc3)c3ccc(-c4cccc5c4oc4ccccc45)c4c3-c3ccccc3C4(c3ccccc3)c3ccccc3)cc2)cc1]

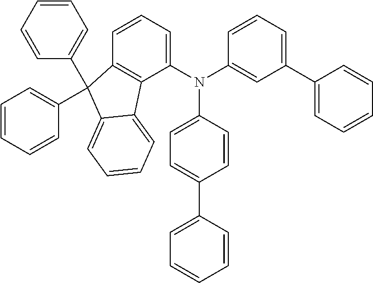 [SMILES: c1ccc(-c2ccc(N(c3cccc(-c4ccccc4)c3)c3cccc4c3-c3ccccc3C4(c3ccccc3)c3ccccc3)cc2)cc1]

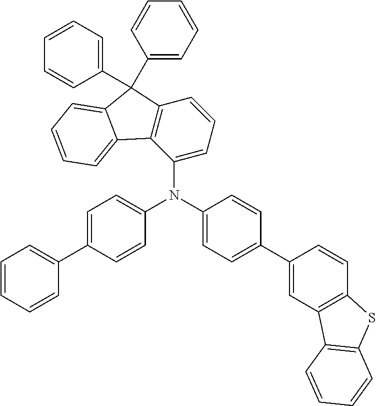 [SMILES: c1ccc(-c2ccc(N(c3ccc(-c4ccc5sc6ccccc6c5c4)cc3)c3cccc4c3-c3ccccc3C4(c3ccccc3)c3ccccc3)cc2)cc1]

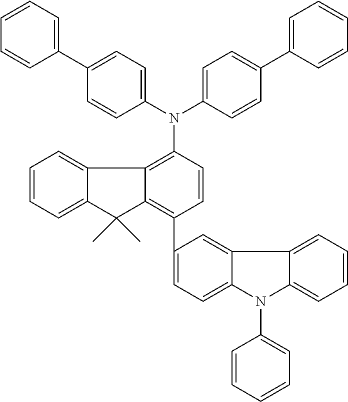 [SMILES: CC1(C)c2ccccc2-c2c(N(c3ccc(-c4ccccc4)cc3)c3ccc(-c4ccccc4)cc3)ccc(-c3ccc4c(c3)c3ccccc3n4-c3ccccc3)c21]

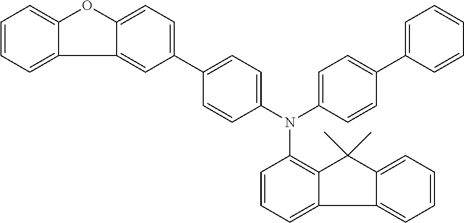 [SMILES: CC1(C)c2ccccc2-c2cccc(N(c3ccc(-c4ccccc4)cc3)c3ccc(-c4ccc5oc6ccccc6c5c4)cc3)c21]

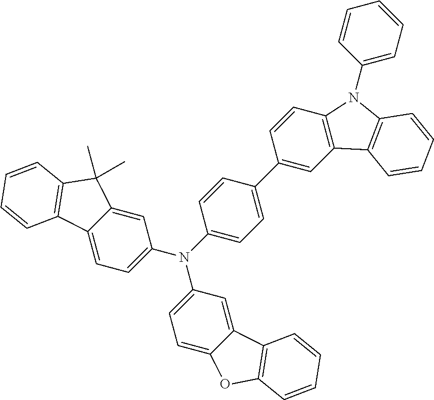 [SMILES: CC1(C)c2ccccc2-c2ccc(N(c3ccc(-c4ccc5c(c4)c4ccccc4n5-c4ccccc4)cc3)c3ccc4oc5ccccc5c4c3)cc21]

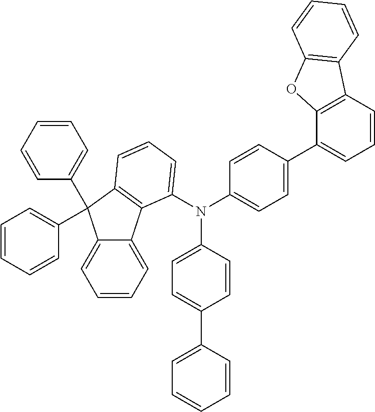 [SMILES: c1ccc(-c2ccc(N(c3ccc(-c4cccc5c4oc4ccccc45)cc3)c3cccc4c3-c3ccccc3C4(c3ccccc3)c3ccccc3)cc2)cc1]

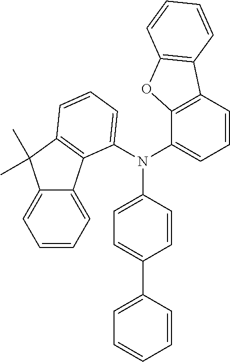 [SMILES: CC1(C)c2ccccc2-c2c(N(c3ccc(-c4ccccc4)cc3)c3cccc4c3oc3ccccc34)cccc21]

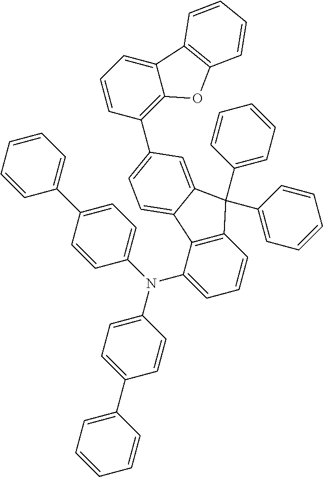 [SMILES: c1ccc(-c2ccc(N(c3ccc(-c4ccccc4)cc3)c3cccc4c3-c3ccc(-c5cccc6c5oc5ccccc56)cc3C4(c3ccccc3)c3ccccc3)cc2)cc1]

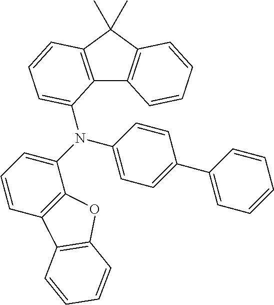 [SMILES: CC1(C)c2ccccc2-c2c(N(c3ccc(-c4ccccc4)cc3)c3cccc4c3oc3ccccc34)cccc21]

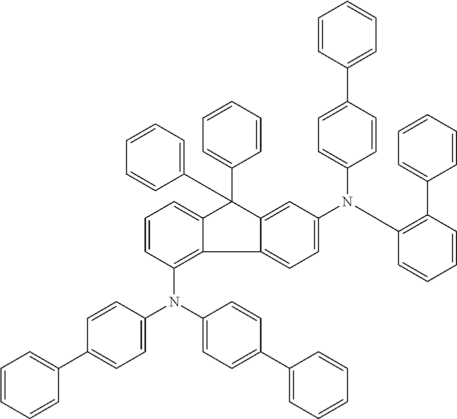 [SMILES: c1ccc(-c2ccc(N(c3ccc4c(c3)C(c3ccccc3)(c3ccccc3)c3cccc(N(c5ccc(-c6ccccc6)cc5)c5ccc(-c6ccccc6)cc5)c3-4)c3ccccc3-c3ccccc3)cc2)cc1]

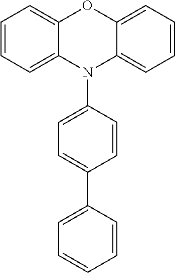 [SMILES: c1ccc(-c2ccc(N3c4ccccc4Oc4ccccc43)cc2)cc1]

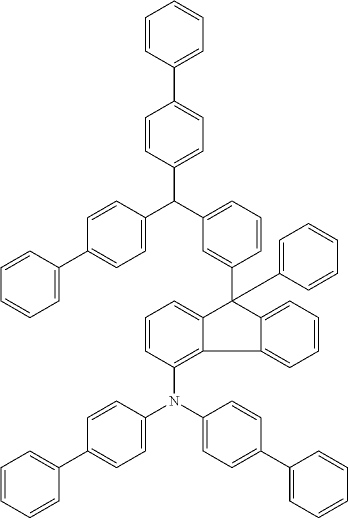 [SMILES: c1ccc(-c2ccc(C(c3ccc(-c4ccccc4)cc3)c3cccc(C4(c5ccccc5)c5ccccc5-c5c(N(c6ccc(-c7ccccc7)cc6)c6ccc(-c7ccccc7)cc6)cccc54)c3)cc2)cc1]

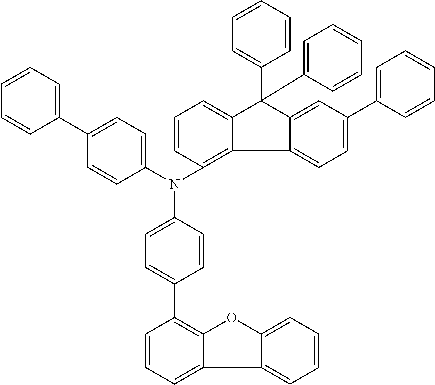 [SMILES: c1ccc(-c2ccc(N(c3ccc(-c4cccc5c4oc4ccccc45)cc3)c3cccc4c3-c3ccc(-c5ccccc5)cc3C4(c3ccccc3)c3ccccc3)cc2)cc1]

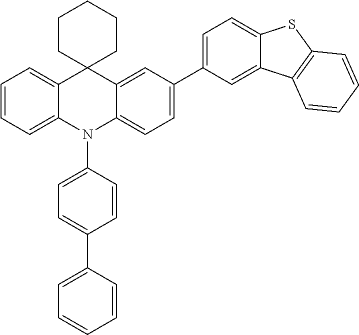 [SMILES: c1ccc(-c2ccc(N3c4ccccc4C4(CCCCC4)c4cc(-c5ccc6sc7ccccc7c6c5)ccc43)cc2)cc1]

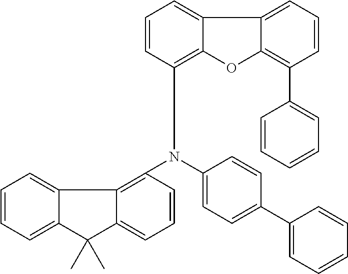 [SMILES: CC1(C)c2ccccc2-c2c(N(c3ccc(-c4ccccc4)cc3)c3cccc4c3oc3c(-c5ccccc5)cccc34)cccc21]

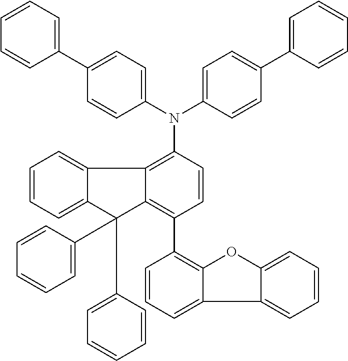 [SMILES: c1ccc(-c2ccc(N(c3ccc(-c4ccccc4)cc3)c3ccc(-c4cccc5c4oc4ccccc45)c4c3-c3ccccc3C4(c3ccccc3)c3ccccc3)cc2)cc1]

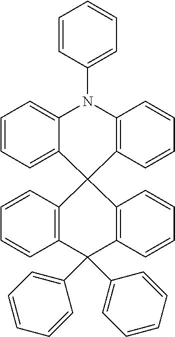 [SMILES: c1ccc(N2c3ccccc3C3(c4ccccc42)c2ccccc2C(c2ccccc2)(c2ccccc2)c2ccccc23)cc1]

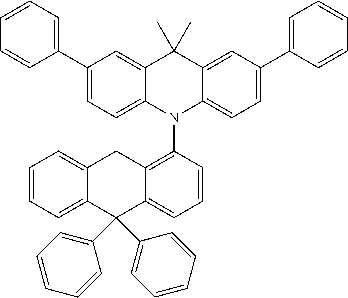 [SMILES: CC1(C)c2cc(-c3ccccc3)ccc2N(c2cccc3c2Cc2ccccc2C3(c2ccccc2)c2ccccc2)c2ccc(-c3ccccc3)cc21]

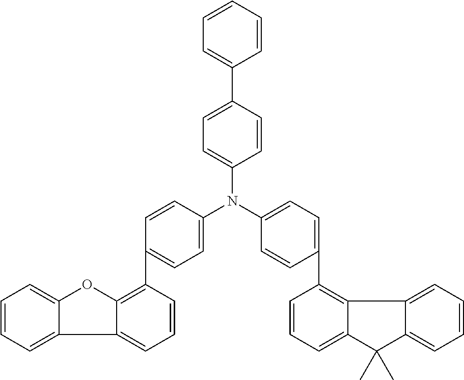 [SMILES: CC1(C)c2ccccc2-c2c(-c3ccc(N(c4ccc(-c5ccccc5)cc4)c4ccc(-c5cccc6c5oc5ccccc56)cc4)cc3)cccc21]

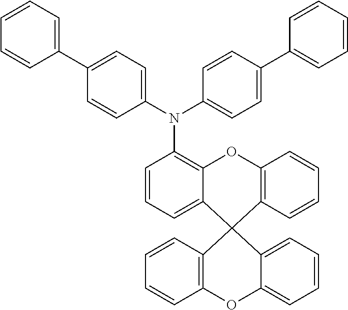 [SMILES: c1ccc(-c2ccc(N(c3ccc(-c4ccccc4)cc3)c3cccc4c3Oc3ccccc3C43c4ccccc4Oc4ccccc43)cc2)cc1]

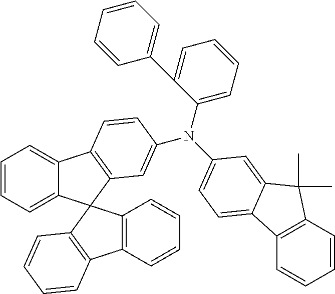 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

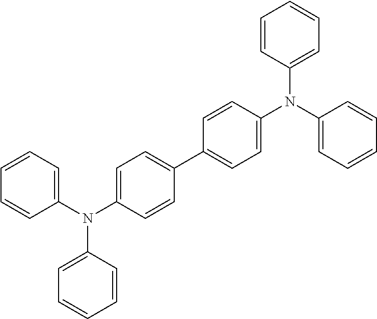 [SMILES: c1ccc(N(c2ccccc2)c2ccc(-c3ccc(N(c4ccccc4)c4ccccc4)cc3)cc2)cc1]

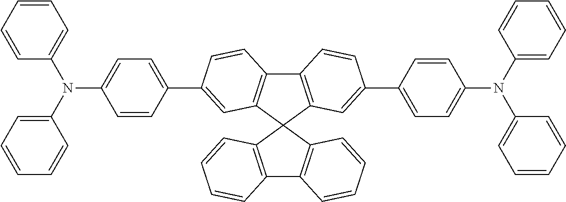 [SMILES: c1ccc(N(c2ccccc2)c2ccc(-c3ccc4c(c3)C3(c5ccccc5-c5ccccc53)c3cc(-c5ccc(N(c6ccccc6)c6ccccc6)cc5)ccc3-4)cc2)cc1]

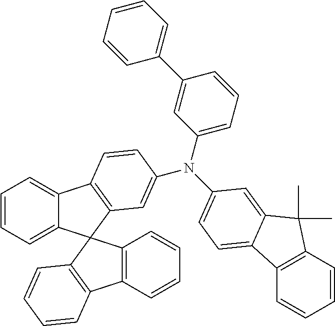 [SMILES: CC1(C)c2ccccc2-c2ccc(N(c3cccc(-c4ccccc4)c3)c3ccc4c(c3)C3(c5ccccc5-c5ccccc53)c3ccccc3-4)cc21]

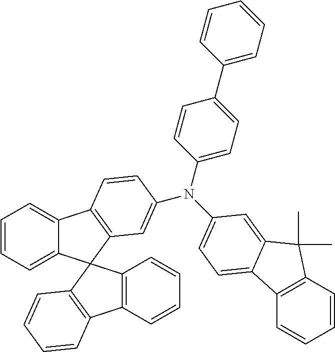 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21]

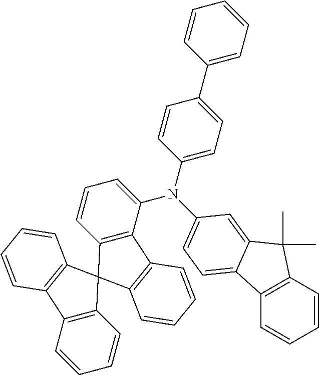 [SMILES: CC1(C)c2ccccc2-c2ccc(N(c3ccc(-c4ccccc4)cc3)c3cccc4c3-c3ccccc3C43c4ccccc4-c4ccccc43)cc21]

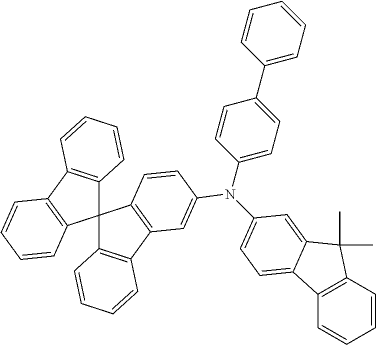 [SMILES: CC1(C)c2ccccc2-c2ccc(N(c3ccc(-c4ccccc4)cc3)c3ccc4c(c3)-c3ccccc3C43c4ccccc4-c4ccccc43)cc21]

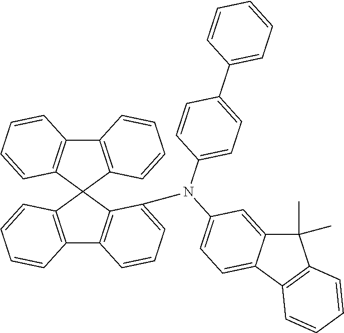 [SMILES: CC1(C)c2ccccc2-c2ccc(N(c3ccc(-c4ccccc4)cc3)c3cccc4c3C3(c5ccccc5-c5ccccc53)c3ccccc3-4)cc21]

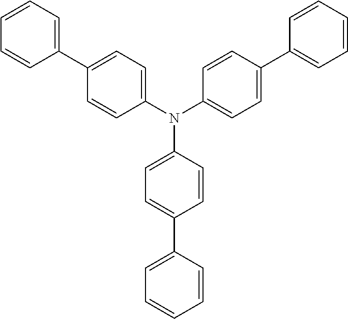 [SMILES: c1ccc(-c2ccc(N(c3ccc(-c4ccccc4)cc3)c3ccc(-c4ccccc4)cc3)cc2)cc1]

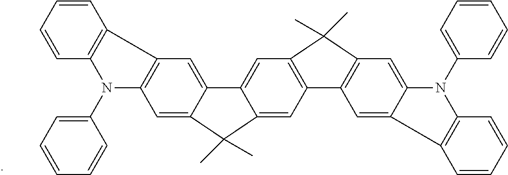 [SMILES: CC1(C)c2cc3c(cc2-c2cc4c5ccccc5n(-c5ccccc5)c4cc21)C(C)(C)c1cc2c(cc1-3)c1ccccc1n2-c1ccccc1]

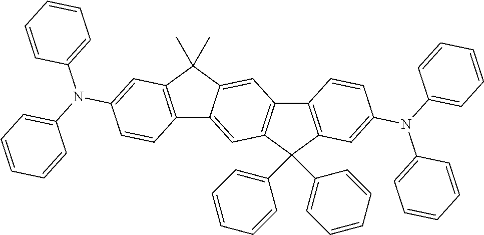 [SMILES: CC1(C)c2cc(N(c3ccccc3)c3ccccc3)ccc2-c2cc3c(cc21)-c1ccc(N(c2ccccc2)c2ccccc2)cc1C3(c1ccccc1)c1ccccc1]

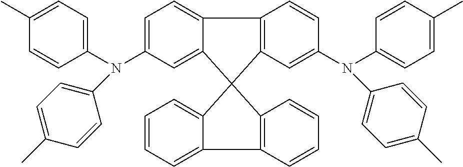

Host systems comprising a hole-transporting host and an electron-transporting host are described, for example, in 2019/158453, WO 2019/007866, WO 2019/007867, WO2019/229011 and WO2021/037401

The organic electroluminescent device comprises cathode, anode and at least one emitting layer. Apart from these layers, it may comprise still further layers, for example in each case one or more hole injection layers, hole transport layers, hole blocker layers, electron transport layers, electron injection layers, exciton blocker layers, electron blocker layers, charge generation layers and/or organic or inorganic p/n junctions. In this case, it is possible that one or more hole transport layers are p-doped, for example with metal oxides such as MoO₃ or WO₃, or with (per)fluorinated electron-deficient aromatics or with electron-deficient cyano-substituted heteroaromatics (for example according to JP 4747558, JP 2006-135145, US 2006/0289882, WO 2012/095143), or with quinoid systems (for example according to EP1336208) or with Lewis acids, or with boranes (for example according to US 2003/0006411, WO 2002/051850, WO 2015/049030) or with carboxylates of the elements of main group 3, 4 or 5 (WO 2015/018539), and/or that one or more electron transport layers are n-doped.

It is likewise possible for interlayers to be introduced between two emitting layers, which have, for example, an exciton-blocking function and/or control charge balance in the electroluminescent device and/or generate charges (charge generation layer, for example in layer systems having two or more emitting layers, for example in white-emitting OLED components). However, it should be pointed out that not necessarily every one of these layers need be present.

In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. Especially preferred are three-layer systems where the three layers exhibit blue, green and orange or red emission (for the basic construction see, for example, WO 2005/011013), or systems having more than three emitting layers. The system may also be a hybrid system wherein one or more layers fluoresce and one or more other layers phosphoresce. A preferred embodiment is tandem OLEDs. A tandem OLED is an OLED that has two or more electroluminescence (EL) units connected electrically in series with unique intermediate connectors within the device. White-emitting organic electroluminescent devices may be used for lighting applications or else with colour filters for full-colour displays.

In accordance with a further preferred embodiment, the organic electroluminescent device comprising the light emitting stack with the emitting layers EMLₓ and EMLₓ₊₁ further comprises another emitting layer EMLₓ₊₂, where the emitting layer EMLₓ₊₂ is arranged between the emitting layer EMLₓ₊₁ and the cathode, and where the emitting layer EMLₓ₊₂ is adjacent to the emitting layer EMLₓ₊₁, where one of the emitting layers EMLₓ and EMLₓ₊₂ has an emission maximum wavelength λ_{R} of from 590 to 660 nm and one of the emitting layers EMLₓ and EMLₓ₊₂ has an emission maximum wavelength λ_{BG} of from 450 to 540 nm; and

where EMLₓ₊₁ has an emission maximum wavelength A_{G}Y from 510 to 585 nm.

Preferably, the interface charge density at the interface of the emitting layers EMLₓ and EMLₓ₊₁, namely ICD_{EMLx},E_{MLx+1}, and the interface charge density at the interface of the emitting layers EMLₓ₊₁ and EMLₓ₊₂, namely ICD_{EMLx+1},E_{MLx+2}, fulfill the following equations:

$$y < {ICD}_{EMLx , EMLx + 1} \leq 0.1 mC {m}^{- 2}$$

$$y < {ICD}_{EMLx + 1 , EMLx + 2} \leq 0.1 mC {m}^{- 2}$$

where y is equal to −1 mC·m⁻² and
where ICD_{EMLx,EMLx+1} and ICD_{EMLx+1,EMLx+2} are respectively the differences between the surface charge density of the emitting layers EMLₓ₊₁ and EMLₓ and between the surface charge density of the emitting layers EMLₓ₊₂ and EMLₓ₊₁ as follows:

$${ICD}_{EMLx , EMLx + 1} = {SCD}_{EMLx + 1} - {SCD}_{EMLx}$$

$${ICD}_{EMLx + 2 , EMLx + 1} = {SCD}_{EMLx + 2} - {SCD}_{EMLx + 1}$$

where the surface charge density SCD is as defined above.

Preferably, the organic electroluminescent device comprises in the following order: an anode;
a light emitting EMLₓ;
a light emitting EMLₓ₊₁;
a light emitting layer EMLₓ+₂, and
a cathode
where
the emitting layers EMLₓ and EMLₓ₊₁ are adjacent;
the emitting layers EMLₓ₊₁ and EMLₓ₊₂ are adjacent; and
where one of the emitting layers EMLₓ and EMLₓ₊₂ has an emission maximum wavelength λ_{R} of from 590 to 660 nm and one of the emitting layers EMLₓ and EMLₓ₊₂ has an emission maximum wavelength λ_{BG} of from 450 to 540 nm; and where EMLₓ₊₁ has an emission maximum wavelength A_{GY} from 510 to 585 nm.

In accordance with a preferred embodiment, EMLₓ has an emission maximum wavelength λ_{R} of from 590 to 660 nm, EMLₓ₊₁ has an emission maximum wavelength A_{GY} from 510 to 585 nm, and EMLₓ₊₂ has an emission maximum wavelength λ_{BG} of from 450 to 540 nm. Therefore, in this case, EMLₓ is a red emitting layer, EMLₓ₊₁ is a green or yellow emitting layer and EMLₓ₊₂ is a blue or green emitting layer.

In accordance with another preferred embodiment, EMLₓ has an emission maximum wavelength λ_{BG} of from 450 to 540 nm, EMLₓ₊₁ has an emission maximum wavelength A_{GY} from 510 to 585 nm, and EMLₓ₊₂ has an emission maximum wavelength λ_{R} of from 590 to 660 nm. Therefore, in this case, EMLₓ is a blue or green emitting layer, EMLₓ₊₁ is a green or yellow emitting layer and EMLₓ₊₂ is a red emitting layer.

It is further preferred that the organic electroluminescent device comprises a light emitting stack comprising a blue light emitting layer between the anode and the cathode, which is separated from the light emitting stack comprising EMLₓ and EMLₓ₊₁ by a charge generation layer.

Preferably, the organic electroluminescent device is a tandem organic electroluminescent device, more preferably a tandem white organic electroluminescent device.

The emitting layers might also comprise a mixture of two or more triplet emitters, especially two or three triplet emitters, together with one or more host materials. In this case, the triplet emitter having the shorter-wave emission spectrum serves as co-host for the triplet emitter having the longer-wave emission spectrum. A preferred embodiment in the case of use of a mixture of three triplet emitters is when two are used as co-host and one as emitting material. These triplet emitters preferably have the emission colours of green, yellow and red or blue, green and orange.

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Mg/Ag, Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs2CO₃, etc.). Likewise useful for this purpose are organic alkali metal complexes, e.g. Liq (lithium quinolinate). The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au.

Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (O—SC) or the emission of light (OLED/PLED, O-LASER).

Preferred anode materials here are conductive mixed metal oxides. Particular preference is given to indium tin oxide (ITO) or indium zinc oxide (IZO). Preference is further given to conductive doped organic materials, especially conductive doped polymers, for example PEDOT, PANI or derivatives of these polymers. It is further preferable when a p-doped hole transport material is applied to the anode as hole injection layer, in which case suitable p-dopants are metal oxides, for example MoO₃ or WO₃, or (per)fluorinated electron-deficient aromatic systems. Further suitable p-dopants are HAT-CN (hexacyanohexaazatriphenylene) or the compound NPD9 from Novaled. Such a layer simplifies hole injection into materials having a low HOMO, i.e. a large HOMO in terms of magnitude.

In the further layers, it is generally possible to use any materials as used according to the prior art for the layers, and the person skilled in the art is able, without exercising inventive skill, to combine any of these materials with the materials of the invention in an electronic device.

Suitable charge transport materials as usable in the hole injection or hole transport layer or electron blocker layer or in the electron transport layer of the organic electroluminescent device of the invention are, for example, the compounds disclosed in Y. Shirota et al., Chem. Rev. 2007, 107(4), 953-1010, or other materials as used in these layers according to the prior art. Preferred hole transport materials which can be used in a hole transport, hole injection or electron blocker layer in the electroluminescent device of the invention are indenofluoreneamine derivatives (for example according to WO 06/122630 or WO 06/100896), the amine derivatives disclosed in EP 1661888, hexaazatriphenylene derivatives (for example according to WO 01/049806), amine derivatives having fused aromatic systems (for example according to U.S. Pat. No. 5,061,569), the amine derivatives disclosed in WO 95/09147, monobenzoindenofluoreneamines (for example according to WO 08/006449), dibenzoindenofluoreneamines (for example according to WO 07/140847), spirobifluoreneamines (for example according to WO 2012/034627, WO 2014/056565), fluoreneamines (for example according to EP 2875092, EP 2875699 and EP 2875004), spirodibenzopyranamines (e.g. EP 2780325) and dihydroacridine derivatives (for example according to WO 2012/150001).

The device is correspondingly (according to the application) structured, contact-connected and finally hermetically sealed, since the lifetime of such devices is severely shortened in the presence of water and/or air.

Additionally preferred is an organic electroluminescent device, characterized in that one or more layers are coated by a sublimation process. In this case, the materials are applied by vapour deposition in vacuum sublimation systems at an initial pressure of typically less than 10⁻⁵ mbar, preferably less than 10⁻⁶ mbar. It is also possible that the initial pressure is even lower or even higher, for example less than 10⁻⁷ mbar.

Preference is likewise given to an organic electroluminescent device, characterized in that one or more layers are coated by the OVPD (organic vapour phase deposition) method or with the aid of a carrier gas sublimation. In this case, the materials are applied at a pressure between 10-5 mbar and 1 bar. A special case of this method is the OVJP (organic vapour jet printing) method, in which the materials are applied directly by a nozzle and thus structured.

Preference is additionally given to an organic electroluminescent device, characterized in that one or more layers are produced from solution, for example by spin-coating, or by any printing method, for example screen printing, flexographic printing, offset printing or nozzle printing, but more preferably LITI (light-induced thermal imaging, thermal transfer printing) or inkjet printing. For this purpose, soluble compounds are needed, which are obtained, for example, through suitable substitution.

The organic electroluminescent device can also be produced as a hybrid system by applying one or more layers from solution and applying one or more other layers by vapour deposition. For example, it is possible to apply an emitting layer comprising a metal complex of the invention and a matrix material from solution, and to apply a hole blocker layer and/or an electron transport layer thereto by vapour deposition under reduced pressure.

These methods are known in general terms to those skilled in the art and can be applied by those skilled in the art without any problems to organic electroluminescent devices comprising the compounds of the invention. In a preferred embodiment of the invention, the emitting layer is applied by a sublimation method.

The invention is illustrated in more detail by the examples which follow, without any intention of restricting it thereby. The person skilled in the art will be able to use the details given, without exercising inventive skill, to produce further electronic devices of the invention and hence to execute the invention over the entire scope claimed.

### DESCRIPTION OF THE FIGURES

FIG. 1: Cross-sectional view illustrating a device used for SCD (Surface Charge Density) experiments according to an embodiment of the present disclosure

FIG. 2: Cross-sectional view illustrating an OLED device according to an embodiment of the present disclosure

### EXAMPLES

### Part 1: Method of Determining the Surface Charge Density (SCD) of a Given Material

### 1.1 Preparation of the Test Devices for SCD Measurements:

Glass plates with structured ITO (50 nm, indium tin oxide) form the substrates on which the OLEDs are processed. Before evaporation of the materials, the substrates are cleaned in a wet process (using filtered deionized water and the detergent “Extran” of Merck KGaA). Glass substrates are then dried for 15 minutes at 170° C. Subsequently the clean and dry substrates are exposed to an oxygen and subsequently to an argon plasma.

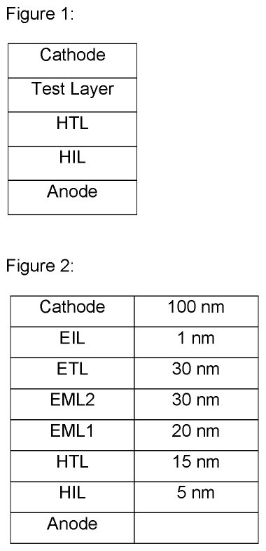

The structure of the test devices used for the SCD measurements is represented in FIG. 1. The anode is an ITO electrode, the HIL (Hole Injection Layer) has a thickness of 10 nm and consists in a mixture of HTM1 and PD1 (95%:5%) (meaning HTM1 is present in the layer in a proportion by weight of 95% and PD1 is present in the layer in a proportion by volume of 5%), the HTL (Hole Transport Layer) has a thickness of 100 nm and consists of HTM1, the test layer has a thickness of 40 nm and consists of the investigated material and TMM-1 (x %:(100-x) %) and the cathode is a 100 nm thick aluminium electrode. The symbol x represents the concentration of the investigated material in the corresponding layer.

All materials are applied by thermal vapour deposition in a vacuum chamber. The structure of the materials is depicted in Table 1 below:

TABLE 1
Materials used in stacks for SCD measurements

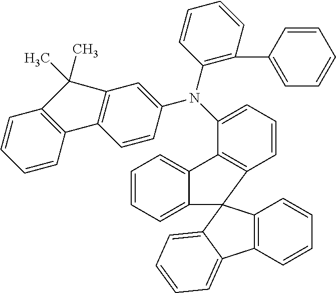 [SMILES: CC1(C)c2ccccc2-c2ccc(N(c3ccccc3-c3ccccc3)c3cccc4c3-c3ccccc3C43c4ccccc4-c4ccccc43)cc21]

HTM1 (CAS 1450933-44-4)

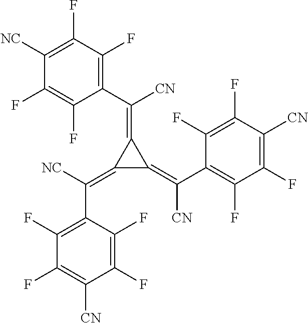 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

PD1 (CAS 1224447-88-4)

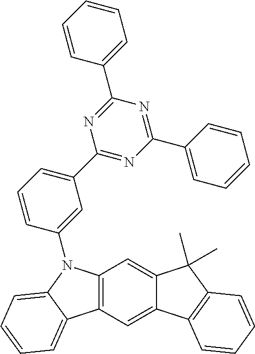 [SMILES: CC1(C)c2ccccc2-c2cc3c4ccccc4n(-c4cccc(-c5nc(-c6ccccc6)nc(-c6ccccc6)n5)c4)c3cc21]

TMM1 (CAS 1257248-13-7)

### 1.2 Determination of the Build-In Voltage U_{bi}

All test devices for SCD measurements are characterized by standard current/voltage/luminance measurements (IUL measurements) assuming a Lambertian emission profile. For the analysis of SCDs, the build-in voltage U_{b}i is taken from the current/voltage characteristics.

### 1.3 Dielectric Spectroscopy Measurements

The Surface Charge Density of the investigated material in determined via dielectric spectroscopy measurements using an Alpha-NB Single-Unit Dielectric Analyzer (Novocontrol technologies) combined with a dielectric interface (Novocontrol ZGS). This setup allows frequency sweeps covering a range from f=10⁻² to f=10⁷ Hz. The AC rms voltage UAC is set to 100 mV for all measurements and the superimposed DC bias U_{D}C is varied between −7 and 7 V. The experimental capacity C-f-U_{DC} curves were analyzed according to the theoretical description in J. Appl. Phys. 107, 1-9 (2010) for Uₜᵣₐₙₛ and C_{SCD} with a fixed frequency f=104 Hz in order to observe all necessary quantities for the final surface charge density SCD of the material under test:

$$SCD = \frac{{C}_{SCD}}{A} ( {U}_{trans} - {U}_{bi} )$$

As mentioned above, the build-in voltage Ubi is taken from the IUL measurements. “A” depicts the active electrode area of the OLED device. Final surface charge density for a material is calculated/extrapolated from a set of experiments where the concentration of the investigated material is x=0%, 10%, 20%, 30%.

### Part 2: Determination of the HOMO and LUMO Energies of the Materials by Cyclic Voltammetry

For Cyclic Voltammetry measurements, a potentiostat from Metronon pAUTOLAB type Ill in a three electrode setup was used including working-electrode (Au), counter electrode (Pt) and reference-electrode (Ag/AgCl, KCl 3M). Oxidation was measured in Methylenchloride (DCM) and reduction in Tetrahydrofuran (THF) and tetrabutylammonium hexafluorophosphate (0.11 M) was added as electrolyte.

Ferrocene or decamethylferrocene were used as internal standard.

### Part 3: Fabrication of OLEDs

Glass plates with structured ITO (50 nm, indium tin oxide) form the substrates on which the OLEDs are processed. Before evaporation of the materials, the substrates are cleaned in a wet process (using filtered deionized water and the detergent “Extran” of Merck KGaA). Glass substrates are then dried for 15 minutes at 170° C. Subsequently the clean and dry substrates are exposed to an oxygen and subsequently to an argon plasma.

The structure of the OLED devices is represented in FIG. 2. The thickness of the different layers is also indicated in FIG. 2. The anode is an ITO electrode, the HIL (Hole Injection Layer) consists in a mixture of HTM2 and PD1 (90%:10%), the HTL (Hole Transport Layer) consists of HTM2, the emitting layers EML1 and EML2 consist of a hole-transporting host material, a electron-transporting host material and a light-emitting compound, the ETL consists of ETM1 and the EIL consists of LiF (lithium fluoride). The composition of the emitting layers EML1 and EML2 in the different devices is represented in Table 2 below. The structures of the materials used in the OLEDs are depicted in Table 3, except for HTM1, PD1 and TMM1 which have been already depicted in Table 2. For the triplet emitters we name the red emitters TER, the yellow emitters TEY and the green emitters TEG.

TABLE 2
Composition of the emitting layers in the OLED stacks

| | EML1 | | | EML2 | | |
|---|---|---|---|---|---|---|
| C1 | HTM2 | TMM2 | TER1 | TMM1 | TMM3 | TEG2 |
| | 48.3% | 48.2% | 3.5% | 46.0% | 46.0% | 8% |
| C2 | HTM2 | TMM2 | TER1 | TMM1 | HTM3 | TEG5 |
| | 38.6% | 57.9% | 3.5% | 35.2% | 52.8% | 12% |
| C3 | HTM5 | TER2 | | HTM6 | TEG7 | |
| | 95% | 5.0% | | 92% | 8% | |
| C4 | HTM2 | TMM2 | TEG2 | TMM1 | TMM3 | TER1 |
| | 35.2% | 52.8% | 12% | 48.25% | 48.25% | 3.5% |
| C5 | HTM2 | TMM2 | TEG2 | TMM1 | TMM3 | TER1 |
| | 26.4% | 61.6% | 12% | 48.25% | 48.25% | 3.5% |
| C6 | HTM2 | TMM2 | TEG2 | TMM1 | TMM3 | TER1 |
| | 17.6% | 70.4% | 12% | 48.25% | 48.25% | 3.5% |
| C7 | HTM2 | TMM2 | TER1 | TMM1 | TMM3 | TEY1 |
| | 48.3% | 48.2% | 3.5% | 37.5% | 37.5% | 25% |
| C8 | HTM2 | TMM2 | TER1 | TMM1 | TMM3 | TEY1 |
| | 48.3% | 48.2% | 3.5% | 42.5% | 42.5% | 15% |
| E1 | HTM2 | TMM2 | TER1 | TMM1 | TMM3 | TEG1 |
| | 38.6% | 57.9% | 3.5% | 44.0% | 44.0% | 12% |
| E2 | HTM2 | TMM2 | TER1 | TMM1 | TMM3 | TEG3 |
| | 38.6% | 57.9% | 3.5% | 44.0% | 44.0% | 12% |
| E3 | HTM2 | TMM2 | TER1 | TMM1 | TMM3 | TEG612% |
| | 38.6% | 57.9% | 3.5% | 44.0% | 44.0% | |
| E4 | HTM2 | TMM2 | TER1 | TMM1 | TMM3 | TEG4 |
| | 38.6% | 57.9% | 3.5% | 29.0% | 59.0% | 12% |
| E5 | HTM2 | TMM2 | TER1 | TMM1 | TMM3 | TEG4 |
| | 38.6% | 57.9% | 3.5% | 30.0% | 62.0% | 8% |
| E6 | HTM2 | TMM2 | TER1 | TMM1 | TMM3 | TEG4 |
| | 38.6% | 57.9% | 3.5% | 28.0% | 56.0% | 16% |
| E7 | HTM2 | TMM2 | TER1 | TMM1 | TMM3 | TEG1 |
| | 38.6% | 57.9% | 3.5% | 44.0% | 44.0% | 12% |
| E8 | HTM2 | TMM2 | TER1 | TMM1 | TMM3 | TEY3 |
| | 48.3% | 48.2% | 3.5% | 37.5% | 37.5% | 25% |
| E9 | HTM2 | TMM2 | TER1 | TMM1 | TMM3 | TEY3 |
| | 48.3% | 48.2% | 3.5% | 42.5% | 42.5% | 15% |
| E10 | HTM7 | TMM4 | TER1 | TMM1 | TMM3 | TEY2 |
| | 68.2% | 29.3% | 2.5% | 26.4% | 61.6% | 12% |
| E11 | HTM7 | TMM4 | TER1 | TMM1 | TMM3 | TEY2 |
| | 68.2% | 29.3% | 2.5% | 44% | 64% | 12% |
| E12 | HTM7 | TMM4 | TER1 | TMM1 | TMM3 | TEY2 |
| | 68.2% | 29.3% | 2.5% | 61.6% | 26.4% | 12% |

| | EML1 | | | EML2 | | | EML3 | | |
|---|---|---|---|---|---|---|---|---|---|
| E13 | HTM2 | TMM2 | TER1 | TMM1 | TMM3 | TEY4 | TMM5 | TMM3 | TEG8 |
| | 39.2% | 58.8% | 2% | 41.6% | 41.7% | 16.7% | 18.7% | 74.8% | 6.5% |
| E14 | HTM2 | TMM2 | TER1 | TMM1 | TMM3 | TEY4 | TMM5 | TMM3 | TEG8 |
| | 39.2% | 58.8% | 2% | 41.6% | 41.7% | 16.7% | 28% | 65.5% | 6.5% |
| E15 | HTM2 | TMM2 | TER1 | TMM1 | TMM3 | TEY4 | TMM5 | TMM3 | TEG8 |
| | 39.2% | 58.8% | 2% | 41.6% | 41.7% | 16.7% | 37.4% | 56.1% | 6.5% |
| E16 | HTM2 | TMM2 | TER1 | TMM1 | TMM3 | TEY4 | TMM6 | TMM3 | TEG8 |
| | 39.2% | 58.8% | 2% | 41.6% | 41.7% | 16.7% | 18.7% | 74.8% | 6.5% |
| E17 | HTM2 | TMM2 | TER1 | TMM1 | TMM3 | TEY4 | TMM6 | TMM3 | TEG8 |
| | 39.2% | 58.8% | 2% | 41.6% | 41.7% | 16.7% | 28% | 65.5% | 6.5% |
| E18 | HTM2 | TMM2 | TER1 | TMM1 | TMM3 | TEY4 | TMM6 | TMM3 | TEG8 |
| | 39.2% | 58.8% | 2% | 41.6% | 41.7% | 16.7% | 37.4% | 56.1% | 6.5% |
| E19 | HTM2 | TMM2 | TER1 | TMM1 | TMM3 | TEY4 | TMM5 | TMM3 | TEG8 |
| | 39.2% | 58.8% | 2% | 41.6% | 41.7% | 16.7% | 27.5% | 64.2% | 8.3% |
| E20 | HTM2 | TMM2 | TER1 | TMM1 | TMM3 | TEY4 | TMM5 | TMM3 | TEG8 |
| | 39.2% | 58.8% | 2% | 41.6% | 41.7% | 16.7% | 27% | 63% | 10% |
| E21 | HTM2 | TMM2 | TER1 | TMM1 | TMM3 | TEY4 | TMM6 | TMM3 | TEG8 |
| | 39.2% | 58.8% | 2% | 41.6% | 41.7% | 16.7% | 27.5% | 64.2% | 8.3% |
| E22 | HTM2 | TMM2 | TER1 | TMM1 | TMM3 | TEY4 | TMM6 | TMM3 | TEG8 |
| | 39.2% | 58.8% | 2% | 41.6% | 41.7% | 16.7% | 27% | 63% | 10% |
| C10 | HTM2 | TMM2 | TER1 | TMM1 | TMM3 | TEY4 | TMM5 | TMM3 | TEG8 |
| | 39.2% | 58.8% | 2% | 41.6% | 41.7% | 16.7% | 45% | 45% | 10% |
| E23 | HTM2 | TMM2 | TER1 | TMM1 | TMM3 | TEY4 | TMM6 | TMM3 | TEG8 |
| | 39.2% | 58.8% | 2% | 41.6% | 41.7% | 16.7% | 45% | 45% | 10% |

TABLE 3
Materials used in OLED stacks

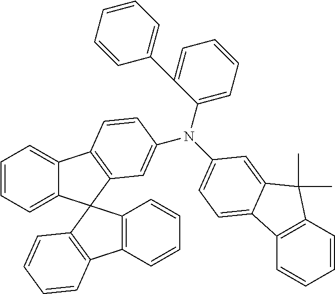 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

HTM2 (CAS 1364603-07-5)

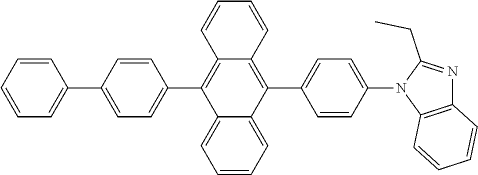 [SMILES: CCc1nc2ccccc2n1-c1ccc(-c2c3ccccc3c(-c3ccc(-c4ccccc4)cc3)c3ccccc23)cc1]

ETM1 (CAS 1254961-38-0)

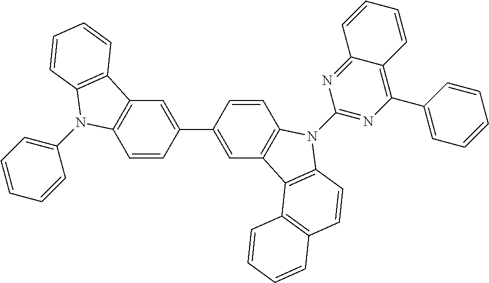 [SMILES: c1ccc(-c2nc(-n3c4ccc(-c5ccc6c(c5)c5ccccc5n6-c5ccccc5)cc4c4c5ccccc5ccc43)nc3ccccc23)cc1]

TMM2 (CAS 1365548-87-3)

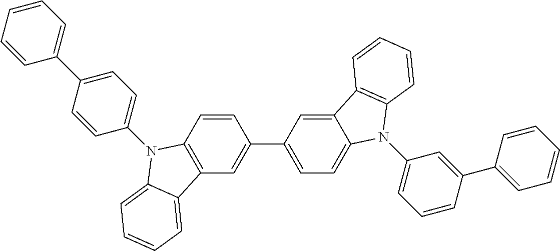 [SMILES: c1ccc(-c2ccc(-n3c4ccccc4c4cc(-c5ccc6c(c5)c5ccccc5n6-c5cccc(-c6ccccc6)c5)ccc43)cc2)cc1]

TMM3 (CAS 1643479-47-3)

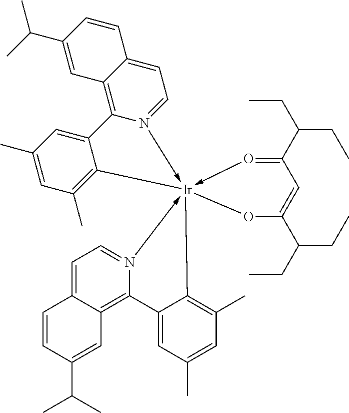

TER1 (CAS 1643580-54-4)

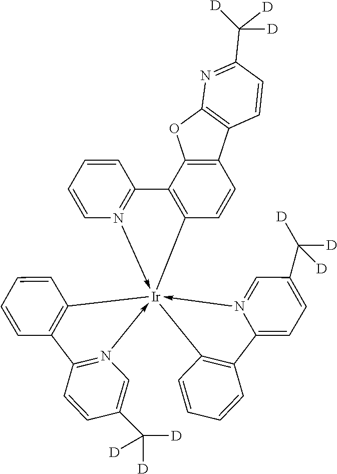

TEG1 (CAS 1609368-32-2)

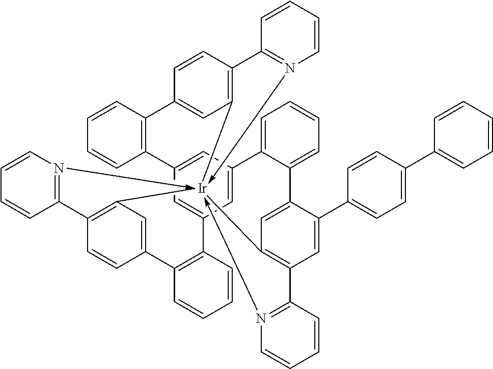

TEG2 (CAS 2245866-06-0)

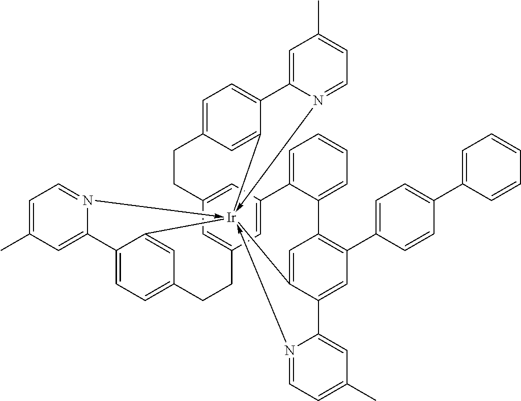

TEG3 (WO 2019/158453)

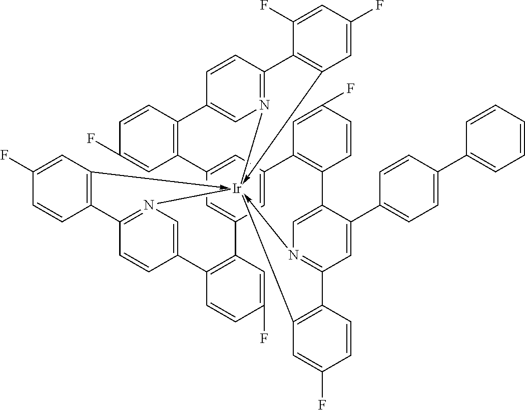

TEG4 (CAS 2719773-99-4)

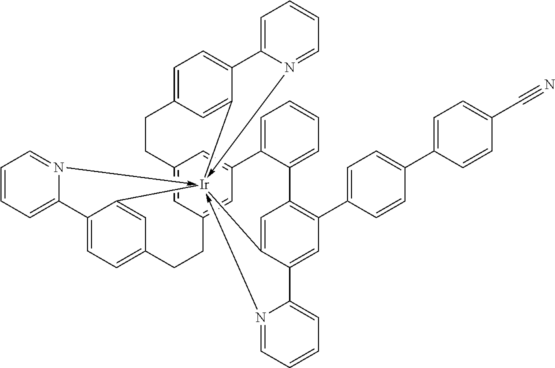

TEG5 (CAS 2765611-34-3)

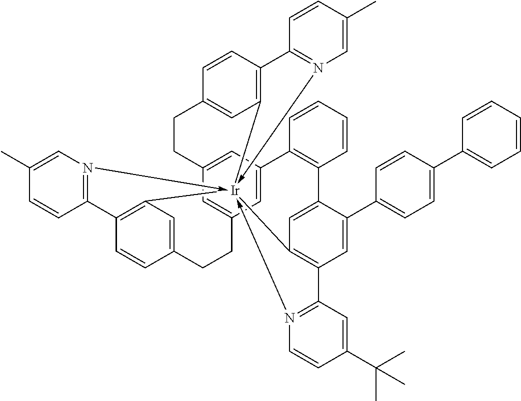

TEG6 (CAS 2719774-65-7)

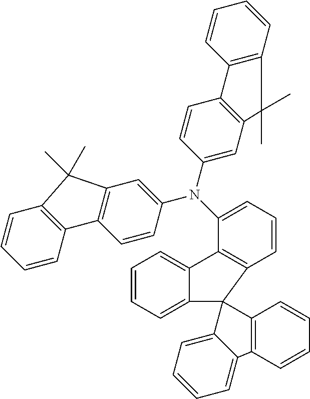 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21]

HTM3 (CAS 1450933-45-4)

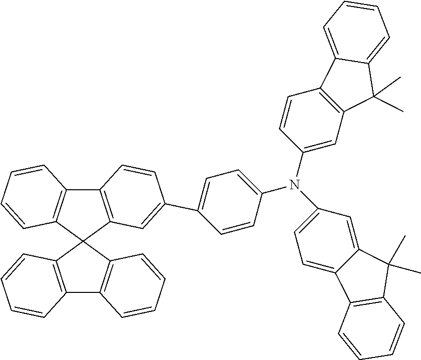 [SMILES: CC1(C)c2ccccc2-c2ccc(N(c3ccc(-c4ccc5c(c4)C4(c6ccccc6-c6ccccc64)c4ccccc4-5)cc3)c3ccc4c(c3)C(C)(C)c3ccccc3-4)cc21]

HTM4 (CAS 2222369-35-7)

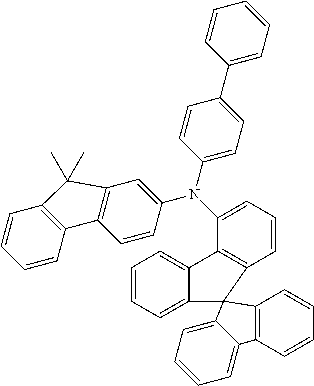 [SMILES: CC1(C)c2ccccc2-c2ccc(N(c3ccc(-c4ccccc4)cc3)c3cccc4c3-c3ccccc3C43c4ccccc4-c4ccccc43)cc21]

HTM7 (CAS 1450933-88-6)

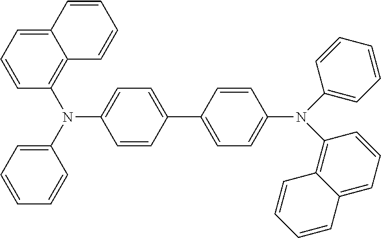 [SMILES: c1ccc(N(c2ccc(-c3ccc(N(c4ccccc4)c4cccc5ccccc45)cc3)cc2)c2cccc3ccccc23)cc1]

HTM5 (CAS 123847-85-8)

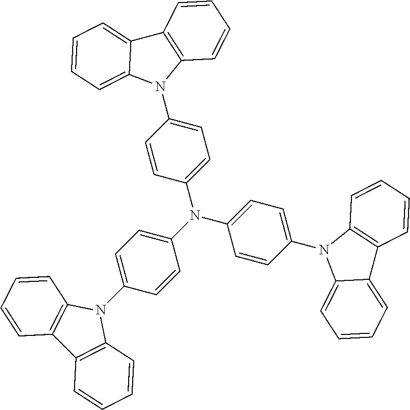 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

HTM6 (CAS 139092-78-7)

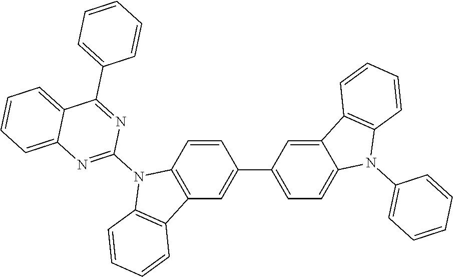 [SMILES: c1ccc(-c2nc(-n3c4ccccc4c4cc(-c5ccc6c(c5)c5ccccc5n6-c5ccccc5)ccc43)nc3ccccc23)cc1]

TMM4 (CAS 1398395-92-0)

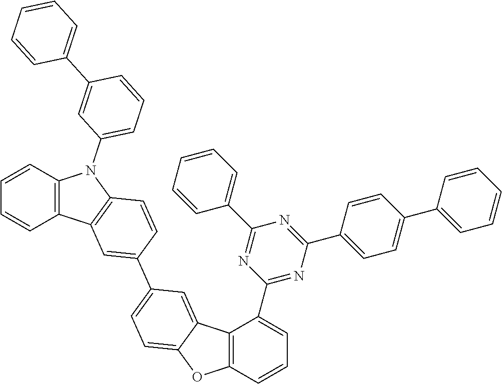 [SMILES: c1ccc(-c2ccc(-c3nc(-c4ccccc4)nc(-c4cccc5oc6ccc(-c7ccc8c(c7)c7ccccc7n8-c7cccc(-c8ccccc8)c7)cc6c45)n3)cc2)cc1]

TMM5 (WO 2015/169412)

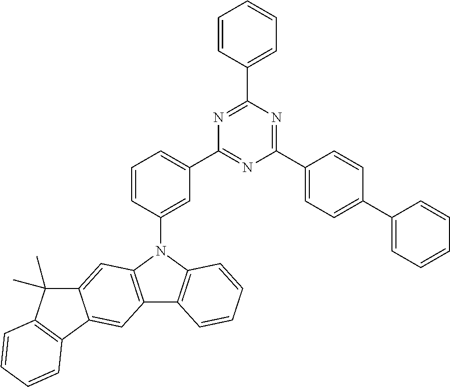 [SMILES: CC1(C)c2ccccc2-c2cc3c4ccccc4n(-c4cccc(-c5nc(-c6ccccc6)nc(-c6ccc(-c7ccccc7)cc6)n5)c4)c3cc21]

TMM6 (CAS 1681086-55-4)

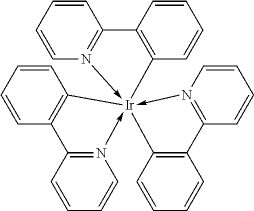

TEG7 (CAS 693794-98-8)

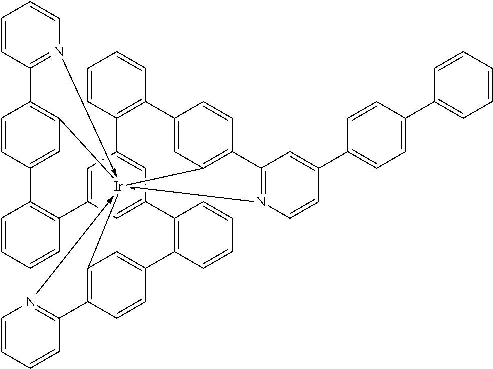

TEY1 (CAS 2245945-28-0)

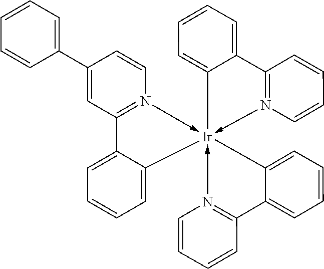

TEY2 (CAS 1215281-24-5)

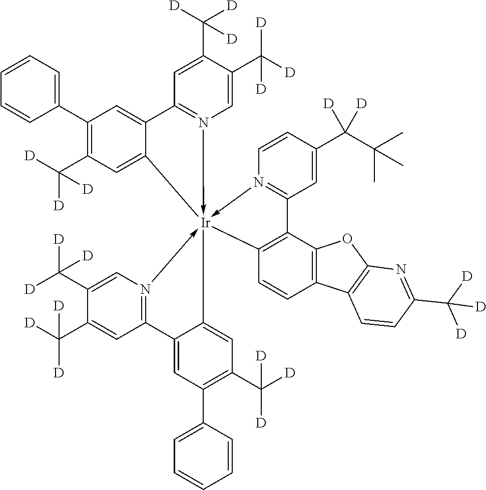

TEG8 (CAS 2245340-37-6)

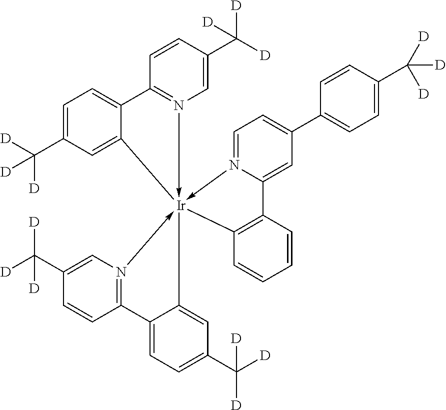

TEY4 (CAS 2085797-96-0)

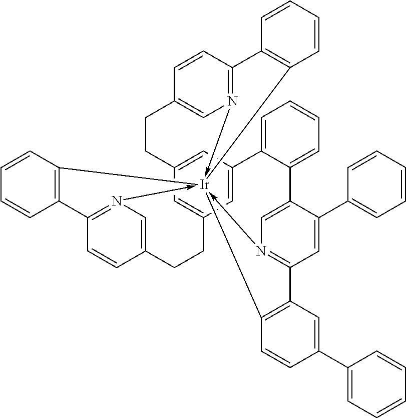

TEY3 (WO 2022/229298)

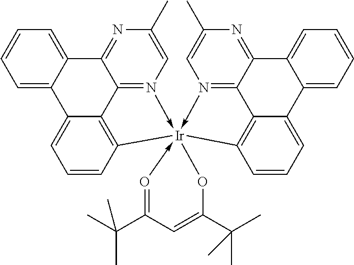

TER2 (CAS 1182724-55-5)

### Part 4: Determination of the Color Shift

All OLEDs are characterized by standard current/voltage/luminance measurements (IUL measurements) assuming a Lambertian emission profile. The electroluminescent spectra and the corresponding CIE 1931 x and y color coordinates are determined at a constant current density of 10 mA/cm² and 50 mA/cm². The color shift is then defined as the difference between the CIEy coordinate at 10 mA/cm² and the CIEy coordinate at 50 mA/cm²:

$$Δ CIEy = {CIEy}_{10 m A / c {m}^{2}} - {CIEy}_{50 m A / c {m}^{2}}$$

A colorstable device is considered with |ACIEy|≤0.012.

### Part 5: Results

The SCDs and electronic properties of the materials are shown in Table 4 below.

The Interface Charge Density (ICD) at the interfaces of EMLₓ and EMLₓ₊₁ as well as the color shift parameter ΔCIEy as defined above are shown in Tables 5, 6, 7, 8 for the following cases:
Table 5: EML1 with red emitter and EML2 with green emitter or EML2 with green and EML1 with red
Table 6: EML1 with red emitter and EML2 with yellow emitter
Table 7: EML1 with red, EML2 with yellow and EML3 with green emitter

For each of these cases we show comparative examples “C” which are not colorstable (|ΔCIEy|≥0.012) because of wrong ICD conditions and several examples “E” which are colorstable (|ΔCIEy| 0.012)

TABLE 4
SCD, HOMO, LUMO of the materials

| | SCD | HOMO CV | LUMO CV |
|---|---|---|---|
| Material | (mC/m²) | (eV) | (eV) |
| HTM1 | −0.03 | −5.26 | −1.54 |
| HTM2 | −0.25 | −5.15 | −1.56 |
| HTM3 | −0.38 | −5.18 | −1.54 |
| HTM4 | −0.52 | −5.09 | −1.90 |
| TMM1 | −0.95 | −5.50 | −2.63 |
| TMM2 | −0.26 | −5.40 | −2.72 |
| TMM3 | −0.57 | −5.34 | −1.76 |
| TER1 | −5.04 | −4.97 | −2.26 |
| TEG1 | −5.95 | −5.05 | −2.01 |
| TEG2 | +8.00 | −5.06 | −2.06 |
| TEG3 | +1.85 | −4.91 | −1.91 |
| TEG4 | −2.46 | −5.30 | −2.34 |
| TEG5 | +2.12 | −4.99 | −2.20 |
| TEG6 | −5.14 | −4.93 | −1.83 |
| TEG7 | +3.16 | −5.08 | −1.94 |
| TEY1 | +3.59 | −5.05 | −2.32 |
| TEY2 | +3.64 | −5.07 | −2.26 |
| TEG8 | −3.43 | −4.95 | −1.92 |
| TEY4 | +1.20 | −4.97 | −2.11 |
| TEY3 | −2.41 | −5.03 | −2.19 |
| TER2 | −7.0 | −5.38 | −2.55 |
| HTM7 | −0.13 | −5.26 | −1.62 |
| HTM5 | 0.0 | −5.10 | −2.10 |
| HTM6 | 0.0 | −5.45 | −1.62 |
| TMM4 | −0.16 | −5.37 | −2.67 |
| TMM5 | −2.12 | −5.56 | −2.66 |
| TMM6 | −1.42 | −5.50 | −2.68 |
| ETM1 | | −5.61 | −2.38 |

TABLE 5
OLEDs comprising EML1(red) and EML2(green) or EML1(green)
and EML2(red) with colorshift and interface charge density

| | | ICD at EML1/EML2 |
|---|---|---|
| | \|ΔCIEy\| | (mC/m²) |
| C1 | 0.034 | +0.36 |
| C2 | 0.029 | +0.13 |
| C3 | 0.040 | +0.60 |
| C4 | 0.022 | −1.65 |
| C5 | 0.018 | −1.65 |
| C6 | 0.015 | −1.65 |
| E1 | 0.011 | −0.96 |
| E2 | 0.002 | −0.17 |
| E3 | 0.010 | −0.86 |
| E4 | 0.003 | −0.48 |
| E5 | 0.005 | −0.41 |
| E6 | 0.001 | −0.56 |
| E7 | 0.010 | −0.85 |

As shown in Table 5, the OLED of comparative examples C1-C6 having two adjacent emitting layers with an ICD>0.1 mC/m² or ICD<−1 mC/m² do not show satisfying properties in terms of color shift (|ΔCIEy|>0.012), whereas the OLEDs according to the examples E1-E7, where |ΔCIEy|≤0.012, show better color stability than the comparative examples

TABLE 6
OLEDs comprising EML1(red) and EML2(yellow)
with colorshift and interface charge density

| | | ICD at EML1/EML2 |
|---|---|---|
| | \|ΔCIEy\| | (mC/m²) |
| C7 | 0.013 | +0.75 |
| C8 | 0.013 | +0.31 |
| E8 | 0.000 | −0.75 |
| E9 | 0.000 | −0.59 |
| E10 | 0.004 | +0.03 |
| E11 | 0.003 | −0.04 |

The OLEDs C7 and C8 do not show satisfying properties in terms of color shift (|ΔCIEy|>0.012), whereas the OLEDs according to the examples E8-E11, where |ΔCIEy|≤0.012, show better color stability than the comparative examples

TABLE 7
OLEDs comprising EML1(red), EML2(yellow) and EML3(green)
with colorshift and interface charge density at EML2/EML3

| | | ICD at EML1/EML2 | |
|---|---|---|---|
| | \|ΔCIEy\| | (mC/m²) | ICD at EML2/EML3 |
| C10 | 0.013 | −0.08 | −1.12 |
| E13 | 0.002 | −0.08 | −0.61 |
| E14 | 0.003 | −0.08 | −0.75 |
| E15 | 0.007 | −0.08 | −0.90 |
| E16 | 0.000 | −0.08 | −0.48 |
| E17 | 0.002 | −0.08 | −0.56 |
| E18 | 0.001 | −0.08 | −0.64 |
| E19 | 0.006 | −0.08 | −0.80 |
| E20 | 0.007 | −0.08 | −0.84 |
| E21 | 0.003 | −0.08 | −0.61 |
| E22 | 0.006 | −0.08 | −0.65 |
| E23 | 0.007 | −0.08 | −0.81 |

As shown in Table 7, most OLEDs are corlorstable (|ΔCIEy| 0.012) except for C10 due to a too negative ICD at the interface between EML2 EML3. Also here the examples E13-E23 having a suitable ICD(EML2/EML3) lead to more color stable OLEDs.

1. An organic electroluminescent device comprising:
an anode;
a cathode, arranged opposite to the anode;
at least one light emitting stack arranged between the anode and the cathode;
wherein the one light emitting stack comprises a first emitting layer, EMLₓ and a second emitting layer, EML_{x+1;}
wherein EMLₓ₊₁ is arranged between the emitting layer EMLₓ and the cathode, and EMLₓ₊₁ is adjacent to the first emitting layer EMLₓ,
characterized in that the interface charge density at the interface of the emitting layers EMLₓ and EMLₓ₊₁, namely ICD_{EMLx,EMLx+1}, fulfills the following equation:
$$y < {ICD}_{EMLx , EMLx + 1} \leq 0.1 mC \cdot {m}^{- 2}$$
where y is equal to −1 mC·m⁻² and
where ICD_{EMLx,EMLx+1} is the difference between the surface charge density of the emitting layers EMLₓ₊₁ and EMLₓ:
$${ICD}_{EMLx , EMLx + 1} = {SCD}_{EMLx + 1} - {SCD}_{EMLx}$$
where the surface charge density SCD of an emitting layer comprising n materials, SCD (EML), corresponds to the sum of the surface charge densities SCDᵢ of each material i present in the corresponding emitting layer multiplied by their proportion ai in the layer:
$$SCD ( EML ) = {\sum }_{i = 1}^{n} {α}_{i} * {SCD}_{i}$$
where
αᵢ is the proportion of the material i in the corresponding emitting layer by weight, based on the total weight of the corresponding layer; and where
SCDᵢ is the surface charge density of the material i as determined by dielectric spectroscopy measurements.

2. An organic electroluminescent device according to claim 1, characterized in that y is equal to −0.8 mC·m⁻².

3. An organic electroluminescent device according to claim 1, characterized in that
$$y < {ICD}_{EMLx , EMLx + 1} \leq 0 mC \cdot {m}^{- 2}$$
where y has the same meaning as in claim 1.

4. An organic electroluminescent device according to claim 1, characterized in that one of the emitting layers selected from EMLₓ and EMLₓ₊₁ has an emission maximum wavelength λ_{R} of from 590 to 660 nm.

5. An organic electroluminescent device according to claim 4, characterized in that the emitting layer having an emission maximum wavelength λ_{R} comprises at least one emitter selected from red phosphorescent emitters.

6. An organic electroluminescent device according to claim 4, characterized in that that the emitting layer having an emission maximum wavelength λ_{R} comprises at least one emitter selected from red phosphorescent emitters and a host system.

7. An organic electroluminescent device according to claim 6, where the host system comprises at least two host materials, wherein one host material is a hole-transporting host material and the other host material is an electron-transporting host material.

8. An organic electroluminescent device according to claim 7, characterized in that:
the at least one emitter has a LUMO of from −2.00 eV to −2.50 eV and a HOMO of from −4.90 eV to −5.20 eV;
the hole-transporting host material has a LUMO of from −1.40 eV to −1.70 eV and a HOMO of from −5.0 eV to −5.35 eV; and
the electron-transporting host material has a LUMO of from −2.5 eV to −2.9 eV and a HOMO of from −5.3 eV to −5.6 eV.

9. An organic electroluminescent device according to claim 5, characterized in that the at least one emitter is a red phosphorescent emitter selected from compounds of formula (M1): 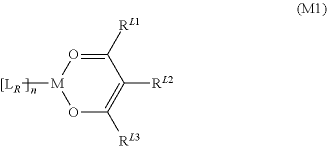
where
M is selected from Ir or Pt;
L_{R} is a bidentate ligand coordinating by one N- and one C-atom;
n is a number equal to 1, if M is Pt, and to 2, if M is Ir;
R^{L1}, R^{L2}, R^{L3} are on each occurrence, identically or differently, selected from H, D, F, a straight-chain alkyl group having 1 to 40 C atoms or a branched or cyclic alkyl having 3 to 40 C atoms, each of which may be substituted by one or more radicals R^{L};
R^{L} stands on each occurrence, identically or differently, for H, D, F, CN, a straight-chain alkyl, alkoxy or thioalkyl group having 1 to 20 C atoms or branched or cyclic alkyl, alkoxy or thioalkyl group having 3 to 20 C atoms, where one or more H atoms may be replaced by D or F.

10. An organic electroluminescent device according to claim 5, characterized in that the at least one emitter is a red phosphorescent emitter selected from compounds of formula (M1-1): 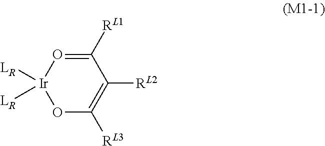
where
L_{R} is a bidentate ligand coordinating by one N- and one C-atom:
R^{L1}, R^{L2}, R^{L3} are on each occurrence, identically or differently, selected from H, D, F, a straight-chain alkyl group having 1 to 40 C atoms or a branched or cyclic alkyl having 3 to 40 C atoms, each of which may be substituted by one or more radicals R^{L}
R^{L} stands on each occurrence, identically or differently, for H, D, F, CN, a straight-chain alkyl, alkoxy or thioalkyl group having 1 to 20 C atoms or branched or cyclic alkyl, alkoxy or thioalkyl group having 3 to 20 C atoms, where one or more H atoms may be replaced by D or F.

11. An organic electroluminescent device according to claim 5, characterized in that the at least one emitter is present in the layer in a proportion of 0.5-50%.

12. An organic electroluminescent device according to claim 7, characterized in that the host system is present in the emitting layer in a proportion of 70-99.5%.

13. An organic electroluminescent device according to claim 1, characterized in that one of the emitting layers selected from EMLₓ and EMLₓ₊₁ has an emission maximum wavelength λ_{BGY} from 450 to 585 nm.

14. An organic electroluminescent device according to claim 13, characterized in that the emitting layer having an emission maximum wavelength λ_{BGY} comprises at least one emitter selected from blue, green and yellow fluorescent or phosphorescent emitters.

15. An organic electroluminescent device according to claim 13, characterized in that that the emitting layer having an emission maximum wavelength λ_{BGY} comprises at least one emitter selected from blue, green and yellow fluorescent or phosphorescent emitters and a host system.

16. An organic electroluminescent device according to claim 15, wherein one host material is a hole-transporting host material and the other host material is an electron-transporting host material.

17. An organic electroluminescent device according to claim 16, characterized in that:
the at least one emitter has a LUMO of from −1.65 eV to −2.05 eV and a HOMO of from −4.85 eV to −5.20 eV;
the hole-transporting host material has a LUMO of from −1.55 eV to −1.90 eV and a HOMO of from −5.2 eV to −5.45 eV; and
the electron-transporting host material has a LUMO of from −2.35 eV to −2.80 eV and a HOMO of from −5.3 eV to −5.7 eV.

18. An organic electroluminescent device according to claim 14, characterized in that the at least one emitter is a blue emitter selected from blue fluorescent emitters and blue phosphorescent emitters.

19. An organic electroluminescent device according to claim 18, characterized in that the at least one emitter is a blue phosphorescent emitter selected from iridium and platinum complexes.

20. An organic electroluminescent device according to claim 19, characterized in that the at least one emitter is a blue phosphorescent emitter selected from tetradentate platinum complexes.

21. An organic electroluminescent device according to claim 14, characterized in that the at least one emitter is a blue, green or yellow phosphorescent emitter selected from emitters of formula (1) and (2) 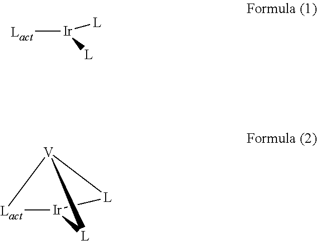
where L_{act} in formula (1) is an optically active ortho-metallated bidentate ligand and in formula (2) is an optically active ortho-metallated bidentate sub-ligand, L is different from L_{act} and is the same or different at each instance and is ortho-metallated bidentate ligands in formula (1) and ortho-metallated bidentate sub-ligands in formula (2), and V in formula (2) is a bridging unit that joins the sub-ligands L_{act} and L covalently to form a tripodal hexadentate ligand.

22. An organic electroluminescent device according to claim 21, characterized in that L_{act} and L are each a structure of one of the formulae (L-1-1), (L-1-2), (L-2-1), (L-2-2), (L-2-3) or (L-2-4) 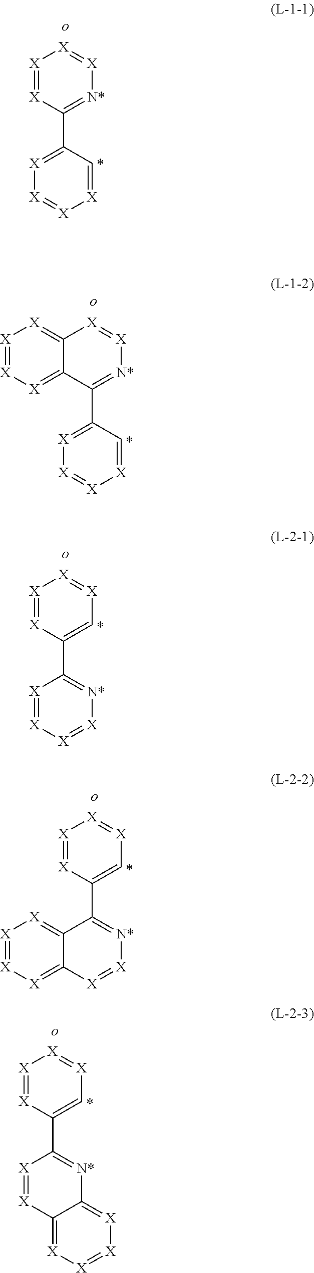 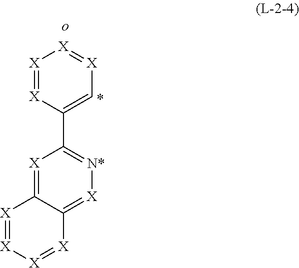
where “o” for compounds of the formula (2) represents the position of the bond to V, in which case the corresponding X is C, and where “o” is undefined for compounds of the formula (1), and in addition:
X is the same or different at each instance and is CR or N, with the proviso that at most two symbols X per ring are N;
R is the same or different at each instance and is H, D, F, Cl, Br, I, N(R¹)₂, OR′, SR′, CN, NO₂, COOR¹, C(═O)N(R¹)₂, Si(R′)₃, B(OR¹)₂, C(═O)R¹, P(═O)(R¹)₂, S(═O)R¹, S(═O)₂R¹, OSO₂R¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals and where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more nonaromatic R¹ radicals; at the same time, two R radicals together may also form a ring system;
R¹ is the same or different at each instance and is H, D, F, Cl, Br, I, N(R²)₂, OR², SR², CN, NO₂, Si(R²)₃, B(OR²)₂, C(═O)R², P(═O)(R²)₂, S(═O)R², S(═O)₂R², OSO₂R², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals and where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic organic radical, especially a hydrocarbyl radical, having 1 to 20 carbon atoms, in which one or more hydrogen atoms may also be replaced by F.

23. An organic electroluminescent device according to claim 14, characterized in that the at least one emitter is present in the layer in a proportion of 0.5-50%.

24. An organic electroluminescent device according to claim 16, characterized in that the host system is present in the emitting layer in a proportion of 60-99.5%.

25. An electroluminescent device according to claim 1, characterized in that:
the first emitting layer EMLₓ has an emission maximum wavelength λ_{R} and the emitting layer EMLₓ₊₁ has an emission maximum wavelength λ_{BGY}; or
the first emitting layer EMLₓ has an emission maximum wavelength λ_{BGY} and the emitting layer EMLₓ₊₁ has an emission maximum wavelength λ_{R},
where λ_{BGY} is of from 450 to 585 nm and λ_{R} is of from 590 to 660 nm.

26. An organic electroluminescent device according to claim 1, characterized in that the light emitting stack comprising the emitting layers EMLₓ and EMLₓ₊₁ further comprises another emitting layer EMLₓ₊₂, where the emitting layer EMLₓ₊₂ is arranged between the emitting layer EMLₓ₊₁ and the cathode, and where the emitting layer EMLₓ₊₂ is adjacent to the emitting layer EMLₓ₊₁, where one of the emitting layers EMLₓ and EMLₓ₊₂ has an emission maximum wavelength λ_{R} of from 590 to 660 nm and one of the emitting layers EMLₓ and EMLₓ₊₂ has an emission maximum wavelength λ_{BG} of from 450 to 540 nm; and
where EMLₓ₊₁ has an emission maximum wavelength λ_{GY} from 510 to 585 nm.

27. An organic electroluminescent device according to claim 26, characterized in that:
the interface charge density at the interface of the emitting layers EMLₓ and EMLₓ+i, namely ICD_{EMLx,EMLx+1}, and the interface charge density at the interface of the emitting layers EMLₓ₊₁ and EMLₓ₊₂, namely ICD_{EMLx+1},EMLₓ₊₂, fulfill the following equations:
$$y < {ICD}_{EMLx , EMLx + 1} \leq 0.1 mC \cdot {m}^{- 2}$$
$$y < {ICD}_{EMLx + 1 , EMLx + 2} \leq 0.1 mC \cdot {m}^{- 2}$$
where y is equal to −1 mC·m⁻² and
where ICD_{EMLx,EMLx+1} and ICD_{EMLx+1,EMLx+2} are respectively the differences between the surface charge density of the emitting layers EMLₓ₊₁ and EMLₓ and between the surface charge density of the emitting layers EMLₓ₊₂ and EMLₓ₊₁ as follows:
$${ICD}_{EMLx , EMLx + 1} = {SCD}_{EMLx + 1} - {SCD}_{EMLx}$$
$${ICD}_{EMLx + 2 , EMLx + 1} = {SCD}_{EMLx + 2} - {SCD}_{EMLx + 1}$$

28. An organic electroluminescent device according to claim 1, characterized in that it further comprises at least a second light emitting stack comprising a blue light emitting layer between the anode and the cathode, which is separated from the light emitting stack comprising EMLₓ and EMLₓ₊₁ by a charge generation layer.

29. An organic electroluminescent device according to claim 1, which is a tandem organic electroluminescent device.
